(19) United States
(12) Patent Application Publication
(10) Pub. No.: US 2026/0181831 A1
(43) Pub. Date: Jun. 25, 2026

(54) CONFIGURABLE SYSTEM FOR DETECTING, TRACKING, AND TRANSMITTING

(71) Applicant: Anduril Industries, Inc., Costa Mesa, CA (US)

(72) Inventors: Bryden Pearson, Irvine, CA (US); Osama E El-Akkad, Poway, CA (US); Joseph Storniolo, Costa Mesa, CA (US); Thao Pham, San Diego, CA (US)

(21) Appl. No.: 19/382,055

(22) Filed: Nov. 6, 2025

Related U.S. Application Data
(60) Provisional application No. 63/738,419, filed on Dec. 23, 2024.

(51) Int. Cl. H05K 7/20; H01Q 1/02

(52) U.S. Cl. CPC H05K 7/2039; H01Q 1/02; H05K 7/20336

(57) ABSTRACT

A module having an integrated thermal system includes a module package having a central portion configured to house an electronic component. The central portion is adaptable to support different variations of the electronic component. The module includes at least two channels extending through lateral portions of the module package in proximity to the central portion. The at least two channels further have a folded fin heatsink disposed within a length of the at least two channels. One or more heat pipes are at least partially embedded in the module package and configured to transfer heat from the electronic component in the central portion of the module package to the at least two channels extending through the lateral portions. The electronic component is in thermal communication with the at least two channels.

### CROSS-REFERENCE TO RELATED APPLICATIONS

This application claims benefit of U.S. Provisional Patent Application No. 63/738419, filed Dec. 23, 2024, and titled “CONFIGURABLE SYSTEM FOR DETECTING, TRACKING, AND TRANSMITTING TO IDENTIFIED OBJECTS.” The entire disclosure of each of the above items is hereby made part of this specification as if set forth fully herein and incorporated by reference for all purposes, for all that it contains.

Any and all applications for which a foreign or domestic priority claim is identified in the Application Data Sheet as filed with the present application are hereby incorporated by reference under 37 CFR 1.57 for all purposes and for all that they contain.

### TECHNICAL FIELD

Implementations of the present disclosure relate generally to systems and methods for operation and cooling of a modular transceiver configured for detecting, tracking, and/or transmitting. Implementations of the present disclosure further generally relate to devices, systems, and methods for transferring heat from heat-generating components of modules housed within a module closure and exhausting said heat by forcing air over one or more heatsinks of the modules by fans coupled to the modules the module enclosure.

### BACKGROUND

Radio frequency (“RF”) systems generate heat during normal operations of monitoring or transmitting radio frequencies. Such systems generally include cooling systems, and are configured to cool internal components during operation by using active or passive systems.

### BRIEF DESCRIPTION OF THE DRAWINGS

Implementations of various inventive features are described with reference to the following drawings. Throughout the drawings, reference numbers are re-used to indicate correspondence between referenced elements. The drawings are provided to illustrate example implementations described herein and are not intended to limit the scope of the disclosure.

FIG. 1 illustrates a block diagram of an example operating environment in which one or more aspects of the present disclosure operate, according to various implementations of the present disclosure;

FIG. 2 illustrates a block diagram of example hardware components of a radio frequency (“RF”) system, according to various implementations of the present disclosure;

FIG. 3 illustrates a block diagram of example software components of an RF system, according to various implementations of the present disclosure;

FIG. 4 illustrates an example implementation and orientation of a plurality of RF systems, according to various implementations of the present disclosure;

FIG. 5 illustrates an example implementation and orientation of an RF system interacting with an object, according to various implementations of the present disclosure;

FIG. 6 shows a block diagram illustrating example computer system components by which various aspects of the present disclosure are implemented;

FIG. 7 illustrates a perspective view of an example implementation of an RF system, according to various implementations of the present disclosure;

FIG. 8 illustrates a front perspective view of an example module enclosure of the RF system, according to various implementations of the present disclosure;

FIG. 9 illustrates a back perspective view of the example module enclosure of FIG. 8, according to various implementations of the present disclosure;

FIG. 10 illustrates a back perspective view of the example module enclosure of FIGS. 8 and 9 without a fan cover, according to various implementations of the present disclosure;

FIG. 11 illustrates a front perspective view of the example module enclosure of FIGS. 8-10 with a cover plate removed, according to various implementations of the present disclosure;

FIG. 12 illustrates a front perspective view of the example module enclosure of FIGS. 8-11 with a cover plate and some modules removed, according to various implementations of the present disclosure;

FIG. 13 illustrates a front perspective view of the example module enclosure of FIGS. 9-12 with a cover plate and all modules removed, according to various implementations of the present disclosure;

FIG. 14 illustrates a front view of the example module enclosure of FIGS. 9-13 with a cover plate and some modules removed, according to various implementations of the present disclosure;

FIG. 15 illustrates a front perspective cross-section along a vertical plane of the perspective view of the example module enclosure of FIG. 8, according to various implementations of the present disclosure;

FIG. 16 illustrates a cross-section along a vertical plane of the perspective view of the example module enclosure of FIG. 8, according to various implementations of the present disclosure;

FIG. 17 illustrates a cross-section along a horizontal plane of the perspective view of the example module enclosure of FIG. 8, according to various implementations of the present disclosure;

FIG. 18 illustrates a schematic cross-section along a horizontal plane of the perspective view of the example module enclosure and a multiplexer (MUX) of FIG. 8, according to various implementations of the present disclosure;

FIG. 19 illustrates a front perspective view of the example module enclosure of the RF system and MUX of FIG. 8, according to various implementations of the present disclosure;

FIG. 20 illustrates a perspective front view of an example implementation of an adaptable module, according to various implementations of the present disclosure;

FIG. 21 illustrates a front perspective view of an example module having an integrated thermal system, according to various implementations of the present disclosure;

FIG. 22 illustrates a partially exposed view of the example module having an integrated thermal system of FIG. 21, according to various implementations of the present disclosure;

FIG. 23 illustrates a top view of the example module having an integrated thermal system FIGS. 21 and 22, according to various implementations of the present disclosure;

FIG. 24 illustrates a bottom perspective view of the example module having an integrated thermal system of FIGS. 21-23, according to various implementations of the present disclosure;

FIG. 25 illustrates a bottom view of the example module having an integrated thermal system of FIGS. 21-24, according to various implementations of the present disclosure;

FIG. 26 illustrates a cross-section along a vertical plane of the example module having an integrated thermal system of FIG. 21, according to various implementations of the present disclosure;

FIG. 27 illustrates a cross-section along a horizontal plane of the example module having an integrated thermal system of FIG. 21, according to various implementations of the present disclosure;

FIG. 28 illustrates another cross-section along a horizontal plane of the example module having an integrated thermal system of FIG. 21, according to various implementations of the present disclosure;

FIG. 29 illustrates a perspective front view of another example module having an integrated thermal system, according to various implementations of the present disclosure;

FIG. 30 illustrates a front view of the another example module having an integrated thermal system of FIG. 29, according to various implementations of the present disclosure;

FIG. 31 illustrates a cross-section along a vertical plane of the another example module having an integrated thermal system of FIGS. 29 and 30, according to various implementations of the present disclosure;

FIG. 32 illustrates an example flow or method of assembling an RF system, according to various implementations of the present disclosure;

FIG. 33 illustrates an example flow or method of managing thermal transfer in a module of an RF system, according to various implementations of the present disclosure; and

FIG. 34 illustrates a perspective view of an example antenna housing of the RF system, according to various implementations of the present disclosure;

FIG. 35 illustrates a front view of the example antenna housing of the RF system of FIG. 34;

FIG. 36 illustrates a perspective view of the example antenna housing without the modules coupled to slots of the RF system of FIGS. 34 and 35;

FIG. 37 illustrates another perspective view of the example antenna housing without the modules coupled to slots of the RF system of FIGS. 34-36;

FIG. 38 illustrates another perspective view of the example antenna housing without the modules coupled to slots and the fan cover removed of the RF system of FIGS. 34-37;

FIG. 39 illustrates a cross-section along a vertical plane of the perspective view of the example antenna housing of the RF system of FIG. 34;

FIG. 40 illustrates a top perspective view of an example module, according to various implementations of the present disclosure;

FIG. 41 illustrates a bottom perspective view of the example module of FIG. 40;

FIG. 42 illustrates a top perspective view of the example module of FIGS. 14 and 15 without the removable cover;

FIG. 43 illustrates a front perspective view of a first substrate of the example module of FIGS. 40-42, according to various implementations of the present disclosure;

FIG. 44 illustrates a front perspective view of a second substrate of the example module of FIGS. 40-43, according to various implementations of the present disclosure;

FIG. 45 illustrates a back perspective view of the first substrate of the example module of FIG. 43;

FIG. 46 illustrates a perspective view of a cross-section along a vertical plane of the perspective view of the example module of FIG. 40;

FIG. 47 illustrates an example flow or method of assembling a, antenna housing for an RF system, according to various implementations of the present disclosure;

FIG. 48 illustrates an example flow or method of managing thermal transfer in a module of a antenna housing for an RF system, according to various implementations of the present disclosure; and

FIG. 49 illustrates a block diagram of an example operational environment, according to various implementations of the present disclosure.

### DETAILED DESCRIPTION

Although certain implementations and examples are disclosed below, inventive subject matter extends beyond the specifically disclosed implementations to other alternative implementations and/or uses and to modifications and equivalents thereof. Thus, the scope of the claims appended hereto is not limited by any of the particular implementations described below. For example, in any method or process disclosed herein, the acts or operations of the method or process are optionally and variously performed in any suitable sequence and are not necessarily limited to any particular disclosed sequence. Various operations are described as multiple discrete operations in turn, in a manner that is helpful in understanding certain implementations; however, the order of description should not be construed to imply that these operations are order dependent. Additionally, the structures, systems, and/or devices described herein are optionally embodied as integrated components or as separate components. For purposes of comparing various implementations, certain aspects and advantages of these implementations are described. Not necessarily all such aspects or advantages are achieved by any particular implementation. Thus, for example, various implementations are carried out in a manner that achieves or optimizes one advantage or group of advantages as taught herein without necessarily achieving other aspects or advantages as also taught or suggested herein.

### Overview

To monitor a surrounding area, one or more items of specialized equipment are installed to identify objects, track objects, and/or transmit signals towards objects. Conventional equipment, and its associated software components, if any, is typically manufactured with bulky and/or inadequate cooling systems. These conventional systems are not sufficiently cooled, and in some cases, are not cooled at all, leading to system shutdowns or performance degradation. For example, if the systems are operating in warm or hot environments, the system are not adequately cool, reducing operability and/or requiring substantial investment in additional cooling to sufficiently cool them down. Such systems also are inefficient in terms of energy consumption, leading to increased operational costs. Additionally, conventional equipment often lacks the modularity required to adapt to diverse monitoring scenarios or changing environmental conditions. For example, a fixed cooling mechanism are ill-suited for systems deployed in environments where temperatures fluctuate dramatically, causing either overcooling or insufficient cooling at different times. Furthermore, the bulky nature of these systems pose significant challenges in deployment, particularly in confined or hard-to-reach areas, such as densely populated urban environments, remote wilderness regions, or industrial facilities with limited space. This lack of adaptability and portability severely limit the scope and efficacy of monitoring operations. Moreover, inadequate cooling not only affects the physical hardware but also impacts the performance of software components reliant on stable operating conditions. Overheating leads to hardware throttling, reduced processing speeds, and/or increased latency, which in turn impair real-time object tracking, identification, and signal transmission functions. Over time, repeated exposure to suboptimal thermal conditions also accelerate hardware wear and tear, leading to a higher frequency of system failures and maintenance requirements.

The systems, methods, and devices of the present disclosure (generally collectively referred to herein as the “RF system”) overcome one or more of these disadvantages, and include a module enclosure and one or more modules that transfer heat away from heat-generating components of said modules, such as through the use of active thermal management systems. The RF system advantageously includes the capability of being cooled while out in the field without additionally external components through the combination of heat transferring devices (e.g., heat pipes and heatsinks) and forced air. The systems, methods, and devices described herein pertain to hardware and software components related to one or more modular systems that ensure consistent performance across a wide range of environmental conditions.

Hardware components of the described radio frequency (“RF”) system include a module enclosure housing one or more processing modules, RF modules, and/or power supply modules, and one or more fans, among other hardware components described in more detail herein. With respect to cooling, in some examples, the one or more fans are physically coupled to the module enclosure and configured to cause air to flow into said module enclosure. The fans are positioned on one side of the module enclosure and, on their own or collectively, force air through the module enclosure and modules, which is exhausted out of the module enclosure into the environment. The airflow is directed through heatsinks within channels or cavities of the modules to facilitate the heat transfer away from heat-generating components. Heat pipes embedded in and/or on the modules direct heat away from the heat-generating components to the heatsinks within the channels or cavities. Waste heat is thus be expelled from the module enclosure modules, maintaining a stable thermal environment for internal module components and reduce the risk of overheating. This configuration also offers several advantages compared to alternative cooling methods. For example, forced airflow through the module enclosure is more effective than passive cooling, which relies on convection or large heatsinks. The fans provide a high cooling capacity, enabling the RF system to handle dense configurations and substantial heat loads, which occur in RF systems. Additionally, the consistent airflow through the modules minimizes hot spots and ensures uniform temperature distribution. The use of active fans also makes the system adaptable to environments with limited natural airflow, such as confined spaces, or in extreme environments such as deserts and mountainous terrain. Furthermore, by removing the heat from the heat-generating components to the heatsinks, the waste heat is transferred to a location where it is effectively dissipated, optimizing the thermal management within the module and reducing the risk of overheating.

Hardware components of the described systems also include a variety of antennas to transmit or receive at varying power levels and frequencies in one or more directions. For example, these antennas include both directional and omnidirectional antennas. Directional antennas, such as those included in a high band frequency extender (“HBFE”) of the RF system, provide greater concentration of radiation in a certain direction is desired, enabling transmission or reception over longer distances and reducing interference from unwanted sources. Their focused energy provide enhanced signal strength, improved range, and reduced susceptibility to interference, making them ideal for point-to-point communication. Additionally, such antennas are used to transmit, receive, or transmit and receive radio signals with a wide frequency spectrum. Also, directional antennas are power-efficient as they minimize energy wastage by targeting specific areas. They also improve communication security by reducing the likelihood of signal interception from unintended directions and often support a broad range of frequencies, enhancing operational flexibility. Omnidirectional antennas are configured to radiate or receive signals uniformly in all horizontal directions, enabling 360-degree coverage. This enables communication with multiple devices or in environments where the direction of signal sources vary. Omnidirectional antennas also do not require precise alignment and maintain reliable performance in dynamic or mobile environments.

The inclusion of both directional and omnidirectional antennas within the RF system provides a synergistic benefit, enabling the system to address a wider range of communication requirements. Directional antennas offer focused, long-range connectivity and improved resistance to interference, while omnidirectional antennas ensure broad coverage and ease of use in scenarios requiring multidirectional communication. This combination enhances the flexibility and adaptability of the RF system, allowing it to switch seamlessly between targeted and widespread communication as operational needs dictate. Additionally, this dual-antenna configuration improves network coverage, supports high-demand applications, and ensures operational redundancy. Should one type of antenna experience performance degradation due to environmental factors, the complementary antenna type maintains communication continuity. By integrating both directional and omnidirectional antennas, the RF system achieves an optimized balance of coverage, performance, and reliability, suitable for deployment in a variety of challenging and evolving environments.

In various implementations, the antennas are configured to transmit and/or receive radio signals in a subset of the wide frequency spectrum. For example, nearby equipment emits signals in a particular frequency range where an antenna is facing, and the system is programmed to filter received signals (e.g., with software) so as to not interfere with analysis of received signals and/or filter transmitted signals (e.g., with software or additional digital signal filtering equipment) to minimize or eliminate interference with the operation of the nearby equipment. Accordingly, the RF system selectively transmits signals of varying powers via the various antennas.

Hardware components of the described systems also include a direction finder, also referred to herein as a radio direction finder or direction finding antenna. The direction finder uses reception of radio waves to determine the direction in which an object is located. In various implementations, by combining the direction information from multiple sources (e.g., other direction finders in the area, other systems, or one or more of the antennas, and/or the like), the source of a transmission are located (e.g., via triangulation or other similar means).

In various implementations, each antenna of a high-band frequency extender (“HBFE”) and its associated electronic circuitry operate independently as well as in a coordinated way with the other antennas of the HBFE. In an example, a first antenna of an HBFE is configured to face and monitor a 120° field of view, and three of the described antennas are configured to monitor a full 360° (or approximately 360°) field of view. In various implementations, there are additional antennas used (e.g., 4 antennas each covering 90°, 5 antennas each covering 72°, 6 antennas each covering 60°, 7 antennas each covering about 52°, and/or the like), fewer antennas used (e.g., 1 antenna each covering 360°, 2 antennas each covering 180°, 3 antennas each covering 120°), and/or some fields of view overlap as well (e.g., 4 antennas with each antenna covering 120°, or the like). The antennas are also configured to comprise automated or manual adjustability with respect to a vertical angle so that the antenna faces more downwards towards the ground or be adjusted to face more upwards towards the sky. In some applications, there is an optimum angle that the antenna adjusts to based on empirical data or artificial intelligence/machine learning.

In various implementations, the antennas of the high band frequency extender (HBFE) and their associated electronic circuitry comprises multiple physical configurations. For example, the antennas and associated electronic circuitry are configured to scan an analyze over a wide area so that the number of HBFE antennas are lessened in one specified location. For example, there may be three antennas at one location, where each antenna is configured to monitor a 120° field of view, for a total field of view of 360° being monitored by the three antennas, which provides hemispherical coverage.

The RF system is advantageously modular to enable multiple configurations for various applications. The modularity of the RF system is found in both the modularity of a particular RF system that operates on its own (including in coordination with one or more additional systems or sensors), and multiple RF systems that isoperated in coordination with one another (including in coordination with one or more additional systems or sensors). In the various implementations, the RF system further includes components for mounting the RF system, such as one or more mounts, clips, slides, pins, and/or the like. Advantageously, the RF system, given its modularity, is appropriately configured for a given application, and mounted on a tripod, a vehicle, a building, and/or the like.

In various implementations, the module enclosure includes processing modules/SOM modules, RF modules, and/or power supply modules. In such implementations, the RF modules support an array of directional and/or omnidirectional antennas, the processing modules/SOM modules support the corresponding RF modules, and the power supply module provides power to the processing modules/SOM modules and the RF modules. Accordingly, the quantity of processing modules/SOM modules, RF modules, and/or power supply modules vary depending on the number of slots of the module enclosure, which also correspond to the number of antennas of the RF system. Additionally, in any of these configurations the RF system additionally supports one or more direction finders via one or more components of the module enclosures (e.g., the processing modules/SOM modules, the RF modules, and/or the power supply modules).

In various implementations, each module enclosure of the RF system includes processing modules and RF modules that include electronic circuitry that is configured to couple to and operate 1, 2, 3, 4, or more individual antennas. For example, each processing module comprises one or more motherboards, one or more processors, one or more graphics processing units (“GPUs”), one or more software-defined radio (“SDR”) transceivers, and/or the like, and is configured to control and operate one or more antennas. In various implementations, a single module enclosure is coupled to two antennas, where the antennas are placed at a single location, or the antennas are placed a distance apart from each other (e.g., 5, 10, 100 feet apart) and coupled to the same module enclosure.

In various implementations, an RF system is manufactured or assembled with a module enclosure (among other hardware components as described herein) and one or more antennas that is configured to have a compact, movable, and/or adaptable design. Additionally, in various implementations, the RF system is manufactured into a compact and/or lightweight design so that the RF system is placed in a variety of positions and locations. For example, in an implementation, the RF system has a total height (e.g., length) of between about 20 cm and about 250 cm, and has a total weight of between about 10 kg and about 100 kg. Additionally, in some examples, the antennas are decoupled from the module enclosure of the RF system and swapped with different types of antennas that may provide different functionality (e.g., wider or narrower field of view such as omnidirectional, longer range sensitivity, shorter range sensitivity, and the like) and/or different physical attributes for improved mobility or adaptability depending on the application (e.g., reduced or increased size, different shape, and the like). For example, if the RF system is going to be moved from the roof of a building onto a vehicle, there is the need to use one or more different antennas that are configured to be secured safely to the vehicle while the vehicle is in operation, and satisfy the new requirements associated with the placement at the same time. Such requirements may include being able to monitor a wider field of view than the prior position of being placed on the side of a building, and the wider field of view is achieved with additional antennas and/or different antennas that are configured differently.

The RF system also advantageously includes a physical modular configuration and materials that efficiently dissipate heat from the components of the modules (e.g., processing modules, the RF modules, and power supply modules) to enable the RF system to operate in high temperature and/or extreme environments. For example, the module enclosure includes fans, and the modules contained in the module enclosure comprise one or more cavities or channels for air to flow through said modules to cool the various components of the modules. The modules, for example, include heatsinks within the cavities or channels, thermally coupled to the processing modules, the RF modules, and the power supply modules via heat pipes, over which air flows as pushed or pulled by the fans to cool the components of the modules. The fans cause air to flow through the module enclosure, through the heatsinks within the cavities or channels of the processing modules, the RF modules, and power supply modules, and out of the modules enclosure to the environment.

The RF system also advantageously include a physical modular configuration that provides physical protection to the components for use in, for example, dirty or extreme environments. For example, the module enclosure include an interior space defined by a shell into which the processing module(s), the RF module(s), and the power supply module(s) are placed. The interior space is sealed from the outside environment. The shell of the module closure also advantageously provides shielding from electromagnetic interference (“EMI”) for the various components of the RF system. EMI shielding provided, for example, by constructing the cavities of metal and/or other EM shielding materials or components. Additionally, the module enclosure also includes vents, grates, filters, or the like to prevent intrusion of sand or other debris into the channels or cavities of the modules housed of the RF system through which air flows.

In various implementations, the RF system, including the various components such as the module enclosure, the processing modules, the RF modules, and power supply modules, and/or the antennas are manufactured to account for and tolerate high temperature and/or extreme environments. For example, specific materials, such as metals, are used to dissipate heat more quickly. Additionally, for example, each of the processing modules, the RF modules, and power supply modules include individual housings that provide additional environmental protection, shock protection, and thermal conductivity for the internal components (e.g., to provide thermal conductivity and heat dissipation to the outside of the individual components). Accordingly, the RF system advantageously provide shielding of sensitive components from weather, sunlight (e.g., heat), and other external threats that may damage or reduce the efficiency of the equipment (e.g., processor throttling due to high temperatures).

In various implementations, the RF modules include power amplifier technology. For example, the RF modules include a radio frequency (“RF”) power amplifier as an electronic amplifier that converts a low-power radio-frequency signal into a higher power signal. The RF modules also include digital and/or analog filter technology. For example, a digital filter (e.g., in signal processing) performs mathematical operations on a sampled, discrete-time signal to reduce or enhance certain aspects of that signal. The RF system, the RF modules, and/or the module enclosure also include multiplexers to provide for receiving and transmitting via the antennas.

In various implementations, the RF system, e.g., the processing modules, also include positioning, navigation, and timing (“PNT”) capabilities. Such PNT capabilities are provided by one or more PNT components that include, for example, global navigation satellite system capabilities (e.g., global positioning system (“GPS”) capabilities), among other PNT functions. In some examples, the one or more PNT components further provide orientation information, altitude information, angle/tilt information, and/or the like. In some implementations, the PNT capabilities are provided in and/or by the direction finder, in whole or in part. The PNT capabilities of the RF system are provided by one or more PNT components, and/or the like. The PNT capabilities are also be referred to herein as “positioning capabilities”, and the one or more PNT components are also referred to herein as “positioning components”, and/or the like. The PNT capabilities of the RF system are used, for example, in object location determinations and/or tracking, as described herein, because such functionality is dependent on the position, orientation, tilt, and/or the like, of the RF system (e.g., such that the correct antenna, with the correct orientation and tilt, is used to detect or target an object).

In various implementations, the processing modules includes a machine learning component that is used to assist the RF system in detecting and/or identifying one or more RF signals captured by a coupled/connected antenna. For example, the machine learning component implement machine learning (“ML”) algorithms, artificial intelligence (“AI”) algorithms, ML models, other programmed algorithms, and/or the like (generally collectively referred to herein as “AI/ML algorithms”, “AI/ML models”, or simply as “ML algorithms”, “ML models”, and/or the like) that, for example, implement models that are executed by one or more processors. Having an AI/ML model to identify RF signals advantageously provide significant improvements as compared to conventional systems because many detected signals include some level of interference, be relatively weak and hard to detect, or otherwise hard to identify due to other factors. In various implementations, the machine learning component use one or more machine learning algorithms to implement one or more models or parameter functions for the detections/identifications. The machine learning component is configured to apply a model that helps detect which types of RF signals (e.g., a range of RF signals, particular frequencies or combinations of frequencies, and/or the like) indicate which types of objects.

In various implementations, a machine learning model of the RF system is programmed or trained by: (1) sampling raw signals (e.g., captured from one or more connected antennas), (2) signal annotation (e.g., frequency, time, and intensity), (3) signal filtering, and (4) model training. The trained model is then applied, by the RF system, to received or captured RF signals for identification purposes. For example, in various embodiments, application of the trained machine learning model comprises: (1) raw signal sampling, (2) application of trained model, and/or (3) output of classes and probabilities (e.g., associated with type of objects). Then, for example, the processing module identifies a captured RF signal and/or a type of object based on the (3) output of classes and probabilities. Also, in various implementations, application of the trained machine learning model comprises the preliminary step of (0) filtering base line signal and/or friendly signals.

In various implementations, sampling raw signals or raw signal (e.g., RF) data includes any form of data sampling. Data sampling, for example, includes a statistical analysis technique used to select, manipulate, and analyze a representative subset of data points to identify patterns and trends in the larger data set being examined. It enables working with a small, manageable amount of data that is representative of a larger, unmanageable amount of data. Sampling advantageously enables analysis of data sets that are too large to efficiently analyze in full or within a desired amount of time. In various embodiments, the RF system samples the raw signal for some period of time (e.g., some number of milliseconds, such as 1 ms, 2 ms, 3 ms, 5 ms, 10 ms, 50 ms, or some other period of time). In various embodiments, other, or additional, sampling methods are employed.

In various implementations, the RF system (e.g., via one or more processing modules and/or one or more RF modules) uses identified types of objects (e.g., output from the applied machine learning model) to generate one or more new signals and, using one or more of the antennas, transmit the new signals. The new signals are transmitted in the direction of the identified signal or one or more objects. Accordingly, the RF system selectively transmits signals of varying powers via the various antennas. In various implementations, the identified signal corresponds to one or more mobile objects (e.g., vehicle, boat, aircraft, drone, and/or the like), and the transmitted signals affect communications in the vicinity of the mobile object during transmission. In various implementations, detections or identification of objects, or identification of signals corresponding to objects, are received from one or more other systems or sensors. Generating a signal based on the identified signal is advantageously beneficial due to increased power efficiency/optimization. For example, instead of transmitting signals in all frequency bands, only signal in a specific frequency or narrow range of frequencies are transmitted instead, thereby increasing power efficiency and/or signal power to reach father distances. In various implementations, the transmitted signal is further filtered to limit interference of sensitive friendly systems in the area.

In various implementations, the RF system tracks an identified signal or object (e.g., while the RF system is transmitting or not). In various implementations, the direction finder provides more accurate tracking as well. For example, the direction finder in conjunction with the one or more antennas identifies a direction where a detected signal is emanating from (e.g., while the antennas are transmitting or not).

In various implementations, there are other sensors or systems (e.g., and including other RF systems in the area) that communicate with the RF system to provide additional data that is used to: (1) improve the detections performed by the RF system by using the machine learning models; (2) assist RF system in continuing to track, or begin tracking, an object or signal; and/or (3) generate and transmit, or continue generating and transmitting, a specific signal in the direction of an object, among other functions.

In various implementations, each RF system includes software, including the machine learning models or component, that are updated over-the-air (“OTA”) or via electrical hardwire connection. For example, the RF system communicates with the central processing server to receive updates. As another example, if multiple RF systems are installed in an area, it is beneficial for the RF systems to communicate and update each other's machine learning models (e.g., by sending the updated models, or relevant data captured so that each RF system trains based on the additional data) over time so that each RF system has the most up-to-date data or model available. In various implementations, although RF systems is in the same area, it may be beneficial to only share portions of data or machine learning models between the RF systems since there may be subtle differences between each RF systems field of view that may result in one model being better suited for a first environment/area than another model that is better suited in a second environment/area.

In various implementations, a series of one or more RF systems are placed in an area. For example, a first RF system is placed on the northeast corner of a building with one antenna (e.g., of a high band frequency extender (HBFE)) facing north and another facing east. Also, a second RF system is placed on the southwest corner of the same building with one antenna (e.g., of a second HBFE) facing south and the other facing west. Accordingly, the four antennas coupled to the two RF systems (and/or additional RF systems and associated antennas) monitor a 360° area (or approximately a 360° area) surrounding the building, and at the same time omitting any signal detection coming from the building itself. As a consequence of the orientation, while any of the antennas are transmitting signals, the transmission is away from the building so that the building and any equipment or personnel in the building are not impacted or affected by any transmissions. The orientation and the signal filtering described herein further limits interference of friendly areas and equipment in an improved manner.

Further, according to various implementations, various interactive graphical user interfaces are provided for allowing various types of users to interact with the systems and methods described herein to, for example, generate, review, and/or modify data captured by or used by one or more RF systems or connected systems.

The interactive and dynamic user interfaces described herein are enabled by innovations in efficient interactions between the user interfaces and underlying systems and components. For example, disclosed herein are improved methods of receiving user inputs, translation and delivery of those inputs to various system components, automatic and dynamic execution of complex processes in response to the input delivery, automatic interaction among various components and processes of the system, and automatic and dynamic updating of the user interfaces. The interactions and presentation of data via the interactive user interfaces described herein accordingly provides cognitive and ergonomic efficiencies and advantages over previous systems.

Further details and examples of functionality and operation of the RF system, including, for example, operation of AI/ML algorithms, signal detection, signal generation, and/or the like, are described in PCT International Publication No. 2023/225417, published Nov. 23, 2023, and titled “Modular System For Detecting, Tracking, And Transmitting To Identified Objects” (the '417 Publication), the entire disclosure of which is hereby made part of this specification as if set forth fully herein and incorporated by reference for all purposes, for all that it contains.

Accordingly, in various implementations, large amounts of data is automatically and dynamically gathered and analyzed in response to user inputs and configurations, and the analyzed data is efficiently presented to users. Thus, in some embodiments, the systems, devices, configuration capabilities, graphical user interfaces, and the like described herein are more efficient as compared to previous systems, and/or the like.

Various implementations of the present disclosure provide improvements to various technologies and technological fields, and practical applications of various technological features and advancements. For example, as described above, some existing systems are limited in various ways, and various embodiments of the present disclosure provide significant improvements over such systems, and practical applications of such improvements. Additionally, various implementations of the present disclosure are inextricably tied to, and provide practical applications of, computer technology. In particular, various implementations rely on specialized hardware installed in specific locations as well as software components to improve energy and processing efficiency. Such features and others are intimately tied to, and enabled by, computer technology, artificial intelligence, and digital signal technology and would not exist except for computer technology, artificial intelligence, and digital signal technology. For example, the RF system, processing module, RF module, and signal detection, generation, and transmission functionality and interactions with detected objects/signals described herein in reference to various implementations cannot reasonably be performed by humans alone, without the computer and technology upon which they are implemented. Further, the implementation of the various implementations of the present disclosure via computer technology enables many of the advantages described herein, including more efficient interaction with, and analysis of, various types of electronic data, and the like.

Various combinations of the above and below recited features, embodiments, and aspects are also disclosed and contemplated by the present disclosure.

Additional implementations of the disclosure are described below in reference to the appended clauses and claims, which serve as an additional summary of the disclosure.

In various implementations, systems and/or computer systems are disclosed that comprise one or more computer-readable storage mediums or devices comprising, configured to store, and/or storing program instructions, and one or more processors configured to execute the program instructions to cause the systems and/or computer systems to perform operations comprising one or more aspects of the above-and/or below-described implementations (including one or more aspects of the appended claims).

In various implementations, computer-implemented methods are disclosed in which, by one or more processors executing program instructions, one or more aspects of the above-and/or below-described implementations (including one or more aspects of the appended claims) are implemented and/or performed.

In various implementations, computer program products comprising one or more computer-readable storage mediums or devices, and/or one or more computer-readable storage mediums or devices, are disclosed, wherein the computer-readable storage mediums comprise, are configured to store, and/or store program instructions, the program instructions executable by one or more processors to cause the one or more processors to perform operations comprising one or more aspects of the above-and/or below-described implementations (including one or more aspects of the appended claims).

Implementations of the disclosure are described below with reference to the accompanying figures, wherein like numerals refer to like elements throughout. The terminology used in the description presented herein is not intended to be interpreted in any limited or restrictive manner, simply because it is being utilized in conjunction with a detailed description of certain specific embodiments of the disclosure. Furthermore, embodiments of the disclosure include several novel features, no single one of which is solely responsible for its desirable attributes or which is essential to practicing the embodiments of the disclosure herein described.

### Example Operating Environment

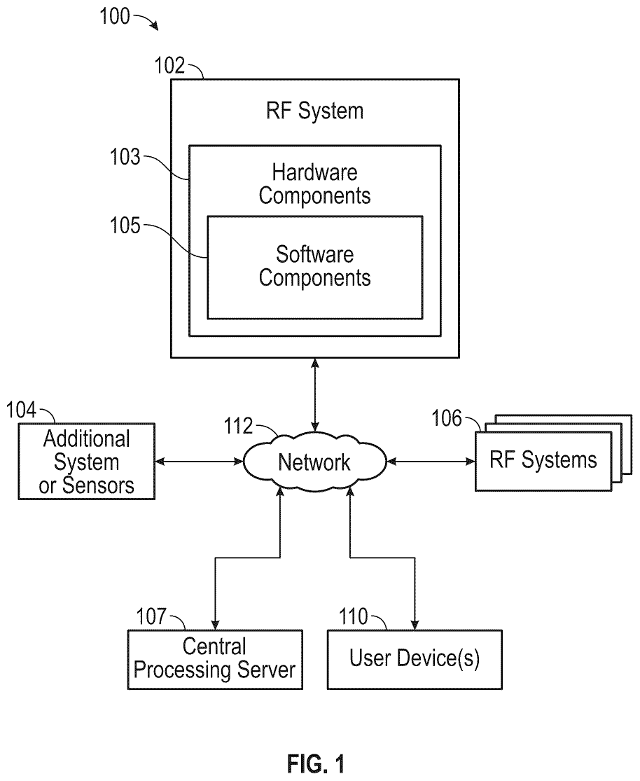

FIG. 1 illustrates a block diagram of an example operating environment 100 in which one or more aspects of the present disclosure operate, according to various implementations of the present disclosure. The operating environment 100 includes an RF system 102, optional additional RF systems 106, additional systems or sensors 104, a central processing server 107, and one or more user devices 110. Each RF system 102 (and optional additional RF systems 106) includes various hardware components 103, and software components 105, with provides various functionality as described further herein.

In various implementations, communications among the various components of the example operating environment 100 are accomplished via any suitable device, systems, methods, and/or the like. For example, the RF system 102 and optional additional RF systems 106) communicate with one another, the additional systems or sensors 104, the central processing server 107, and one or more user devices 110 via any combination of the network 112 or any other wired or wireless communications networks, method (e.g., Bluetooth, WiFi, infrared, cellular, and/or the like), and/or any combination of the foregoing or the like. As further described below, network 112 comprises, for example, one or more internal or external networks, the Internet, and/or the like.

Further details and examples regarding the implementations, operation, and functionality of the various components of the RF system 102 and the example operating environment 100 are described herein in reference to various figures.

### Network 112

The network 112 includes any wired network, wireless network, or combination thereof. For example, the network 112 is a personal area network, local area network, wide area network, over-the-air broadcast network (e.g., for radio or television), cable network, satellite network, cellular telephone network, or combination thereof and/or the like. As a further example, the network 112 is a publicly accessible network of linked networks, possibly operated by various distinct parties, such as the Internet. In various implementations, the network 112 is a private or semi-private network, such as a corporate or university intranet. The network 112 includes one or more wireless networks, such as a Global System for Mobile Communications (GSM) network, a Code Division Multiple Access (CDMA) network, a Long Term Evolution (LTE) network, C-band, mmWave, sub-6 GHz, or any other type of wireless network. The network 112 uses protocols and components for communicating via the Internet or any of the other aforementioned types of networks. For example, the protocols used by the network 112 include Hypertext Transfer Protocol (HTTP), HTTP Secure (HTTPS), Message Queue Telemetry Transport (MQTT), Constrained Application Protocol (CoAP), and the like. Protocols and components for communicating via the Internet or any of the other aforementioned types of communication networks are well known to those skilled in the art and, thus, are not described in more detail herein.

In various embodiments, the network 112 represents a network that is local to a particular organization, e.g., a private or semi-private network, such as a corporate or university intranet. In some implementations, devices (e.g., RF system 102, RF systems 106, additional systems or sensors 104, central processing server 107, device(s) 110, and/or the like) communicate via the network 112 without traversing an external network, such as the Internet. In some implementations, devices connected via the network 112 are walled off from accessing the Internet, e.g., the network 112 are or are not connected to the Internet. Accordingly, e.g., the user device(s) 110 communicate with the RF system 102, RF systems 106, or additional systems or sensors 104 directly (via wired or wireless communications) or via the network 112, without using the Internet. Thus, even if the network 112 or the Internet is down, the RF system 102, RF systems 106, or additional systems or sensors 104 continue to communicate and function via direct communications (and/or via the network 112).

In various implementations, the network 112 and/or various other aspects of the operating environment 100 incorporate “mesh” type communications among components, and/or secure communications among components. Examples of such mesh and/or secure communications are described in U.S. Patent Publication No. 2019/0380032, published Dec. 12, 2019, and titled “Lattice Mesh” (the '032 Publication), the entire disclosure of which is hereby made part of this specification as if set forth fully herein and incorporated by reference for all purposes, for all that it contains. For example, and in some implementations as described herein, detection and/or identification of object(s), and/or responding to such a detection and/or identification (e.g., by transmitting one or more RF signals) is performed by one more systems (e.g., RF systems), devices, sensors, or the like. For instance, any devices and/or sensors communicate with one or more of the RF systems described herein so that any information transmitted between devices is used, in whole or in part (e.g., in combination with one or more of the RF systems'own detections), to initiate a response (e.g., transmit one or more RF signals).

### Additional Systems or Sensors 104

The additional systems or sensors 104 include, for example, various sensors and monitoring equipment. For example, non-limiting examples of additional systems or sensors 104 include: sensors/monitors (e.g., temperature, positioning/location, PNT, direction finder, altitude, angle/tilt, levels, vibration, power, pressure, and/or the like); video cameras (e.g., video, audio, position, motion, heat, and/or the like); antennas (e.g., long range, short range, and/or the like); radar devices; light detection and ranging (“LIDAR”) devices; mobile systems or sensors (e.g., a sensor on a vehicle or an aerial drone); stationary systems or sensors (e.g., a sensor on a tower station); other types of systems or sensors; and/or any combination of the foregoing. Additional examples of systems or sensors 104 that are included in the operating environment 100, and which provide information to, or receive information from, RF systems 102, 106, as described herein, are described in U.S. Patent Application Publication No. 2020/0167059, filed Nov. 27, 2018, and titled “Interactive Virtual Interface” (the '059 Publication), and in U.S. Patent Application Publication No. 2020/0363824, filed May 17, 2019, and titled “Counter Drone System” (the '824 Publication), the entire disclosures of each of which are hereby made part of this specification as if set forth fully herein and incorporated by reference for all purposes, for all that it contains.

As described herein, RF system 102 communicates with, provide information to, or receive information from, additional systems or sensors 104. Similarly, RF system 102 communicates with, provide information to, or receive information from, one or more RF systems 106. Similarly, RF systems 106 communicates with, provides information to, or receives information from, additional systems or sensors 104. In various embodiments, communications among the various components of the operating environment 100 is accomplished via intermediate communications with a centralized server or database (e.g., central processing server 107), which stores data associated with the additional systems or sensors 104. Alternatively, additional systems or sensors 104 are communicated with and/or configured via communication with user device(s) 110. Data and information gathered from the additional systems or sensors 104 is provided directly or indirectly to the RF system 102.

In various implementations, one or more of, or a combination of, the RF system 102, RF systems 106, and/or the user device(s) 110 provide an application programming interface (“API”) by which communications are accomplished with the additional systems or sensors 104.

The various communications among the components of the operating environment 100 can, as described herein, be used to determine locations of objects (which includes mobile objects) via various methods. Examples of such communications and methods of determining locations of objects are provided in, for example, the '059 Publication and the '824 Publication.

### Central Processing Server 107

The central processing server 107 includes, for example, one or more computing systems in communication (e.g., via network 112) with the RF systems (e.g., RF system 102 and RF systems 106), additional systems or sensors 104, and/or user device(s) 110. For example, data and information gathered from the additional systems or sensors 104, the RF system 102, or RF systems 106 are provided directly or indirectly to the central processing server 107 for storage, analysis, and/or transmission to other connected systems. For example, one RF system 106 may detect/identify a specific signal and/or object, and the RF system 106 transmits that data to the central processing service 107, which then transmits an indication of the detected signal to other systems (e.g., RF system 102). For example, in some examples described herein, RF systems (e.g., RF system 102 and RF systems 106) work together in a network to detect signals around a designated area or location (e.g., a building) since each RF system includes antennas that may only face certain directions. In various implementations, the central processing server 107 is communicated with and/or configured via communication with user device(s) 110.

As noted above, the various components of the operating environment 100 can, as described herein, be used to determine locations of objects (which includes mobile objects) via various methods. Examples of such methods of determining locations of objects are provided in, for example, the '059 Publication and the '824 Publication. Accordingly, the central processing server 107 and/or user device(s) 110 of the present disclosure are analogous, in whole or in part, to the interactive virtual interface system of the '059 Publication in that various sensor data and location determinations are integrated together. Such location information is further shared among the various components of the operating environment 100 (e.g., RF system 102 and RF systems 106) to enable coordination among the components for transmitting generated signals to located objects (which includes mobile objects). Further, as noted above, communications among the various components of the operating environment 100 are provided via various methods, some examples of which are described in the '032 Publication.

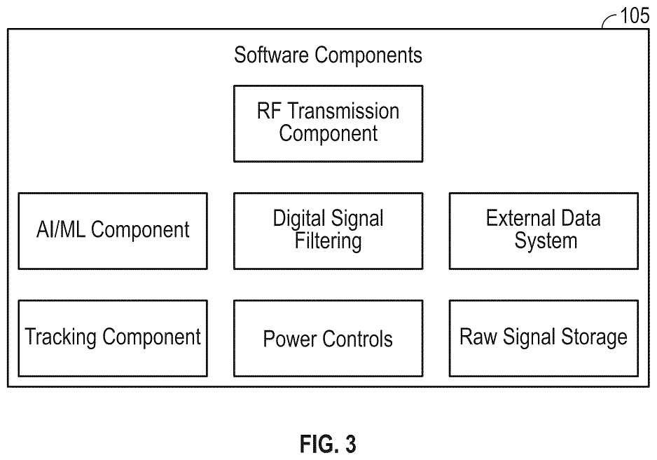

In various implementations, the central processing server 107 comprises hardware similar to that of the computer system described herein in reference to FIG. 3. Alternatively, in various implementations, the central processing server 107 exists via software thereby linking a number of RF systems and any other optional additional systems or sensors together so that the systems or sensors share information among themselves (in such implementations, the various collective components of the RF systems provide similar functionality to that of the computer system described in reference to FIG. 3). In various implementations, the central processing server 107 creates a mesh network, an example of which is described in the '032 Publication (as noted above). For example, the central processing server 107 comprises an interface and a processor. The interface is configured to receive a request to register from a host, wherein the request to register includes a key and a set of asset identifications (“IDs”) that the host wishes to claim. The processor is configured to sign the key to generate a resource authority (“RA”) certificate signed key with an RA certificate; update an asset database with the RA certificate signed key; distribute the RA certificate signed host public key through the network; and provide the host with the RA certificate signed key. In various implementations, the server further comprises a memory that is coupled to the processor and configured to provide the processor with instructions. The system for a mesh network includes a secure mechanism for communication between nodes (e.g., RF system 102, RF system 106, additional systems or sensors 104, user device 110, and/or the like) that is enabled for messages that have a targeted destination both in a point-to-point mode and a publication mechanism where a message is targeted at multiple destinations. The security for the communications, for example, are designed to prevent compromised nodes from being used to acquire significant message traffic from the network once the node is compromised. In addition, the network prioritizes real-time data despite variable performance of network links. The network also ensure security by establishing secure routing by using point to point authorizations. The network also strategically caches data flowing in the network so that when channels are available data is sent. In some examples, the mesh network is an improvement over other networks by improved security. The network is designed to overcome unstable communication links and the potential for nodes becoming compromised. The mesh network overcomes potential issues by using security systems that secure messages, secure routes, and secure backfilling of messages that wait to be sent through the network.

In various implementations, the central processing server 107 provides an application programming interface (“API”) by which communications are accomplished with the RF system 102, RF systems 106, user device(s) 110, and/or additional systems or sensors 104. For example, data collected or generated by RF system 102 is sent to the central processing server 107 to be combined with other data collected (e.g., from RF system 106 and/or additional systems or sensors 104) and stored for later transmission to any system on the network 112 or outside of the network 112 (e.g., via the internet and by using an API). In various implementations, the central processing server 107 also implements some or all of the machine learning and/or data or signal processing that the RF systems (e.g., 102 and 106) perform, for example.

### Example User Device(s) 110

The user device(s) 110 comprises computing devices that provide a means for a user or admin to interact with a device (e.g., RF system 102, RF systems 106, additional systems or sensors 104, or central processing server 107). In some examples, user devices 110 comprise user interfaces or dashboards that couple a user with a machine, system, or device, commonly used in industrial processes. In various implementations, user device(s) 110 comprise computer devices with a display and a mechanism for user input (e.g., mouse, keyboard, voice recognition, touch screen, and/or the like). In various implementations, the user device(s) 110 comprise tablet computing devices, laptop computing devices, or smart phones.

As noted above, the user device(s) 110 communicate with the RF system 102, RF systems 106, additional systems or sensors 104, and/or central processing server 107 via direct (e.g., not via a network) wired and/or wireless communications, and/or via a network (e.g., a local network) wired and/or wireless communications. Advantageously, according to various implementations, a user configures an interactive user interface layout, and then push the interactive user interface layout configuration to one or more RF systems 102 and/or 106. In various implementations, the RF systems 102 and/or 106 then provide the configured interactive user interface remotely to any user devices 110 in communication with the RF systems 102 and/or 106. Advantageously, such functionality enables remote and centralized configuration of interactive user interfaces without requiring direct programming or interaction with the RF systems 102 and/or 106 or user device(s) 110. Advantageously, according to various implementations, because connection interface is provided by the RF systems 102 and/or 106, multiple user devices 110 simultaneously access and/or communicate with the RF systems 102 and/or 106, and a current configuration/status of the RF systems 102 and/or 106 is accurately kept synchronized/kept up-to-date from each device and between such devices.

In various implementations, a user operates the RF system 102 (and/or RF systems 106, among other components of the operating environment 100) via one or more user interfaces accessible via device(s) 110 (and/or other user interfaces of the central processing server 107). Via such user interfaces, the user can review and/or set a configuration or status of the RF system 102, can receive indications from the RF system 102 (and/or central processing server 107, which provides coordination among various components of the operating environment 100) of an identified object, provides approval to the RF system 102 (and/or central processing server 107, which provides coordination among various components of the operating environment 100) to begin transmission to an identified object, reviews a battery health of the RF system 102, accesses automated logs associated with the RF system 102 (and/or central processing server 107), and/or the like.

In various implementations, the user devices 110 can comprise relatively streamlined interactive graphical user interfaces. For example, the interactive user devices 110 can comprise relatively few large buttons by which a user can select to stop a currently running configuration, can select a different configuration from a list, can search for a different configuration, and/or can monitor a current status of inputs/outputs, analyses, machine learning models, and/or the like (and as noted above).

Additionally, it has been noted that design of computer user interfaces “that are useable and easily learned by humans is a non-trivial problem for software developers.” (Dillon, A. (2003) User Interface Design. MacMillan Encyclopedia of Cognitive Science, Vol. 4, London: MacMillan, 453-458.) The present disclosure describes various implementations of interactive and dynamic graphical user interfaces that are the result of significant development. This non-trivial development has resulted in the graphical user interfaces described herein which can provide significant cognitive and ergonomic efficiencies and advantages over previous systems. The interactive and dynamic graphical user interfaces include improved human-computer interactions that can provide reduced mental workloads, improved decision-making, improved capabilities, reduced work stress, and/or the like, for a user. For example, user interaction with the interactive graphical user interface via the inputs described herein can provide an optimized display of, and interaction with, video gateway devices or controller devices, and can enable a user to more quickly and accurately access, navigate, assess, and digest analyses, configurations, received/operational data, and/or the like, than previous systems.

Further, any interactive and dynamic graphical user interfaces described herein are enabled by innovations in efficient interactions between the user interfaces and underlying systems and components. For example, disclosed herein are improved methods of receiving user inputs (including methods of interacting with, and selecting, received data), translation and delivery of those inputs to various system components (e.g., RF systems 102 and/or 106), automatic and dynamic execution of complex processes in response to the input delivery (e.g., execution of configurations on RF systems 102 and/or 106), automatic interaction among various components and processes of the system, and automatic and dynamic updating of the user interfaces (to, for example, display the information related to RF systems 102 and/or 106). The interactions and presentation of data via the interactive graphical user interfaces described herein accordingly provides cognitive and ergonomic efficiencies and advantages over previous systems.

### RF Systems 102

The RF system 102 can comprise hardware and software components, and can be a modular, adaptable, and movable system including one or more antennas. The RF system 102 can be configured to receive or capture external RF signals from one or more directions (e.g., the direction(s) the antennas are facing in conjunction with the configured field of view angle), determine one or more RF signals to transmit based on the received RF signals (e.g., by applying one or more machine learning models and determining a type of object), and generate and transmit the determined one or more RF signals in particular directions and with particular powers, among other functionality as described in more detail herein.

In various implementations, in addition to RF system 102, one or more additional RF systems 106 can be provided (e.g., as illustrated in the example operating environment 100 of FIG. 1). Each of the RF systems 106 can generally include similar configurations and functionality as the RF system 102. For example, each of the RF system 102 and RF systems 106 includes similar hardware components and software components and functionality. Each of the RF systems also differ in various ways, for example, each includes one or more module enclosures, and one or more antennas, among other features. The description herein provides details of the implementation of RF system 102, but each of RF systems 106 are similarly implemented.

Although the RF system 102 is shown separately from RF systems 106, in some embodiments, each RF system shown have functionality that is unique to itself (e.g., based on location/placement, particularities of its trained data model that is the same or different than other RF systems, different hardware or software, different ranges of frequencies to monitor due to a configured blacklist or whitelist, or other features) or shared functionality among all RF systems (e.g., a shared machine learning model, shared data inputs, shared blacklist of whitelist, or other features). So, in some implementations, functionality of the RF systems reside on one device or multiple devices. For example, processing of data signals received by one RF system 102 can be performed by the RF system 102 or a combination of the RF system 102 and other RF systems 106. In some implementations, RF system 102 can perform functions unique to the RF system 102, and RF system 106 can perform functions unique to the RF system 106. In some implementations, a combination of features may be available to all RF systems, some features unique to each RF system, and some features that can be shared. In some implementations, there is only be one RF system used and thus all available features or functionality for the single RF system would reside on the single RF system. In some embodiments, additional systems or sensors 104 can provide additional data or functionality to the RF system(s), as described herein. As described above, coordination among the various components of the operating environment 100 can be direct, and/or via the central processing server 107, among other possible configurations.

In various implementations, there are additional RF systems 106 installed in an area associated with or nearby the RF system 102. In various implementations, the RF systems 102 and 106 can be placed in an area and connected together (e.g., in communication via network 112, or hardwire connection). For example, an RF system 102 can be placed on the northeast corner of a building with one antenna that is coupled to RF system 102 facing north and another antenna coupled to RF system 102 facing east. Also, RF system 106 can be placed on the southwest corner of the same building with one antenna coupled to RF system 106 facing south and the other antenna coupled to RF system 106 facing west. Accordingly, the four antennas coupled to the two RF systems (and/or additional RF systems and associated antennas) can monitor a 360° area (or approximately a 360° area) surrounding the building, and at the same time omitting any signal detection coming from the building itself. As a consequence of the orientation, while any of the antennas are transmitting signals, the transmission can be away from the building so that the building and any equipment or personnel in the building are not impacted or affected by any transmissions. The orientation and the signal filtering described herein can further limit interference of friendly areas and equipment in an improved manner.

In various implementations, the RF system is manufactured into a compact, lightweight, movable, and/or adaptable design such that the RF system is placed in a variety of positions and locations. For example, in an implementation, the RF system has a total height (e.g., length) of between about 20 cm and about 180 cm, and have a total weight of between about 10 kg and about 100 kg. Additionally, the antennas are decoupled from the module enclosure of the RF system and swapped with different types of antennas that may provide different functionality (e.g., wider or narrower field of view such as omnidirectional, longer range sensitivity, shorter range sensitivity, and the like) and/or different physical attributes for improved mobility or adaptability depending on the application (e.g., reduced or increased size, different shape, and the like). For example, if the RF system is going to be moved from the roof of a building onto a vehicle, there is the need to use one or more different antennas that are configured to be secured safely to the vehicle while the vehicle is in operation, and satisfy the new requirements associated with the placement at the same time. Such requirements may include being able to monitor a wider field of view than the prior position of being placed on the side of a building, and the wider field of view is achieved with additional antennas and/or different antennas that are configured differently.

### Example Hardware Components of the RF System

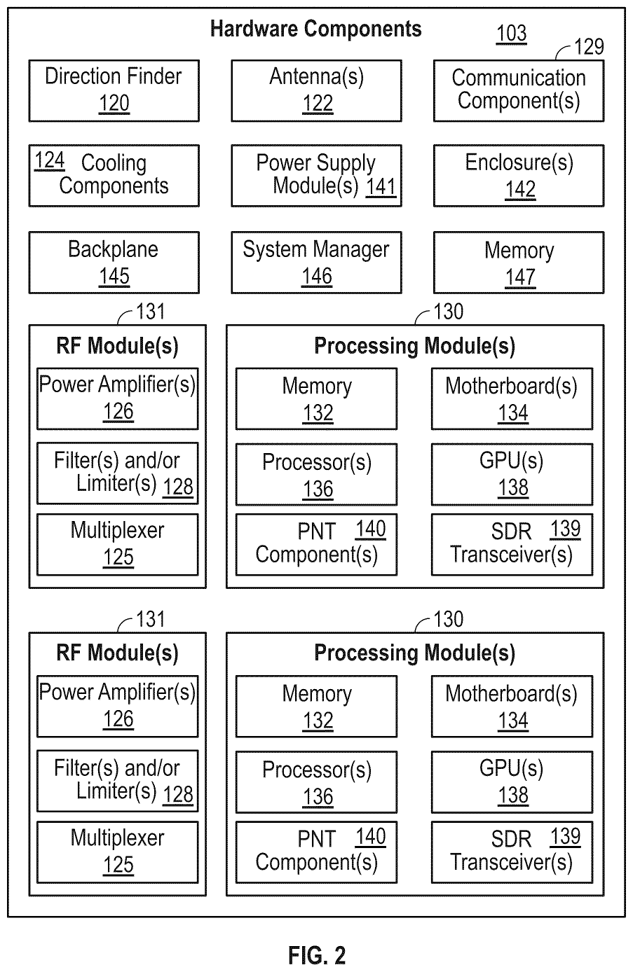

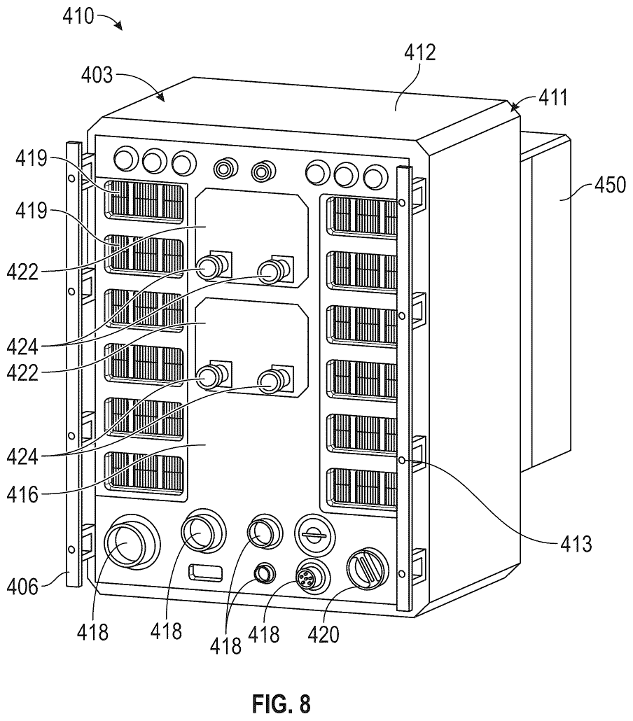

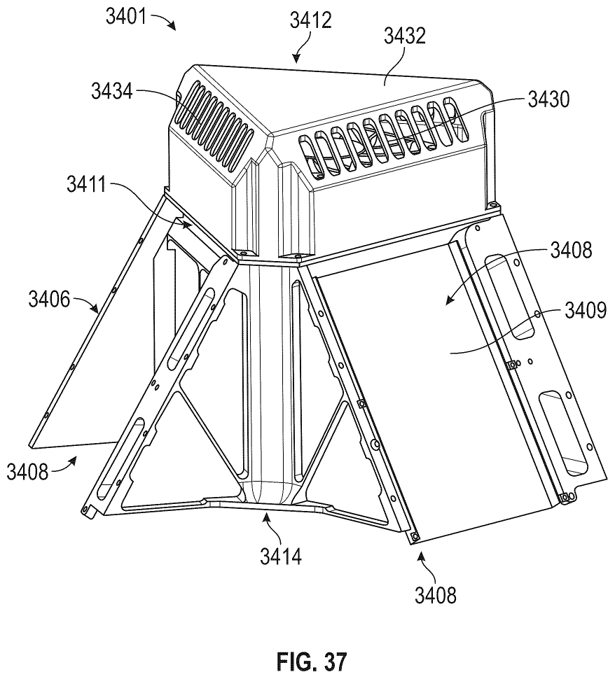

FIG. 2 illustrates a block diagram of example hardware components 103 of the RF system 102, according to various implementations of the present disclosure. In addition to the description below, further details of the hardware components and related functionality are described below in reference to, for example, FIGS. 8-49. The hardware components 103 include for example, a direction finder 120, one or more antennas 122, communication components 129, cooling components 124, one or more power supply modules 141, one or more enclosure components 142, one or more RF modules 131, one or more processing modules 130, a backplane 145, a system manager 146, and memory 147. Software components 105 of the RF system 102 are implemented on various components of the RF system 102, but, according to various implementations, primarily on the one or more processing modules 130, as described herein.

As noted above, the RF system 102 is advantageously modular to enable multiple configurations for various applications. For example, the modularity of the RF system is found in both the modularity of a particular individual RF system that operates on its own (including in coordination with one or more additional systems or sensors), and multiple RF systems that are operated in coordination with one another (including in coordination with one or more additional systems or sensors). The modularity of the RF system is enabled, in part, by the adaptability of the enclosures 142 of the RF system 102, which houses or provides attachments for the various other hardware components 103.

For example, the RF system 102 is implemented with one module enclosure in which any number of processing module(s) 130 (e.g., 1, 2, 3, 4, 5, etc.) and/or RF modules(s) 131 (e.g., 1, 2, 3, 4, 5, etc.) are housed. In an example of an enclosure having four processing module 130 and two processing module 130, the module enclosures of the RF system 102 comprises six slots for receiving the six modules. Accordingly, in an implementation, the RF system 102 includes nine modules of any configuration. In the various implementations, the RF system also includes an adaptable enclosure, and further includes components for mounting the RF system, such as one or more mounts, clips, slides, pins, and/or the like. Advantageously, the RF system, given its modularity, is appropriately configured for a given application, and mounted on a tripod, a vehicle, a building, and/or the like.

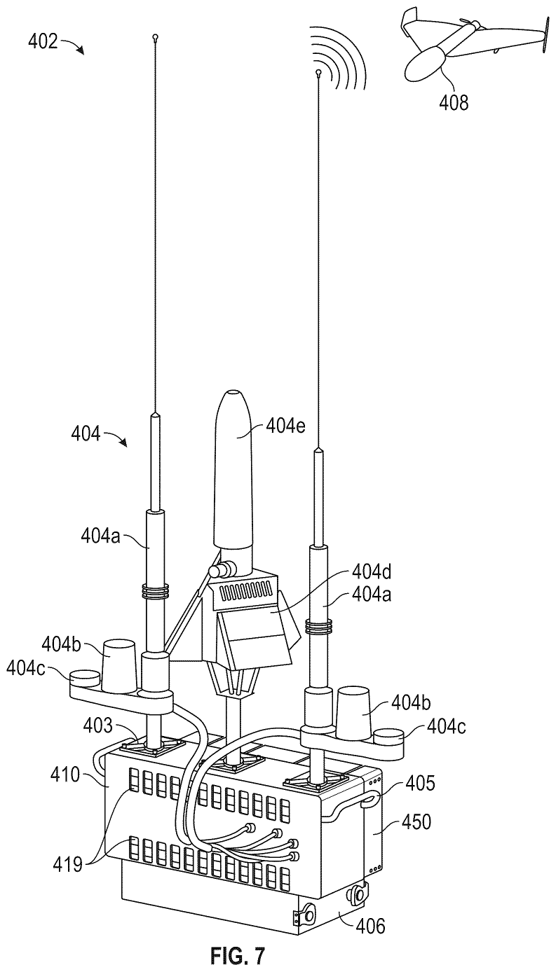

In some examples, the module enclosure comprises one or more processing modules 130, one or more RF modules 131, and one or more power supply modules 141. In various implementations, the processing modules 130 comprise system-on-module (“SOM”) aspects, and are thus referred to herein as “SOM modules”. Each of the module enclosures, and associated processing module(s) 130, RF module(s) 131, and power supply module(s) 141 support an array of antennas 122 (e.g., antennas 404a-404c and HBFE 404d of FIG. 7, which comprises directional and/or omnidirectional antennas) and/or a direction finder 120 (e.g., direction finder 404e of FIG. 7). For example, in an implementation, the module enclosure includes a single processing module 130, two RF modules 131, and a power supply module 141. In this implementation, the RF modules 131 support one or more antennas 122, the processing module 130 supports the two RF modules 131, and the power supply module 141 provides power to the processing module 130 and the two RF modules 131. In the implementations including six or more modules, the multiple processing modules 130 communicate with one another directly to provide the functionality described herein, or communicate with one another via a system management module. Additionally, in any of these configurations, the RF system 102 additionally supports one or more direction finders 120 via one or more components of the module enclosures (e.g., the processing module 130, the RF module(s) 131, and/or the power supply module 141).

The RF system 102 advantageously includes a physical modular configuration that provides physical protection to the components for use in, for example, dirty or extreme environments. For example, each of the enclosures includes an interior space into which the processing module(s) 130, the RF module(s) 131, and the power supply module(s) 141 are placed. The cavities are sealed or hermetically sealed from the outside environment. The enclosures also includes additional cavities for the routing of connections and wiring among the various components. In some examples, these additional cavities are also sealed or hermetically sealed from the outside environment. These various cavities also advantageously provide shielding from electromagnetic interference (“EMI”) for the various components of the RF system 102. EMI shielding is provided, for example, by constructing the cavities of metal and/or other EM shielding materials or components. Additionally, the module enclosure includes vents, grates, filters, or the like to prevent intrusion of sand or other debris into portions of the RF system through which air flows.

Accordingly, in an implementation, each RF module 131 can comprise its own enclosure housing its related components, each processing module 130 comprises its own enclosure housing its related components, and each power supply module 141 comprises its own enclosure housing its related components. Each module's housing can be made of a thermally conductive material, such as metal. Each of these individual enclosures of the various modules are then placed within the cavities of, for example, the module enclosure(s) of the RF system 102. Additionally, the various electrical components of the RF system 102 can be wired for power and data communication with one another via the various cavities. For example, the processing module 130 can be in wired communication with the RF module(s) 131, and the RF module(s) 131 can be in wired communication with the directional antenna(s) 122 and/or direction finder 120. Such data and power wired communications can be accomplished via routing through the cavities of the enclosures, and via connectors on and through surfaces of the enclosures and outside of the enclosures. In some implementations, one or more of the various components of the RF system 102 can in communication with one another through wireless communications.

In addition to the internal power supply modules 141 described above (which can provide appropriate power to the various other modules and components of the RF system 102), the power supply module(s) 141 can also include an external or internal main power supply module that provides main power to the RF system 102. Such power may be from a wired main power source or a battery source. For example, as shown in FIG. 7, the module enclosure 410 of the RF system 402 can include a battery 406. In some implementations, the RF system 102 includes an internal battery power source that provides power to the components of the RF system 102 via the power supply module(s) 141.

### Direction Finder 120

The direction finder 120 (also referred to herein as a radio direction finder or direction finding antenna) comprises a radio direction finder (“RDF”) or other direction finding device, and, in some examples, is a device configured to find or otherwise identify a direction, or bearing, to a radio source. In some examples, the direction finder 120 includes one or more antennas configured to conduct direction finding. Direction finding includes using two or more measurements from different locations. Based on the two or more measurements, the location of an unknown object (e.g., a transmitter, vehicle, drone, and/or the like) or other target is determined. In various implementations, by combining the direction information from multiple sources (e.g., other direction finders in the area, other systems or sensors, or one or more of antennas, and/or the like), the source of a transmission is located (e.g., via triangulation or other similar means).

In some implementations, the direction finder 120 is used to detect any radio source. The size of a receiver antenna of the direction finder 120 is a function of a wavelength of a receiving signal. For example, longer wavelengths (low frequencies) include larger antennas. The ability to locate a position of a transmitter is particularly valuable in various applications, including transmission object location searching and identifying. In some implementations, the direction finder 120 includes one or more phased array antennas to allow more rapid beam forming for more accurate finding. The direction finder 120 includes a sense antenna, a dipole antenna, a parabolic antenna, and/or the like. The direction finder 120 employs one or more of a phase or a doppler technique. In various implementations, a plurality of direction finders 120 obtain direction information from two or more suitably spaced receivers (or a single mobile receiver), the source of a transmission is located via triangulation.

The direction finder 120 communicates with one or more (or all) of the processing modules 130 of the RF system 102 in any given configuration. In various implementations, a plurality of direction finders 120 are coupled to a common processing unit (e.g., processing module 130). As noted herein, in some implementations, the PNT capabilities (e.g., some or part of the PNT components 140) are provided in and/or by the direction finder 120, in whole or in part.

### Antennas 122

The one or more antennas 122 (e.g., omnidirectional and directional antennas) are configured to transmit and/or receive radio signals. As noted above, the antennas 122 are in electrical/wired communication with an RF module 131, which RF module 131 provides signal receipt or transmission amplification, among other functionalities. In various implementations, the antennas 122 are designed to transmit and receive radio waves in all (omnidirectional) or in a particular direction (directional, or high-gain, or “beam” antennas). Some of the one or more antennas 122 are omnidirectional antennas which are configured to transmit and/or receive radio signals across a 360-degree horizontal plane. In various implementations, each of the omnidirectional antennas 122 are in electrical communication with an RF module 131, which RF module 131 provides functionalities such as amplification for signal reception and transmission. For example, in various implementations, omnidirectional antennas are configured to radiate or receive signals evenly in all directions on a horizontal plane, generating a characteristic doughnut-shaped radiation pattern. In some implementations, these antennas include configurations such as dipole designs (e.g., two conductive elements) or collinear arrays, which stack multiple elements vertically to enhance gain while maintaining omnidirectional properties. In various implementations, the antennas 122 also include features such as vertical polarization or elements that enable consistent signal coverage across the horizontal plane. Other configurations are possible, including the use of omnidirectional antennas in combination with directional antennas to address both broad coverage and focused signal requirements. For example, omnidirectional antennas are used for general signal distribution, while directional antennas are used for specific high-gain applications. Various combinations and configurations of the antennas 122 are employed depending on the desired communication objectives.

In some implementations, some of the antennas 122 can be directional (see HBFE 404d of FIG. 7 having directional antennas attached thereto) and can be configured to radiate or receive signals over an area that is between 80 degrees and 110 degrees in a direction the antenna is configured to face (e.g., a primary received and/or transmitting angular arc of the antenna). In some implementations, some of the one or more antennas 122 (e.g., directional antennas) can be configured to provide communications within about a 90° angle, and thus two directional antennas can be configured to provide communications within about a 180° angle, three directional antennas can be configured to provide communications within about a 270° angle, and four directional antennas can be configured to provide communications within about a 360° angle. Other combinations of antennas and various arrangements are possible. For example, some of the one or more antennas 122 can be configured to provide communications within about a 120° angle, and thus two antennas can be configured to provide communications within about a 240° angle and three antennas can be configured to provide communications within about a 360° angle. In various implementations, the antennas 122 can include one or more reflectors (e.g., parabolic reflectors), horns, and/or parasitic elements, which can direct the radio waves into a beam or other desired radiation pattern.

The one or more antennas 122 can be physically positioned and configured to transmit or receive at varying power levels and frequencies in various directions, such that some of the antennas can collectively provide greater directionality and sensitivity in certain direction(s) than in other directions. Advantageously, this can allow for increased performance and reduced interference from unwanted sources (e.g., sources that are not in the direction of the antenna's directionality). For example, the directional antennas of antennas 122 can provide increased performance when greater concentration of radiation in a certain direction is desired. Additionally, the omnidirectional antennas of the antennas 122 can also be configured to operate at varying power levels and frequencies, providing flexible 360-degree coverage. Power adjustments via an RF module 131 can extend range or reduce interference, while varying the antenna gain can optimize performance for specific environments. For instance, higher-gain designs focus energy horizontally for extended range, while lower-gain designs provide balanced vertical and horizontal coverage. Additionally, some of the antennas 122 can be broad-bandwidth antennas that can be used to transmit, receive, or transmit and receive radio signals with a wide frequency spectrum. In various implementations, the antennas 122 can be configured to transmit and/or receive radio signals in a subset of the wide frequency spectrum. For example, there may be nearby equipment that emits signals in a particular frequency range where an antenna is facing and the RF system can be programmed to filter received signals (e.g., with software) so as to not interfere with analysis of received signals and/or filter transmitted signals (e.g., with software or additional digital signal filtering equipment) so as to minimize or remove interference with the operation of the nearby equipment. Accordingly, the RF system may selectively transmit signals of varying powers via the various direction antennas.

In various implementations, each antenna 122 and its associated electronic circuitry (e.g., associated RF module 131) can operate independently as well as in a coordinated way with the other antennas. For example, a directional antenna of the antennas 122 (e.g., HBFE 404d of FIG. 7) can be configured to face and monitor a 120° field of view, and two other directional antennas can be configured to monitor a full 360° (or approximately 360°) field of view. In another example, a directional antenna of the antennas 122 (e.g., HBFE 404d of FIG. 7) can be configured to face and monitor a 90° field of view, and three other directional antennas can be configured to monitor a full 360° (or approximately 360°) field of view.

The antennas can also be configured to comprise automated or manual adjustability with respect to a vertical angle or tilt so that the antenna can face more downwards towards the ground or be adjusted to face more upwards towards the sky. In some applications, there can be an optimum angle that the antenna can adjust to based on empirical data or artificial intelligence/machine learning (e.g., the machine learning models described herein, or other models). Adjustability of the angle of the antennas may be provided by an antenna mount that is user-adjustable. The measured angle of an antenna may comprise an angle of elevation or tilt as compared to a plane the RF system is stationed on (which may be the same as a line perpendicular or normal to a side surface of the RF system on which the antenna is mounted, if the RF system is mounted level). In various implementations, for the RF system 102, the corresponding one or more antennas 122 and associated electronic circuitry can comprise multiple physical configurations. For example, the antennas and associated electronic circuitry can be configured to be detachable and/or stackable so that multiple antennas can be used in one specified location. For example, there may be four antennas at one location, where each antenna is configured to monitor a 90° field of view, for a total field of view of 360° being monitored by the four antennas or an omnidirectional antenna.

### Cooling Components 124, Environmental Protection

The cooling components 124 can be configured to remove heat produced by one or more of the hardware components 103. For example, the cooling components 124 can help avoid temporary malfunction or permanent failure by overheat of power supplies, amplifiers, integrated circuits such as central processing units (“CPUs”) and graphics processing units (“GPUs”), and/or other elements described herein. The other hardware components 103 described herein may be configured to generate little heat, but more heat may still be produced than can be removed without use of the cooling components 124. The cooling components 124 can include one or more fans, one or more heatsinks, one or more thermal couplings, one or more heat pipes or conductors, and/or the like, configured to allow removal of heat from the system. Thus, the RF system can advantageously include a physical modular configuration and materials that efficiently dissipate heat from the components of the system to enable the RF system to operate in high temperature and/or extreme environments.

For example, the enclosure can include fans, and the enclosure and the module enclosure(s) together can provide a cavity or channel for air to flow through the RF system to cool the various components of the RF system. The module enclosures can, for example, include heatsinks within the cavity or channel, and thermally coupled to the processing modules, the RF modules, and power supply modules, over which air can flow as pushed or pulled by the fans to cool the components of the RF system. The fans can cause air to flow into the enclosure, through the heatsinks of one or more module enclosures, and out through the enclosure. Further, each of the modules (e.g., the processing module(s) 130, the RF module(s) 131, and/or the power supply module(s) 141) can internally include various thermal couplings, heat pipes or conductors, and/or the like, to conduct heat to the thermal interfaces and thereby to the heatsinks.

In various implementations, the RF system, including the various components such as the module enclosures, the enclosure, the processing modules, the RF modules, and power supply modules, and/or the antennas can be manufactured to account for and tolerate high temperature and/or extreme environments. For example, specific materials, such as metals, can be used to dissipate heat more quickly. Additionally, for example, each of the processing modules, the RF modules, and power supply modules can include individual housings that can provide additional environmental protection, shock protection, and thermal conductivity for the internal components (e.g., to provide thermal conductivity and heat dissipation to the outside of the individual components). Accordingly, the RF system can advantageously provide shielding of sensitive components from weather, sunlight (e.g., heat), and other external threats that may damage or reduce the efficiency of the equipment (e.g., processor throttling due to high temperatures). As noted above, the RF system can also include EMI protection (e.g., for the various modules of the system).

In various implementations, the cooling components 124 can include liquid cooling elements that use liquid (e.g., water, liquid nitrogen, etc.) to cool other hardware components 103. Use of the cooling components 124 can maintain or increase a clock speed of the elements of the processing module 130 (e.g., a processor 136, a GPU 138).

### Communications Components 129

Communications components 129 can include various components of the RF system 102 that provide or enable communications among the components of the RF system 102, 106, and communications with other systems and sensors. Such communications components 129 can include, for example, wires, optical fibers, transceivers, plugs, jacks, connectors, and/or the like.

Communications components 129 include wiring between the antennas 122 and the respective RF modules 131. Such wiring can include a plug providing an interface to an exterior of the RF system 102, 106, and an associated connector on a wire from an antenna to enable plugging the antenna's wire into the plug to provide electrical communications between the antenna and the RF module. Communications components 129 include similar wiring between the direction finder 120 and one or more of the RF modules 131 and/or processing modules 130 (including wires, plugs, connectors, and/or the like to provide electrical communications). Communications components 129 also include wiring or communications among the RF modules 131 and the processing modules 130, among multiple processing modules 130, and between processing modules 130 and external systems or sensor 104, central processing server 107, and/or user devices 110.

In various implementations, the communications components 129 may include electrical, optical, and/or electromagnetic communication channels. The communications components 129 can include components for communicating with other systems remote from the system. For example, the communications components 129 can include a remote data interface, such as a wireless transmitter.

In various embodiments the communications components 129 may include one or more digital data interfaces to send or receive digital data via a wired or a wireless link. For example, the communications components 129 can include one or more wireless transceivers, one or more antennas, and/or one or more electronic systems (e.g., front end modules, antenna switch modules, digital signal processors, power amplifier modules, and/or the like) that support communication over one or more communication links and/or networks. In some examples, each transceiver can be configured to receive or transmit different types of signals based on different wireless standards via the antenna (e.g., an antenna chip). Some transceivers may support communication via a low power wide area network (“LPWAN”) communication standard. In some examples, one or more transceivers can support communication with wide area networks (“WANs”) such as a cellular network transceiver that enables 3G, 4G, 4G-LTE, or 5G. Further, one or more transceivers can support communication via a Narrowband Long-Term Evolution (“NB-LTE”), a Narrowband Internet-of-Things (“NB-IoT”), or a Long-Term Evolution Machine Type Communication (“LTE-MTC”) communication connection with the wireless wide area network. In some cases, one or more transceivers may support Wi-Fi communication. In some cases, one or more transceivers can support data communication via a Bluetooth or Bluetooth Low Energy (“BLE”) standard. In some examples, one or more transceivers can be capable of down-converting and/or up-converting a baseband or data signal from and/or to a wireless carrier signal. In some examples, the communications components 129 can wirelessly exchange data between other components, such as other portions of the system or another system, a mobile device (e.g., smartphone, a laptop, and/or the like), a Wi-Fi network, WLAN, a wireless router, a cellular tower, a Bluetooth device, and/or the like. The antenna can be capable of sending and receiving various types of wireless signals including, but not limited to, Bluetooth, LTE, or 3G.

The communications components 129, in various implementations, can also comprise aspects of the PNT component 140.

### Processing Module 130

As noted above, each module enclosure 142 of the RF system 102, 106 can include processing modules 130 and RF modules 131 that include electronic circuitry that can be configured to couple to and operate 1, 2, 3, 4, or more individual antennas 122 (e.g., antennas). For example, each processing module 130 can comprise can include memory 132, one or more motherboards 134, one or more processors 136, one or more GPUs 138, one or more software-defined radio (“SDR”) transceivers, and one or more positioning, navigation, and timing (“PNT”) components 140. The processing modules 130 can be configured to receive transmissions from, and provide transmission via, one or more directional antennas. In various implementations, a single module enclosure can be configured with one processing module 130, and can support two antennas, where the antennas 122 can be placed at a single location, or the antennas 122 can be placed a distance apart from each other (e.g., 5, 10, 100 feet apart) and couple to the same module enclosure. For example, one may be placed on the north side of the building facing north, and another may be placed on the east side of the same building facing east. Alternatively, the antennas 122 may be placed at the northeast corner at the same location, with one antenna facing north and the other facing east. In various implementations, two module enclosures joined together in a single RF system can be configured with two processing modules 130, and can support four antennas, where the antennas can be placed at a single location, or the antennas can be placed a distance apart from each other (e.g., 5, 10, 100 feet apart) and be in communication with the same RF system.

As also noted above, each of the processing modules 130 can comprise system-on-module (“SOM”) aspects, and can thus be referred to herein as “SOM modules”. In implementations in which a given RF system 102 includes two or more processing modules 130 (e.g., when the RF system includes two or more module enclosures) the multiple processing modules 130 can communicate with one another directly to provide the functionality described herein, or can communicate with one another via a system management module (e.g., system manager 146) that can provide coordination functionality among the multiple processing modules 130. In implementations that use a system management module, the system management module can provide communications with other external systems or sensors, and can relay those communications to the multiple processing modules 130. In various implementations, the system management module can incorporate components and/or functionality of one or more of the processing modules, such as the PNT components 140. In various implementations, when the RF system 102 includes two or more processing modules 130, one of the processing modules can be manually and/or automatically designated to act as the system management module (and thus no physically separate system management module is present) to provide the coordination and communication functionality described above. The system management module can also be referred to as a system controller module and/or the system management module can comprise a system controller module.

The memory 132 can include non-volatile memory and/or volatile memory. The non-volatile memory may include flash memory or solid-state memory. The memory 132 can store software instructions for implementing operation of the RF system as described herein. The memory 132 can also store the AI/ML model(s) and other information needed for executing the detection of objects, and generation of signals.

The motherboard 134 can be referred to a mainboard, a main circuit board, or some other central processing system. The motherboard 134 can include a main printed circuit board (“PCB”). The motherboard 134 can include various communications interfaces or buses to allow for communications among components of the processing module 130, such as memory 132, one or more processors 136, one or more GPUs 138, one or more SDR transceivers, and one or more PNT components 140. The motherboard 134 can provide connectors for other elements described herein. The motherboard 134 can include significant sub-systems, such as the central processor, the chipset's input/output and memory controllers, interface connectors, and other components integrated for general use.

The one or more processors 136 can include any type of general-purpose central processing unit (“CPU”). In various embodiments, the one or more processors 136 can include more than one processor of any type including, but not limited to complex programmable logic devices (“CPLDs”), field programmable gate arrays (“FPGAs”), application-specific integrated circuits (“ASICs”), or the like.

The one or more GPUs 138 can include any type of specialized electronic circuit that can execute advanced computations that can be executed more slowly, or less efficiently, on a general-purpose processor (or which may not be executable on a general-purpose processor). The GPUs 138 can include fast memory and highly parallel structure to process large blocks of data in parallel. For example, the GPUs 138 can be configured to perform matrix calculation, perform linear algebra calculations, execute Fourier transforms, and/or other advanced calculations, including executing the ML models as described herein. Also, for example, the GPUs 138 can be configured to perform many calculations per second (e.g., 10, 15, 20, 30, or more Tera FLOPS per second). These GPUs 138 can include their own memory and/or processors or may execute instructions stored in the memory 132 and/or as instructed by the processors 136. The instructions can be executed by the processor(s) 136 and/or the GPUs 138. For example, the processor(s) 136 can instruct the GPUs 138 to apply an ML model to sampled RF data to, e.g., determine a type of object, as described herein. Additionally or alternatively, the processor(s) 136 can support in making the calculations and other determinations.

Various aspects and functionality of the processing modules 130 may correspond to aspects of the system described in reference to FIG. 3, and thus the components and functionality described in reference to FIG. 3 may be applicable to the processing modules 130.

The SDR transceivers 139 can comprise circuitry and functionality to produce, modify, detect, sense, or otherwise work with RF signals as described herein. For example, the SDR transceivers 139 can be configured to transmit/receive signals that can be mixed, filtered, amplified, modulated/demodulated, and/or detected using one or more components described herein. As a further example, the SDR transceivers 139 can receive instructions from the processor 136 to generate one or more signals to be transmitted by the RF system (e.g., to target an identified object). Thereafter, the SDR transceivers 139 can generate the signals, which can then be communicated to the RF modules 131 (as appropriate for targeting, and including instructions regarding an amount of power to transmit on any applicable antenna) for amplification and transmission via the antennas 122.

The SDR transceivers 139 can include one or more analog-to-digital (“ADCs”) converters and one or more digital-to-analog converts (“DAC”). For example, received signals (received, e.g., via a directional antenna and RF module, and communicated to the processing module) can be passed through an ADC for further digital domain sampling and analysis, as described herein. Signals to be transmitted may be generated by the SDR transceiver, and passed through a DAC before being communicated to an RF module for amplification and transmission via a directional antenna). In various implementations, the ADCs and DACs may be located elsewhere in the system, e.g., as separate components of the processing modules and/or RF modules.

In various implementations, the RF system, e.g., the processing modules 130, can include PNT capabilities. Such PNT capabilities can be provided by the one or more PNT components 140 that can include, for example, global navigation satellite system capabilities (e.g., global positioning system (“GPS”) capabilities), among other PNT functions. The one or more PNT components 140 may further provide orientation information, altitude information, angle/tilt information, and/or the like. In some implementations, the PNT capabilities 140 can be provided in and/or by the direction finder 120, in whole or in part. The PNT capabilities can also be referred to herein as “positioning capabilities”, and the one or more PNT components 140 can also be referred to herein as “positioning components”, and/or the like. The PNT capabilities of the RF system can be used, for example, in object location determinations and/or tracking, as described herein, because such functionality can be dependent on the position, orientation, tilt, and/or the like, of the RF system (e.g., such that the correct antennas 122, with the correct orientation and tilt, may be used to detect or target an object).

### RF Module 131

Each of the RF modules 131 can include one or more power amplifiers 126, one or more filters and/or limiters 128, and one or more multiplexers 125. As described herein, in various implementations, each RF module 131 can be in communication with one antenna 122 (e.g., directional antenna). Further, each RF module 131 can both receive RF signals via the associated antenna (e.g., directional antenna), and cause transmission of RF signals via the associated antenna. The received signal can be communicated to the processing module 130, with which the RF module 131 is in communication. Similarly, the processing module 130 (via the SDR transceivers 139) can provide signals to the RF module 131 for transmission.

The radio frequency (“RF”) power amplifiers 126 can include amplifiers both for received signals, and for transmission of signals. In various implementations, that system can include multiple signal channels, and thus multiple amplifiers, both for receiving and for transmission. In various implementations, the power amplifiers 126 can drive an antenna, or modify a received signal, such that the output can include improved gain, power output, bandwidth, power efficiency, linearity (e.g., low signal compression at rated output), input and output impedance matching, and/or heat dissipation. In various implementations, the power amplifiers 126 can amplify signals in the radio frequency range between about 20 kHz and about 300 GHz, and/or can include preamplifiers that may precede other signal processing stages.

The one or more filters and/or limiters 128 can provide signal filtering and/or limiting, primarily for received signals, but optionally also for transmitting signals. Filters can include, for example, broadband, narrowband, high-pass, low-pass, notch, and/or other kinds of filters for RF signals. In some implementations, the filters can be configured to reduce noise within a received and/or transmitted RF signal. The limiters can include various circuit elements for limiting the power of signals, e.g., received by the RF system. In general, the RF modules 131 operate in the analog domain (e.g., analog signals are communicated to the RF module from the processing modules/SDR transceivers), but some aspects, in some implementations, can be digital domain (e.g., if ADCs and/or DACs are provided on the RF module, and/or if some filtering and/or limiting is performed by the RF module in the digital domain).

The RF modules 131 can also include multiplexers 125 to provide for receiving and transmitting via the antennas (e.g., directional antennas). For example, a multiplexer 125 of the RF module 131 can switch between receiving RF signal from the antenna (e.g., directional antenna) (and providing the received signal to the processing module) and transmitting an RF signal (received from the processing module) via the antenna (e.g., directional antenna). In various implementations, at least two communications links are provided between the processing module 130 and the RF module 131 to enable receiving and transmitting functionality. In various implementations, the RF system 102 can periodically, intermittently, on demand, rapidly, and/or according to a program, switch between receiving signals and transmitting signals. In various implementations, the RF system may simultaneously receive and transmit signals (e.g., one set of directional antenna and RF module may be receiving, which another set of direction antenna and RF module is transmitting). In various embodiments, the multiplexer can modulate and/or demodulate a signal that is received and/or transmitted.

In various embodiments, the RF system can include one or more FPGAs or ASICs can be used instead of a general-purpose processor, or a specialized digital signal processor (“DSP”) with specific paralleled architecture for expediting operations such as filtering. In various implementations, the RF system 102 can include one or more additional amplifiers and/or other circuit components to provide the functionality described herein.

### Backplane 145

The backplane 145 can comprise a structure that provides physical and electrical couplings, allowing components or modules of the RF system 102 to communicate. The backplane 145 can include a circuit board or framework with pathways for power, data, and/or control signals. The backplane 145 can further includes multiple connectors, such as sockets or pins, configured to hold and interface with modules (e.g., processing modules 130 and/or RF modules 131), enabling installation and removal. The backplane 145 can further be configured for power distribution. For example, the backplane 145 can include power lines to ensure each coupled module and/or component (e.g., antennas 122) receives the appropriate levels of power. Separate power rails can transfer different voltage requirements, such as 3.3V, 5V, or 12V, supporting both digital and analog circuits.

The backplane 145 can also comprise a data bus system that enables data transfer across various modules through parallel and/or serial communication protocols, such as PCIe, USB, or proprietary data lines. The backplane 145 can utilize differential signaling to improve signal integrity in applications with high frequencies. The data bus system can also allow components to exchange data efficiently. Control signal routing within the backplane 145 can perform synchronization and/or timing across components, which can include clock distribution networks, reset lines, and interrupt signals, coordinating operations across the modules. The backplane 145 can include ground planes and shielding to limit electromagnetic interference (EMI) and crosstalk. Ground planes can provide dedicated grounding paths, reducing electrical noise that may interfere with data. In applications requiring flexibility, the backplane 145 can support hot-swappable functionality, allowing components to be inserted or removed without shutting down the RF system 102. For example, hot-swappable can support maintenance and/or upgrades while the system remains active.

The backplane 145 can also comprise supports like stiffeners, mounting brackets, and vibration-resistant connectors, which assist with maintaining connections in conditions with physical stress. The stiffeners can reinforce connectivity and prevent disconnection and/or decoupling in rugged or mobile environments. For system diagnostics and monitoring, the backplane 145 can further include integrated sensors or test points to track temperature, voltage, current, or other operational parameters of the RF system 102. The sensors can support real-time monitoring and early detection of potential issues.

### System Manager 146

The system manager board 146 can be a control module configured to manage, coordinate, and/or monitor the modules (e.g., processing modules 130 and/or RF modules 131), host user interfaces, and/or integrating third-party modules for comprehensive functionality. The system manager board 146 can be the main interface between the various systems and sub-systems of the RF system 102, enabling communication and coordination among the modules. For example, the system manager board 146 can direct all inputs/outputs (I/O) traffic to the appropriate modules and components. In addition to handling real-time communication and operational control, the system manager board 146 can hosts user interfaces for system management, allowing direct interaction and monitoring by users or operators. The system manager board 146 can also support the integration of third-party modules, expanding the system's capabilities and adaptability.

The system manager board 146 can include a microprocessor and/or microcontroller that can manage the operations of the RF system 102. The system manager board 146 can monitor data flow between different controller modules, ensuring that commands and information are relayed accurately. In addition to the central processing unit, the system manager board 146 can include various interfaces and communication protocols. These can include Ethernet, CAN bus, I2C, SPI, and UART, among others. These interfaces can allow the system manager board 146 to couple with a wide range of peripheral devices and other controller modules, facilitating integration and interoperability within the RF system 102. The system manager board 146 can also include memory components (e.g., memory 147), such as RAM and flash storage, to handle the data processing and storage needs of the system.

The system manager board 146 can include power management, which dynamically regulates energy distribution across components, such as the modules, while its fault detection and health diagnostics allow proactive maintenance by identifying and mitigating issues early. The system manager board 146 can ensure that each module receives the appropriate power levels and can also implement power-saving measures.

### Memory 147

The memory 147 can comprise any computer-readable storage medium and/or device (or collection of data storage mediums and/or devices). Examples of data stores include, but are not limited to, optical disks (e.g., CD-ROM, DVD-ROM, and/or the like), magnetic disks (e.g., hard disks, floppy disks, and/or the like), memory circuits (e.g., solid-state drives, random-access memory (RAM), and/or the like), and/or the like. Another example of a data store is a hosted storage environment that includes a collection of physical data storage devices that may be remotely accessible and may be rapidly provisioned as needed (commonly referred to as “cloud” storage).

### Example Software Components of the RF System

FIG. 3 illustrates a block diagram of example software components 105 of the RF system 102 (and/or RF systems 106), according to various embodiments of the present disclosure. The software components 105 can include an RF transmission component, an AI/ML component, a digital signal filtering, an external data system, a tracking component, power controls, and/or raw signal storage. In various implementations, the software components 105 are implemented in one or more of the hardware components 103 of the RF system 102. For example, the software components 105 can be implemented by the processing modules 130 (e.g., may comprise software instructions stored in the memory, and executed by the processor(s), GPU(s), SDR transceiver(s), and/or the like, of the processing modules 130).

In various implementations, the one or more of the software components 105 can comprise executable software instructions, modules, engines, and/or the like, that can communicate with one another to share computer resources to execute various tasks in conjunction with a specific functionality such as: tracking a signal or object, identifying a signal, generating a signal, transmitting a signal, training/sharing/applying an AI/ML model, reducing/increasing power output, or the like. Each task can include one component of the software components 105 or multiple components. In various implementations, functionality can be shared by each of the software components 105. In various implementations, functionality can be shared by some of the software components 105 as well as hardware components (e.g., 103) or other devices and systems.

In general, the software components 105 of the RF system can enable tracking of objects, detecting and/or identifying one or more RF signals captured by a connected and/or coupled antenna, and/or determining and causing transmission of a signal to a tracked object via the one or more directional antennas. For example, software components can implement, e.g., via a machine learning component, machine learning (“ML”) algorithms, artificial intelligence (“AI”) algorithms, ML models, programmed algorithms, and/or the like (generally collectively referred to herein as “AI/ML algorithms”, “AI/ML models”, or simply as “ML algorithms”, “ML models”, and/or the like) that can, for example, implement models that are executed by one or more processors. Having an AI/ML model to identify RF signals can advantageously provide significant improvements as compared to conventional systems because many detected signals may include some level of interference, be relatively weak and hard to detect, or otherwise hard to identify due to other factors. In various implementations, the machine learning component can apply one or more ML models or parameter functions for the detections/identifications. The machine learning component can be configured to apply one or more ML models that can help detect which types of RF signals (e.g., a range of RF signals, particular frequencies or combinations of frequencies, and/or the like) indicate which types of objects.

The AI/ML component (also referred to above as “machine learning component”) can be configured to store, update, and/or apply one or more AI/ML models, programmed algorithms, and/or the like. As is described in greater detail herein, the AI/ML models implemented at the AI/ML component can be, for example, one or more models trained to identify frequencies (or related signal properties), objects, classes or types of objects, or other characteristics of detected objects based on received RF signals emitted from objects. In some implementations, the AI/ML component can also be involved with generating and/or training the one or more AI/ML models. In various implementations, the AI/ML component is performed by one or more of the processors or the GPUs of the processing modules 130.

The one or more ML models can be used to determine an expected RF signal frequency range or additional signal properties based on analysis of received or captured data. In various implementations, signal monitoring criteria or signal identification criteria can be designated by a user, admin, or automatically. For example, the signal monitoring criteria or signal identification criteria can indicate which types of detections to monitor, record, or analyze. By designating specific types of detections, resources (e.g., processing power, bandwidth, and/or the like) can be preserved for only the types of detections desired. Various types of detections are described in more detail herein.

A number of different types of AI/ML algorithms and AI/ML models can be used by RF system. Further, these AI/ML models can be developed, programmed, and/or trained using various methods. For example, certain implementations herein can use a logistical regression model, decision trees, random forests, convolutional neural networks, deep networks, or others. However, other models are possible, such as a linear regression model, a discrete choice model, or a generalized linear model. The machine learning aspects can be configured to adaptively develop and update the models over time based on new input. For example, the models can be trained, retrained, or otherwise updated on a periodic basis as new received data is available to help keep the predictions in the model more accurate as the data is collected over time. Also, for example, the models can be trained, retrained, or otherwise updated based on configurations received from a user, admin, or other devices. Some non-limiting examples of machine learning algorithms that can be used to train, retrain, or otherwise update the models can include supervised and non-supervised machine learning algorithms, including regression algorithms (such as, for example, Ordinary Least Squares Regression), instance-based algorithms (such as, for example, Learning Vector Quantization), decision tree algorithms (such as, for example, classification and regression trees), Bayesian algorithms (such as, for example, Naive Bayes), clustering algorithms (such as, for example, k-means clustering), association rule learning algorithms (such as, for example, Apriori algorithms), artificial neural network algorithms (such as, for example, Perceptron), deep learning algorithms (such as, for example, Deep Boltzmann Machine), dimensionality reduction algorithms (such as, for example, Principal Component Analysis), ensemble algorithms (such as, for example, Stacked Generalization), support-vector machines, federated learning, and/or other machine learning algorithm. These machine learning algorithms can include any type of machine learning algorithm including hierarchical clustering algorithms and cluster analysis algorithms, such as a k-means algorithm. In some cases, the performing of the machine learning algorithms can include the use of an artificial neural network. By using machine-learning techniques, large amounts (such as terabytes or petabytes) of received data can be analyzed to generate or implement models with minimal, or with no, manual analysis or review by one or more people. In some implementations, the algorithms can be programmed based on empirical data (e.g., in addition to, or without, machine learning or artificial intelligence being implemented).

In various implementations, an ML model of the RF system 102 can be trained by: (1) sampling raw signals (e.g., captured from one or more connected and/or coupled antennas), (2) signal annotation (e.g., frequency, time, and intensity), (3) signal filtering, and (4) model training. The trained model can then be applied, by the RF system 102, to received or captured RF signals for identification purposes. For example, in various implementations, application of the trained machine learning model can comprise: (1) raw signal sampling, (2) application of trained model, (3) output of classes and probabilities (e.g., associated with type of objects). Then, for example, the processing module 130 can identify a captured RF signal and/or a type of object based on the (3) output of classes and probabilities. Also, in various implementations, application of the trained machine learning model can comprise the preliminary step of (0) filtering base line signal and/or friendly signals.

In various implementations, sampling raw signals or raw signal (e.g., RF) data can include any form of data sampling. Data sampling, for example, can include a statistical analysis technique used to select, manipulate, and analyze a representative subset of data points to identify patterns and trends in the larger data set being examined. It can enable working with a small, manageable amount of data that can be representative of a larger, unmanageable amount of data. Sampling can advantageously enable analysis of data sets that are too large to efficiently analyze in full or within a desired amount of time. In various implementations, the RF system 102 can sample the raw signal for some period of time (e.g., some number of milliseconds, such as 1 ms, 2 ms, 3 ms, 5 ms, 10 ms, 50 ms, or some other period of time). In various implementations, other, or additional, sampling methods can be employed.

In various implementations, the machine learning model can be configured (e.g., by its training automatically, or manually, or a combination) to monitor a specific subset of frequencies or subset of other wave properties. For example, although the processing module, via signals received from one or more antennas 122, can detect and scan for a set of frequencies, the processing module can limit analysis to a specific subset of frequencies. For example, this can be a consequence of the machine learning model training where certain frequencies are not important or useful and are therefore ignored freeing up processing power to analyze other frequencies. Also, for example, the subset of frequencies can be configured manually if there is friendly equipment in the area emitting certain frequencies that the system doesn't need to identify (e.g., the equipment is already known/identified). In various implementations, each antenna 122 can be operated by the processing module 130 (via one or more RF modules 131) separately, as well where one antenna can monitor one subset of frequencies and another antenna in communication with the same processing module may monitor a second subset of frequencies different from the first subset. For example, this may be implemented if one antenna 122 is facing friendly equipment and another is not. Also, in various implementations, the subset of frequencies can adjust based on the time of the day, week, month, or year. For example, during the day a vehicle can be positioned in front of one antenna emitting a signal at a specific frequency, and the vehicle can move such that it is not in front of the antenna during the night.

In various implementations, the RF system 102 (e.g., via one or more processing modules 130 and/or one or more RF modules 131) can use identified types of objects (e.g., output from the applied machine learning model) to generate one or more new signals and, using one or more of the antennas (e.g., directional antennas), transmit the new signals. The new signals can be transmitted in the direction of the identified signal and/or one or more objects. Accordingly, the RF system 102 can selectively transmit signals of varying powers via the various antennas 122 (e.g., directional antennas). In various implementations, the identified signal corresponds to one or more mobile objects (e.g., vehicle, boat, aircraft, drone, and/or the like), and the transmitted signals can affect communications in the vicinity of the mobile object during transmission. In various implementations, detections and/or identification of objects, or identification of signals corresponding to objects, can be received from one or more other systems or sensors. Generating a signal based on the identified signal can advantageously be beneficial due to increased power efficiency/optimization. For example, instead of transmitting signals in all frequency bands, only signals in a specific frequency or narrow range of frequencies can be transmitted instead, thereby increasing power efficiency and/or signal power to reach father distances. In various implementations, the transmitted signal can be further filtered to limit interference of sensitive friendly systems in the area.

As mentioned above, further details and examples of functionality and operation of the RF system, including, for example, operation of AI/ML algorithms, signal detection, signal generation, and/or the like, are described in the '417 Publication.

The RF transmission component can be configured to cause transmission of RF signals and/or to generate RF signals to be transmitted, as described above and herein. For example, the RF transmission component can be in communication with one or more antennas (e.g., antenna(s) 122 of FIG. 2, such as directional antennas) or other transmitting devices and configured to cause the one or more antennas to transmit RF signals. In various implementations, the RF transmission component can include at least a portion of the SDR transceiver, and/or can provide instructions to the SDR transceiver, including software configured to selectively cause transmission of signals at desired frequencies, intensities, and/or directions. The RF transmission component can further be configured to receive tracking data from the tracking component, such as to transmit RF signals to an object being tracked by the system.

The digital signal filtering component can be configured to filter raw RF signal data collected by the system, e.g., before the RF signal data is provided to the AI/ML component for signal analysis based on a trained AI/ML model. For example, in various implementations, the RF system 102 can remove RF signals from the raw RF signal data collected that can correspond to RF signals associated with friendly equipment, equipment that has been manually or automatically flagged as friendly, or filter raw RF signal data based on a whitelist and/or blacklist (e.g., manually and/or automatically populated). The digital signal filtering component can also be configured to filter raw RF signal data transmitted or emitted by the system. For example, in various implementations, the RF system 102 can remove RF signal frequencies from any generated RF signals (e.g., as transmitted by the RF transmission component or one or more antenna(s) 122) can correspond to RF signals associated with friendly equipment, equipment that has been manually or automatically flagged as friendly, or based on a whitelist and/or blacklist (e.g., manually and/or automatically populated). As the digital signal filtering is mostly accomplished in the digital domain, received signals are typically converted to digital before this filtering, and generated signals are typically converted to analog after this filtering. In some implementations, the filtering described above can be perform in part or in whole in the analog domain. In various implementations, the digital filtering is performed by one or more of the processors or the SDR transceivers of the processing modules 130.

The tracking component can be configured to track detected objects based on identified RF transmissions received from the detected objects. In various implementations, the tracking component can track an identified signal or object (e.g., while the RF system 102 is transmitting or not). In various implementations, the direction finder can provide more accurate tracking as well. For example, the direction finder in conjunction with the one or more antennas 122 can identify a direction where a detected signal is emanating from (e.g., while the antennas 122 are transmitting or not).

In various implementations, there can be other sensors or systems (e.g., and including other RF systems in the area) that can couple to or be in communication with the RF system 102 to provide additional data that can be used to: (1) improve the detections performed by the RF system 102 by using the machine learning models; (2) assist RF system 102 in continuing to track, or begin tracking, an object or signal; and/or (3) generate and transmit, or continue generating and transmitting, a specific signal in the direction of an object, among other functions. For example, if an object or signal is moving from out of range of one antenna 122 coupled a first RF system (e.g., RF system 102) into range of another antenna 122 coupled to a second RF system (e.g., RF system 106), the two RF systems can communicate and hand-off the task (e.g., identifying, tracking, transmitting, and/or the like) being implemented by the first RF system can continue to be performed by the second RF system. In various implementations, the first RF system can shut off and the second RF system can turn on during the transition. In various embodiments, the first RF system and second RF system can stay on and perform the same tasks over a period of time (e.g., 5 second, 1 minute, 10 minutes, and/or the like), or at least until the task is completed and both RF systems stop. In various implementations, the first RF system can reduce the power utilized to implement the task as the second RF system increases power (e.g., there may be a threshold power usage set that limits the total amount of power used by one or both RF systems at one time).

The external data system component can store or retrieve, from any external data storage of external devices, sensors, or systems (e.g., additional systems or sensors 104, central processing server 107, and/or the like), any desired data for implementation in conjunction with the systems and methods of the present technology. For example, AI/ML models, data associated with known objects or classes of objects and/or RF signal characteristics associated with the known objects or classes of objects, data defining signal content to be transmitted to detected and/or tracked objects, and the like, can be stored and/or retrieved via the external data system. In various implementations, the external data system component or associated external data sources or devices can include one or more databases connected to a user device (e.g., device(s) 110), a central processing server (e.g., central processing server 107), one or more RF systems (e.g., RF system 102 and/or RF systems 106), or additional systems or sensors (e.g., sensors 104), for example. In various implementations, the data described above can similarly be stored in a memory of the processing modules, as described herein.

The power controls can be configured for software control of power supplied to any of various components of the system, such as any of the hardware components 103 (e.g., FIG. 2). For example, the power controls can control selective RF transmissions from antennas 122 based at least in part on the power supplied to the antennas 122 (e.g., via RF modules 131) for transmission.

The raw signal storage can store raw RF signals or complex data related to the raw RF signals received by an antenna 122. In various implementations, the raw signal storage can store, for example, raw data corresponding to an analog-to-digital conversion of an RF signal received at an antenna 122, spectrogram data corresponding to the raw data, determined RF signals to be transmitted based on any received RF signals (e.g., as determined by the AI/ML component), or any other type of data structure indicative of a raw RF signal received or transmitted by one or more antennas 122.

In various implementations, each RF system 102 can also include software components for performing over-the-air (“OTA”) (or via electrical hardwire connection) updates of the various software, components, machine learning models or components, and/or the like. For example, the RF system 102 can communicate with the central processing server 107 to receive updates. As another example, if multiple RF systems (e.g., RF system 102 and/or RF systems 106) are installed in an area, it can be beneficial for the RF systems to connect and/or communicate and update each other's machine learning models (e.g., by sending the updated models, or relevant data captured so that each RF system can train based on the additional data) over time so that each RF system has the most up-to-date data or model available. In various implementations, although RF systems (RF system 102 and/or RF systems 106) can be in the same area, it may be beneficial to only share portions of data or machine learning models between the RF systems since there may be subtle differences between each RF systems field of view that may result in one model being better suited for a first environment/area than another model that is better suited in a second environment/area.

### Example Implementation of RF Systems

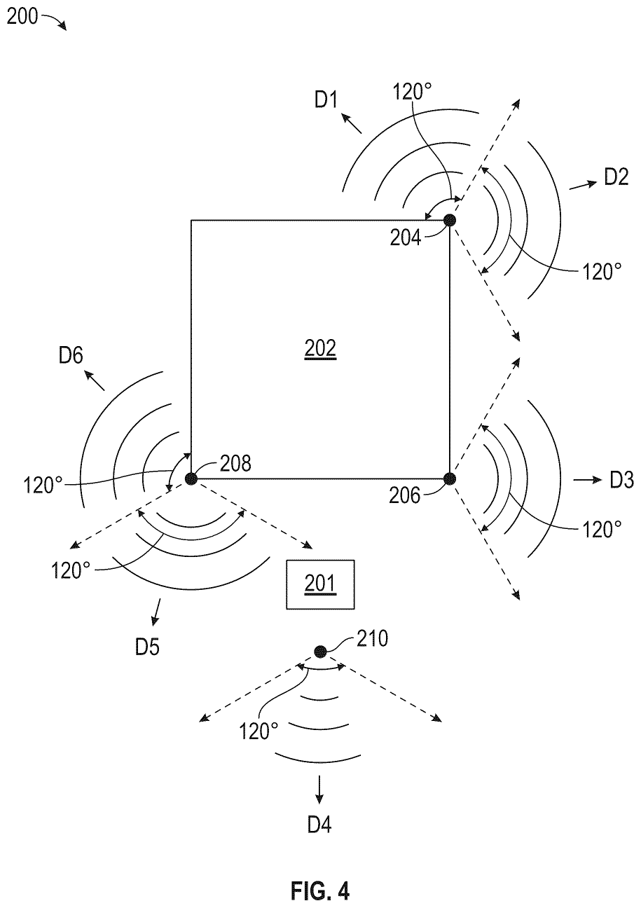

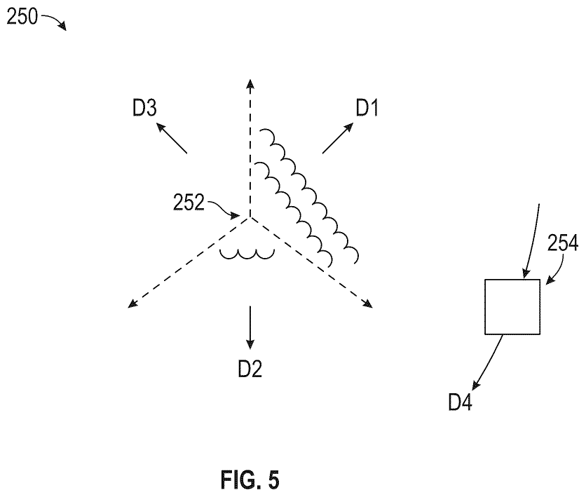

FIGS. 4 and 5 illustrate example implementations and orientations of one or more RF systems (e.g., RF systems 102 and/or 106) in operation, according to various implementations of the present disclosure.

FIG. 4 illustrates an example implementation and orientation 200 of a plurality of RF systems (e.g., RF systems 102 and/or 106) utilizing directional antennas (see HBFE 404d of FIG. 7 having directional antennas attached thereto). In FIG. 4, the plurality of RF systems 204, 206, 208, and 210 can be placed surrounding a building or area 202 such that corresponding directional antennas coupled to the RF systems can face directions away from locations that can comprise sensitive equipment or is otherwise designated as a protected area to be omitted from monitoring by the RF systems. Although FIG. 4 shows one arrangement, any number of arrangements can be devised for each site where RF systems are deployed/installed. For example, placement of each RF system, hardware components (e.g., hardware components 103) or software components (e.g., software components 105) of each RF system, the type of data being shared between the RF systems, the areas or buildings to omit from the antennas'fields of view, and other criteria can vary for each site such RF systems are to be deployed in.

Additionally in FIG. 4, the RF systems (e.g., RF systems 204, 206, 208, and 210) are shown with a high-bandwidth frequency extender having 1-2 directional antennas attached thereto corresponding to each RF system. For example, RF systems 204 and 208 are shown being installed either on the roof of building 202, adjacent building 202, or on one of the side walls of building 202. The RF systems 204 and 208 also correspond to two antennas each having an HBFE, with each antenna facing a particular direction with a 120° field of view. For example, RF system 204 has one antenna facing D1 and a second antenna facing D2, both with a 120° field of view. Also, for example, RF system 208 has one antenna of an HBFE facing D5 and a second antenna of the HBFE facing D6, both with a 120° field of view. The RF systems 206 and 210 also correspond to two antennas each, with each antenna facing a particular direction with a 120° field of view. For example, RF system 206 has one antenna facing D3, and RF system 210 has one antenna of an HBFE facing D4, both antennas having a 120° field of view. In various implementations, for example, RF system 204 may have 1 antenna with 240° field of view, or 3 antennas with a 80° field of view, or other similar combinations, to have the same overall field of view achieved by the two antennas shown. In various implementations, RF systems (e.g., 204, 206, 208, and 210) can include any number of antennas (e.g., 1, 2, 3, 4, 5, 6, and/or the like), and antennas facing specific direction(s) can be turned on or off based on software instructions, orientation relative to sensitive equipment, orientation relative to other RF systems, customized preferences (e.g., based on the terrain or surrounding area), detected objects in the vicinity, or the like.

Advantageously, the RF systems (e.g., RF systems 204, 206, 208, and 210) and their corresponding antenna(s) are arranged such that the building 202 and area 201 (e.g., which may be another building, temporary building, stationary vehicle, or other friendly or sensitive equipment, or the like) are located outside of the antennas'fields of view. In various implementations, data can be transmitted between the RF systems such that detections (e.g., training or application of a machine learning model), tracking, and/or transmissions can be coordinated, for example.

FIG. 5 illustrates an example implementation and orientation 250 of an RF system 252 interacting with an object 254, according to various implementations of the present disclosure. In FIG. 5, an RF system 252 can be placed in a location (e.g., near or on a building or area). In various implementations, a high-band frequency extender (see HBFE 404d of FIG. 7) having several surfaces in which multiple antennas (e.g., one or more antennas facing similar directions) are disposed facing various directions can be used to cover a surrounding area. For example, FIG. 5 shows a HBFE of the RF system 252 including at least three antennas facing directions D1, D2, and D3. Although FIG. 5 shows one arrangement, any number of arrangements can be devised where a HBFE of an RF system can include any number of antennas (e.g., 1, 2, 3, 4, 5, 6, and/or the like) facing specific directions, and antennas facing said specific direction(s) can be turned on or off based on software instructions, orientation relative to sensitive equipment, orientation relative to other RF systems, customized preferences (e.g., based on the terrain or surrounding area), detected objects in the vicinity, or the like. The antennas of the HBFE are also shown with at least a 60° field of view. In various implementations, for example, RF system 252 may have four antennas with 90° field of view, or 8 antennas with a 45° field of view, or other similar combinations, to have the same overall field of view achieved by the three antennas shown. Also, for example, placement of the RF system 252, hardware components (e.g., hardware components 103) or software components (e.g., software components 105) of the RF system 252, the type of data being shared between the RF system 252 and other RF systems or devices/sensors (e.g., 104), areas or buildings to omit from any of the antennas'fields of view, and other criteria can vary for the RF system 252.

Furthermore, in FIG. 5, object 254 is shown moving in direction D4 from an area covered by a first antenna facing direction D1 towards an area covered by a second antenna covering direction D2. In various implementations, power can be provided to the first antenna to improve the first antenna's performance related to receiving/transmitting RF signals in direction D1 while object 254 is in the area covered by the first antenna. As the object 254 moves along direction D2 into the area covered by the second antenna, power can be diverted from the first antenna to the second antenna so that the RF system 252 can continue to effectively receive/transmit RF signals in relation to the object 254. In various implementations, power can be ramped down for the first antenna (e.g., ⅔ power signals shown in the direction D1 corresponding to the first antenna) and simultaneously ramped up for the second antenna (e.g., ⅓ power signals shown in the direction D2 corresponding to the second antenna). In various implementations, power can be binary, and the first antenna can be turned off as the second antenna turns on. In various implementations, the power for each antenna, based on movement of an identified/tracked object (e.g., object 254) can be controlled by one or more computing processing modules of the RF system 252 (or one or more RF systems) such as those described herein so that performance can be optimized (e.g., based on velocity of the identified/tracked object, distance of the identified/tracked object as compared to the RF system doing the tracking, properties of the tracked signal (e.g., strength, wavelength, frequency, or the like), or the like). Additionally, in the example shown in FIG. 5, a third antenna facing direction D3 is shown as being deactivated or turned off since the object 254 is not in the area covered by the third antenna or fourth antenna. In various implementations, all antennas can be turned on or off at the same time as well.

In another example arrangement not shown in a figure, a first RF system can be placed on the northeast corner of a building with one antenna of the HBFE facing north and another facing east. Also, a second RF system can be placed on the southwest corner of the same building with one antenna of a second HBFE facing south and the other facing west. Accordingly, the four antennas coupled to the two RF systems (and/or additional RF systems and associated antennas) can monitor a 360° area (or approximately a 360° area) surrounding the building, and at the same time omitting any signal detection coming from the building itself. As a consequence of the orientation, while any of the antennas are transmitting signals, the transmission can be away from the building so that the building and any equipment or personnel in the building are not impacted or affected by any transmissions. The orientation and the signal filtering described herein can further limit interference of friendly areas and equipment in an improved manner.

In another example arrangement not shown in a figure, an HBFE of a RF system having three antennas radially positioned about a center axis of the HBFE can provide hemispherical coverage. Accordingly, the three antennas of the HBFE coupled to the RF system can monitor a 360° area (or approximately a 360° area), allowing for effective and continuous surveillance of the surrounding area in the horizontal and vertical plane. Each antenna can be placed at an equal angular distance from the others around the center, ensuring minimal overlap and interference while maximizing coverage. This radial positioning allows each antenna to monitor a specific segment of the environment, collectively covering the entire circumference. The RF system can thus receive and transmit signals across all directions in the plane, ensuring that no single point within the hemispherical field is left unmonitored. For example, the RF system can dynamically track a moving target within its coverage area by seamlessly switching between the antennas as needed. As the target moves from one antenna's coverage zone to another, the system can automatically reassign the tracking function to the next antenna, allowing for continuous monitoring without any interruptions. This adaptive switching between antennas of the HBFE also optimizes signal quality and accuracy, as the system can prioritize the antenna that provides the strongest, most reliable signal for a given target's location. This functionality can enable the system to maintain continuous contact with a target, and also to adjust its response in real-time, enhancing the reliability and robustness of tracking.

This setup can be advantageous for applications where constant coverage in all directions is desired, such as in radar, surveillance, and communication systems. Additionally, the hemispherical coverage provided by the three antennas allows for enhanced reliability, as signals received from multiple directions can be analyzed together to improve accuracy and mitigate signal loss. By coupling each of the three antennas of the HBFE to the RF system, signal processing algorithms can combine input from each antenna to provide a seamless, comprehensive picture of the monitored area, further supporting robust and high-resolution hemispherical coverage.

Advantageously, any number of other arrangements (in addition to the examples provided above) of one or more RF systems, and one or more antennas per HBFE of the RF system, are possible with the modular and configurable RF system of the present disclosure.

### Additional Example Hardware-Related Features and Functionality

The description of FIGS. 7-31 below provides further details regarding implementations, components, and related functionality of the radio frequency (RF) system. While different numerals may be used to describe the various aspects of the RF system as compared to the foregoing description, it is to be understood that similar aspects and components may include similar or the same functionality. Thus, aspects described above may be applied to aspects described below, and vice versa.

### RF System

FIG. 7 illustrates a perspective view of an example implementation of the radio frequency (RF) system 402 interacting with an object 408, according to various implementations of the present disclosure. The RF system 402 can comprise hardware and software components, and can be a modular, adaptable, and/or movable system including one or more antennas. The RF system 402 can receive or capture external RF signals from one or more directions, determine one or more RF signals to transmit based on the received RF signals (e.g., by applying one or more machine learning models and determining a type of object), and generate and transmit the determined one or more RF signals in particular directions and with particular powers, among other functionality as described in more detail herein. The RF system 402 can include mounting surface 403, antennas 404, handles 405, battery 406, and a module enclosure 410. Furthermore, in FIG. 7, as object 408 moves in a direction, the various antennas 404 are able to detect and transmit/receive signals in the direction of the object 408. As mentioned above, and in various implementations, power to the antennas 404 can be dynamically monitored to effectively receive/transmit RF signals in relation to the object 408. For example, power can be ramped down for some antennas and simultaneously ramped up for other antennas depending on the flight path and distance of the object 408. In various implementations, power can be binary, and some antennas can be turned off as the other antennas turns on. In various implementations, the power for each antenna, based on movement of an identified/tracked object (e.g., object 408) can be controlled by one or more computing processing modules of the RF system 402 (or one or more RF systems) such as those described herein so that performance can be optimized (e.g., based on velocity of the identified/tracked object, distance of the identified/tracked object as compared to the RF system doing the tracking, properties of the tracked signal (e.g., strength, wavelength, frequency, or the like), or the like).

As illustrated in FIG. 7, the module enclosure 410 of the RF system 402 can be a main housing of the RF system 402. As shown, the antennas 404 can be mounted to outside (or exterior) surfaces of the module enclosure 410 by one or more coupling points, or antenna mounts, and/or antenna mounting surfaces 403. Each of the one or more antenna mounts can provide one or more degrees of freedom. Each degree of freedom can reflect an ability of the respective antennas to tilt, rotate, or translate along one or more axes. The mounting surface 403 can be on a top surface, a bottom surface, and/or side surfaces of the module enclosure 410, but a mounting surface 403 can be disposed elsewhere. The mounting surface 403 can be configured to mount to another modular assembly and/or to a mount, such as a tripod or other mounting system. The module enclosure 410 can also include a handle 405 for transporting the RF system 402.

The module enclosure 410 can include one or more fans 450 one a first side of the module enclosure 410 to enable or promote air flow within the module enclosure 410. The fans 450 can be coupled to the module enclosure 410, which promote the flow of air from the fans 450, through an interior space 414 (e.g., a cavity) of the module enclosure 410, and out through one or more air vents 419 on a second surface of the module enclosure 410. Modules located within the interior space 414 of the RF system 402 can include one or more heatsinks within channels that may be thermally coupled to heat-generating components of the modules. The fans 450 can force air through the module channels to dissipate heat transferred to the heatsinks. The RF system 402 can also include one or more mounting surfaces 403.

As shown in FIG. 7, The RF system 402 can also include a variety of antennas 404. For example, the antennas 404 of the RF system 402 can include low-band antennas 404a that operate at lower frequencies, typically within the HF to VHF range (roughly 3 MHz to 300 MHz). The low-band antennas are capable of long-range communication and high penetration through obstacles, such as buildings, trees, or even water. Low-band antennas are often large and less directional, as their wavelengths are relatively long. The antennas 404 can further include mid-band antennas 404b, which cover the frequency range generally from 300 MHz to 3 GHz, which includes the UHF and lower portion of the SHF spectrum. These antennas can be used for moderate ranges with better data rates than low-band frequencies. Mid-band antennas can be medium-sized, with designs that can range from omnidirectional to semi-directional, providing versatile deployment options across various applications. The antennas 404 can also include GNSS (Global Navigation Satellite System) and alternative navigation (Alt-Nav) antennas 404c which operate within a specific subset of mid-to-high frequencies dedicated to navigation and positioning, typically between 1 GHz and 2 GHz. The GNSS/Alt-Nav antennas 404c can be configured for receiving precise positioning signals from global satellite systems like GPS, Galileo, GLONASS, and BeiDou. GNSS/Alt-Nav antennas 404c can be compact, highly sensitive, and optimized for stable signal reception. The RF system 402 in FIG. 7 can also include a high-band frequency extender (HBFE) 404d having one or more antennas one each exterior surface of the HBFE, operating in the higher SHF and even EHF bands (above 3 GHz, often up to 30 GHz or beyond), to extend communication capabilities to high-band frequencies. The HBFE 404d can be configured for high-data-rate applications, such as satellite communications, radar, and advanced wireless systems like 5G. High-band antennas, such as HBFE 404d, can be compact but directional. Lastly, the antennas 404 can comprise a direction finder (DF) antennas 404e, which can be configured to determine the direction of incoming signals. The DF antenna 404e can operate across a wide range of frequencies. The DF antenna 404e can be directional and arranged in an array to enable triangulation and direction-finding. The antennas 404 can be mounted to outside (or exterior) surfaces of the module enclosure 410 by one or more coupling points or antenna mounts. Each of the one or more antenna mounts can provide one or more degrees of freedom. Each degree of freedom can reflect an ability of the respective antennas to tilt, rotate, or translate along one or more axes.

### Module Enclosure

FIG. 8 illustrates a front perspective view of an example module enclosure 410 of the RF system 402, according to various implementations of the present disclosure. The module enclosure 410 can include an outer shell 412. The outer shell 412 can define an interior space 414 in which various hardware components can be inserted. The module enclosure 410 can be a housing configured to enclose or house one or more of the hardware elements described herein or other hardware components that may benefit from the described configuration. A cover plate 416 can couple to the module enclosure 410 and can seal and/or protect the interior space 414 of the module enclosure 410 from the operating environment. The module enclosure 410 can protect internal elements of the RF system 402 from harsh weather conditions, environmental hazards, wildlife interference, electromagnetic interference (“EMI”), and the like. The module enclosure 410 can generally comprise a shape of a portion of a rectangular prism (e.g., as shown in FIG. 8). The module enclosure 410 can comprise one or more regular shapes and/or irregular shapes. The module enclosure 410 making up the main housing of the RF system 402 can generally be comprised of rigid or strong material, such as metal. The main housing can be comprised of aluminum, but can also incorporate aspects made of other materials, such as plastic or rubber. The main housing can be made of a material, or include coatings, to generally protect internal components from EMI, weather, and/or other adverse conditions. The module enclosure 410 can further include one or more mounting surfaces 403. The mounting surface 403 can be on a top surface, a bottom surface, and/or side surfaces of the module enclosure 410, but a mounting surface 403 can be disposed elsewhere. The mounting surface 403 can be configured to mount to another modular assembly and/or to a mount, such as a tripod or other mounting system. The module enclosure 410 can also include a handle 405 (see FIG. 7) for transporting the RF system 402.

The cover plate 416 can be removable coupled to the module enclosure 410. The cover plate 416 can seal the module enclosure 410 from an external environment (e.g., operating environment 100). For example, the interior space 414 can be sealed (e.g., liquid sealed, fluid sealed) by the cover plate 416. The interior space 414 can, for example, house system modules and components. The cover plate 416 can include at least one external interface 418 (e.g., attachment pointes) for attaching external devices (e.g., antennas, power cables, ethernet cables, etc.). The cover plate 416 can further include one or more closures 420 for accessing the interior space 414 of the module enclosure 410. The closures 420 can be integrated into the cover plate 416. The closures 420 can be movable between an open and closed position to provide access to the interior space 414 of the module enclosure 410 without removing the cover plate 416. The at least one external interface 418 and/or closures 420 can be located on an outer surface of the cover plate 416. The external interface 418 can include various types of attachment points. For example, the external interfaces 418 can include a plurality of attachment points for securely connecting external devices comprising of antennas (e.g., antennas 404, which can comprise both directional and omnidirectional antennas), sensors, and/or communication modules to the module enclosure 410. Also as shown in FIG. 8, the cover plate 416 can also include one or more air vents 419 (e.g., openings). These vents 419 facilitate the movement of air to and/or from the interior space 414 to the external environment, helping to dissipate heat generated by components housed within the module enclosure 410. Advantageously, by allowing warm air to exit the interior space 414, the vents 419 can maintain a lower internal temperature and protect the electronic components of the RF system 402 from overheating.

In some implementations, the module enclosure 410 can include a multiplexer (MUX) 422 (similar and/or identical to the multiplexers 125 described above) configured to combine signals from multiple modules (e.g., power amplifiers) for selective transmission of the signals to the antennas. For example, the multiplexer 422 can switch between receiving RF signal from the directional antenna (e.g., HBFE 404d) (and providing the received signal to a processing module) and transmitting an RF signal (received from the processing module) via the directional antenna. The MUX 422 can include a multiplexer (MUX) interface 424. The MUX interface 424 can enable selective signal routing from various sources to designated outputs or components inside the module enclosure 410. Based at least on system needs, the MUX interface 424 can function as either an analog or digital multiplexer, handling continuous high-frequency signals and/or discrete data signals. Controlled by onboard processing, the MUX interface 424 can dynamically switch channels to adapt to operational demands without physical reconfiguration. To ensure signal integrity, the MUX interface 424 can include buffering, amplification, and filtering components that counteract signal loss and reduce interference, supporting reliable and efficient signal distribution across complex systems. In some implementations, at least two communications links are provided between the processing module and the RF module to enable receiving and transmitting functionality. In various implementations, the RF system may periodically, intermittently, on demand, rapidly, and/or according to a program, switch between receiving signals and transmitting signals. In some implementations, the RF system can simultaneously receive and transmit signals (e.g., one set of directional antenna and RF module may be receiving, which another set of direction antenna and RF module is transmitting). In some implementations, the MUX 422 can modulate and/or demodulate a signal that is received and/or transmitted.

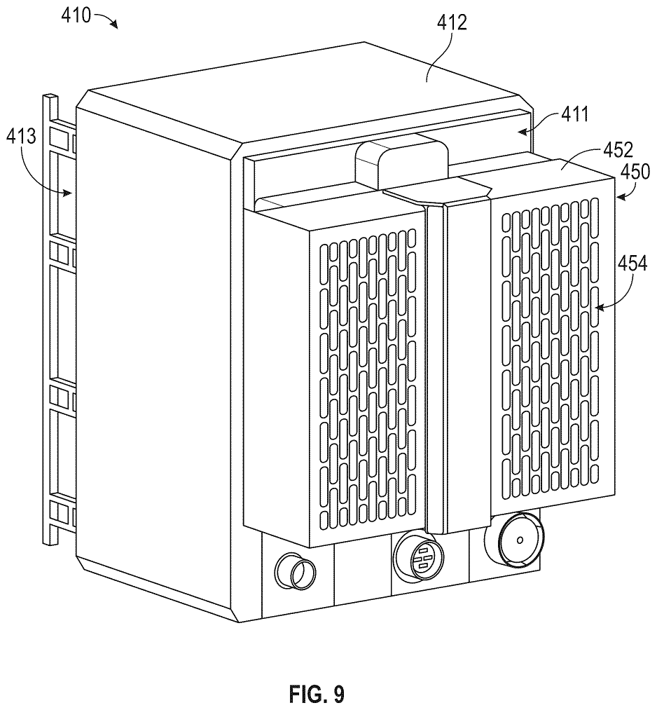

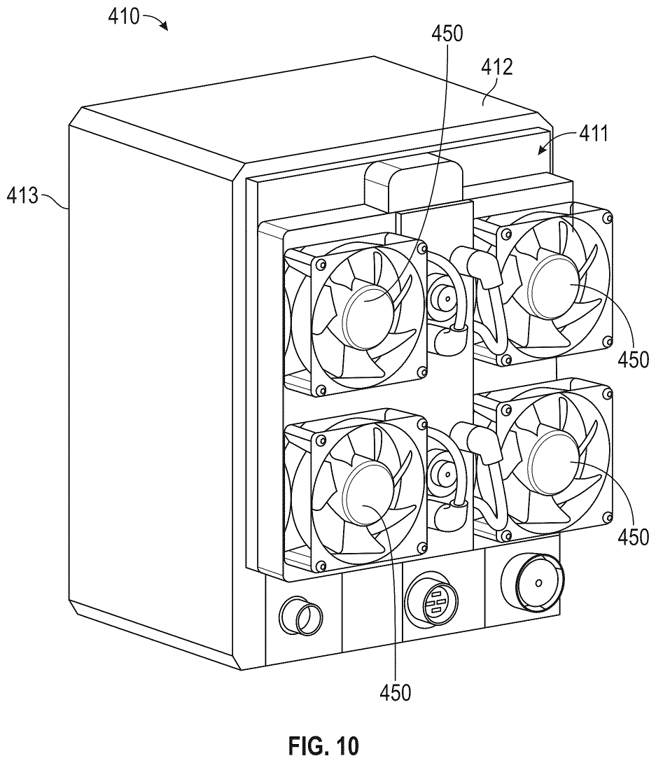

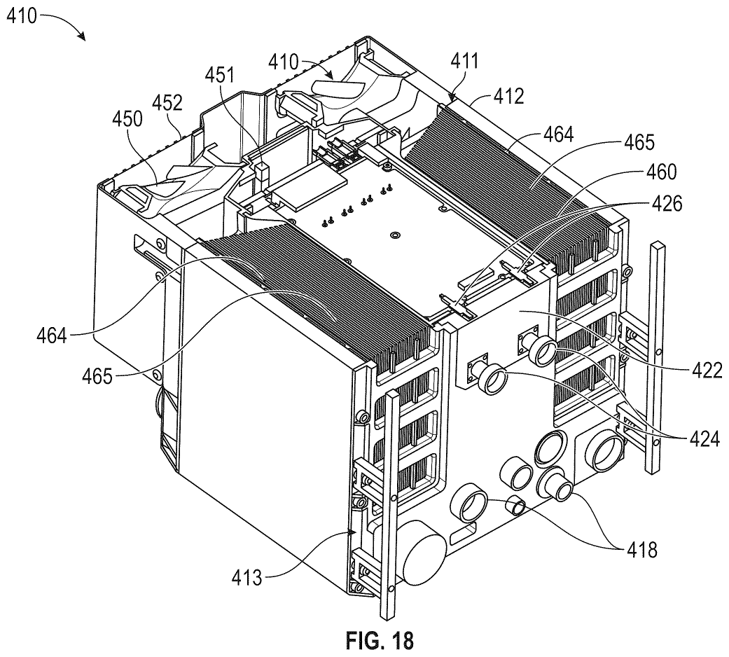

FIG. 9 illustrates a back perspective view of an example module enclosure 410 of the RF system 402, according to various implementations of the present disclosure. FIG. 10 illustrates a back perspective view of an example module enclosure 410 of the RF system 402 without the fan cover 452. As shown in FIGS. 9 and 10, the RF system 402 can further include one or more fans 450 (e.g., cooling fans) coupled to a first side 411 of the module enclosure 410. The fans 450 can also cause air to be flowed into the interior space 414 of the module enclosure 410. The air can exit the interior space 414 of the module enclosure 410 through the second side 413 of the module enclosure 410. The second side 413 can be opposite from the first side 411. The fans 450 can cause air to flow from the first side 411 of the module enclosure 410 to the second side 413 (e.g., pushing air into the module enclosure 410) and through the one or more air vents 419. For example, the fans 450 can create a positive pressure system (e.g., fans blow air into the interior space 414 of the module enclosure 410). Additionally, the fans 450 can also cause air to flow from the second side 413 through the one or more air vents 419 to the first side 411 (e.g., drawing in air into the module enclosure 410). The fan 450 can provide a variable airflow rate, allowing the RF system 402 to adapt dynamically to the thermal demands of the hardware housed within the interior space 414. The fan 450 can include a motor with adjustable speed control to vary the airflow based at least on thermal requirements of the hardware disposed within the interior space 414. The fans 450 can be configured to draw air into the module enclosure 410. In some implementations, the fans 450 can be coupled to a thermal management controller 451 (e.g., a fan controller) (see FIG. 18) that adjusts fan speed in response to real-time temperature readings within the module enclosure 410, ensuring efficient and adaptive cooling.

To protect the fans 450 from external debris and accidental contact, a fan cover 452 can be mounted over them. The fan cover 452 can be constructed from a durable, heat-resistant material with a perforated design to allow unrestricted airflow while also shielding the fans from dust and foreign particles. Additionally, the fan cover 452 can include fasteners for accessing the fans 450. The fan cover 452 can also include an integrated, removable fan filter 454, which can trap debris (e.g., fine particles) before they reach the fans 450, thereby reducing dust accumulation on the blades of fans 450 and within the fan cover 452. The removable fan filter 454 helps prevent blockages that may impair the efficiency of fans 450, which can extend their operational lifespan and improving the overall reliability. The filter 454 can be removed for cleaning or replacement, reducing downtime and maintaining consistent airflow quality.

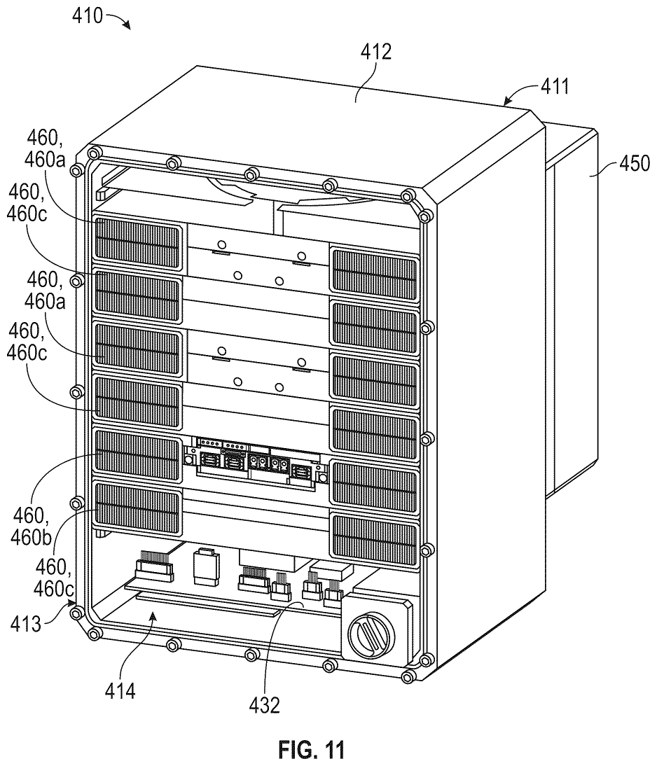

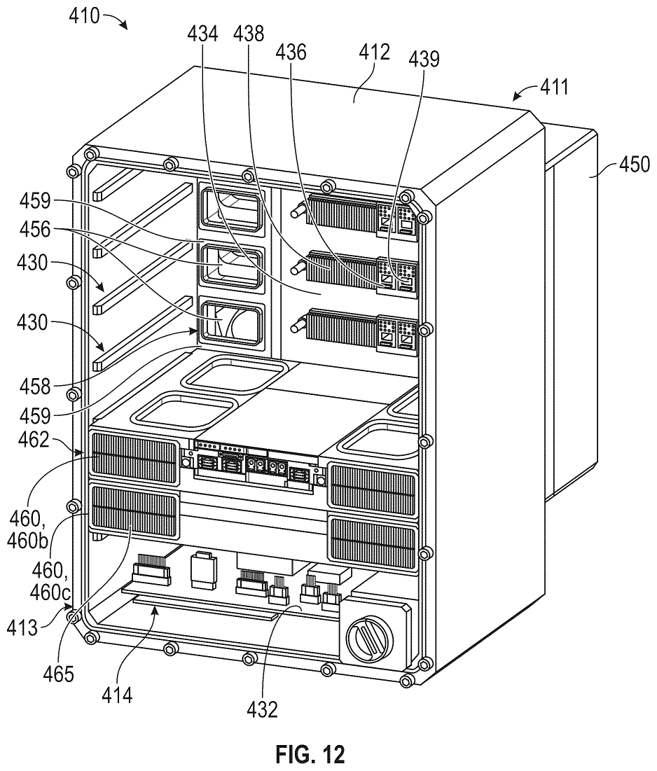

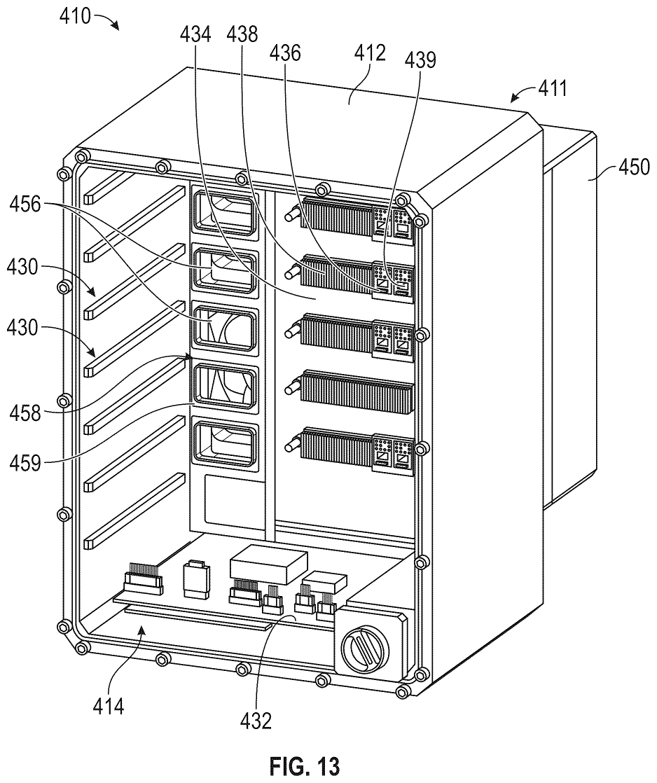

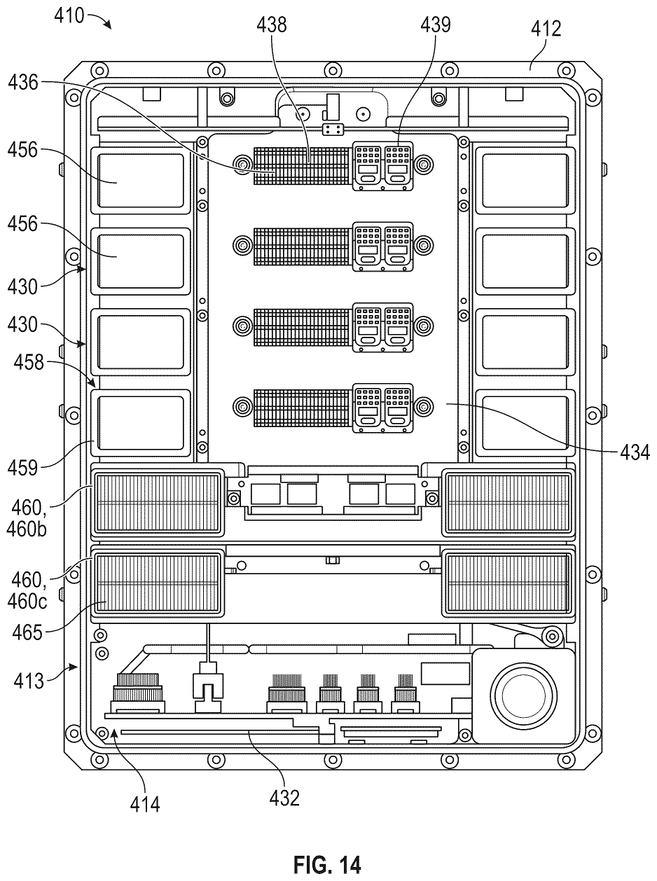

FIG. 11 illustrates a front perspective view of the example module enclosure 410 of the RF system 402 with the cover plate 416 removed, according to various implementations of the present disclosure. FIG. 12 illustrates a front perspective view of the example module enclosure 410 of the RF system 402 with the cover plate 416 and some of modules 460 removed. FIG. 13 illustrates a front perspective view of the example module enclosure 410 of the RF system 402 with the cover plate 416 and the modules 460 removed. FIG. 14 illustrates a front view of the example module enclosure 410 of the RF system 402 with the cover plate 416 and the modules 460 removed. As shown in FIG. 11, a plurality of modules 460 can be disposed (e.g., inserted, slotted, positioned, housed, etc.) within the interior space 414 of the module enclosure 410. The module enclosure 410 can include a plurality of slots 430. Each slot 430 can be configured to receive a corresponding module 460 via the second side 413. Each slot 430 can include alignment guides (e.g., rails) within each slot 430 for positioning and insertion and/or removal of the corresponding module 460. 460abc

The modules 460 can be configured for various types of modules. For example, the modules 460 can comprise modules 460a-460c, which can include a RF module 460a, a SOM module 460b, and a power supply module 460c. Other modules are possible. The description below that references particular modules and aspects of the RF system 402 can understood to similarly apply to other implementations of those modules and aspects. RF module 460a can include, for example, an amplifier and/or a multiplexer (e.g., the MUX 422). The RF module 460a can be in communication with and/or otherwise coupled to a corresponding directional antenna 404 (see HBFE 404d of FIG. 7). The RF module 460a can include a multi-channel (e.g., four channel) power amplifier that is configured to amplify the RF signal output by the antenna 404a. The power amplifier can operate on frequencies between about 70 MHz and about 6 GHz. The RF module 460 a can be configured to output at least about 20 Watts of radio signal per channel. The RF module 460 a can be in communication with the multiplexer 422, which can switch between a transmit mode and a receive mode. Additionally or alternatively, the multiplexer 422 can modulate transmitted signals according to a target signal amplitude and/or frequency. Multiplexing can be accomplished in combination with one or more other elements of the RF system 402, such as the SOM module 460b. The multiplexer 422 can include a receiving channel switch matrix that allows the RF module 460a to multiplex a current function of the associated directional antenna 404a.

As noted above, the RF system 402 can include one or more processing modules 460b. The processing modules may comprise system-on-module (“SOM”) aspects, and can thus be referred to herein as “SOM modules”. The SOM module 460b can include an integration of digital and analog functions on a single processing board. The SOM module 460b can include a processor, memory, computer executable code, and/or other elements configured to perform certain functions described herein. The SOM module 460b may include a software defined radio (“SDR”) transceiver that is configured to perform one or more functions traditionally performed by different kinds of hardware (e.g., signal mixing, signal filtering, signal amplification, signal modulation and/or demodulation, signal detection, and/or the like). The SOM module 460b can receive one or more attributes of an RF signal from one or more elements of the RF system 402 (e.g., from the antennas 404) and determine a source direction (e.g., from the DF antenna 404e, the antennas 404, and/or via communications with other aspects of the operating environment 100 as described above), a source amplitude, a source frequency, a source identifier, and/or another aspect of the source. The SOM module 460b can transmit instructions and/or data related to one of those aspects to another element of the RF system 402, an element of a different RF system 402, and/or a remote computing device (e.g., a remote server). Thus, the SOM module 460b can help identify a source and/or transmit information based on that identification. In some implementations, the SOM module 460b can modify a direction, amplitude, frequency, and/or other attribute of an RF signal transmitted by the antennas 404. In some implementations, the RF system 402 can modify a direction of the transmitted RF signal based on the identified attribute of a received RF signal. The antennas 404 can be configured to receive signals at a relatively high bandwidth and/or angular arc in order to identify a source signal. Additionally or alternatively, the antennas 404 can be configured to transmit RF signals at a relatively narrower or more precise bandwidth and/or angular arc in order to interfere with or disrupt a target source signal or hardware that is emitting the source signal. In some implementations, the primary receiving and/or transmitting angular arc of one of the directional antennas may be between about 80 degrees and about 110 degrees but other arcs are possible.

The RF system 402 can further include a power supply module 460c which can provide one or more of the modules 460 and/or other elements of the RF system 402 with sufficient power to perform their respective functions. The power supply module 460c can include and/or be coupled to a power source (e.g., a battery, grid power, generated power). The power supply module 460c can be coupled to an external and/or internal power source (e.g., in some implementations the RF system includes an internal battery power source that provides power to the components of the RF system via the power supply module(s)). The power supply module 460c can convert power from one current to another. For example, the power supply module 460c can convert AC power to DC power, and can output DC power in multiple voltages and amperages as needed by the various components of the RF system 402. Additionally or alternatively, the power supply module 460c can output at least 1200 Watts of power at a voltage of between about 16-50 Volts. Additionally or alternatively, the power supply module 460c can output at least 25 Amps of power. The power supply module 460c can be configured to transmit data to and/or from one or more of the other system modules 460. In some implementations, the power supply module 460c can be replaced with another system module and the RF system 402 can be coupled to power via an electrical wire or to another source of power (e.g., another RF system).

The RF system 402 can further include a system manager board (SMB) 432 housed within the interior space 414 of the module enclosure 410 and be in communication with the modules 460. The system manager board 432 can be a control module configured to manage, coordinate, and/or monitor the modules 460, host user interfaces, and/or integrating third-party modules for comprehensive functionality. The system manager board 432 can be the main interface between the various systems and sub-systems of the RF system 402, enabling communication and coordination among the modules 460. For example, the system manager board 432 can direct all inputs/outputs (I/O) traffic to the appropriate modules 460/and components. In addition to handling real-time communication and operational control, the system manager board 432 can hosts user interfaces for system management, allowing direct interaction and monitoring by users or operators. The system manager board 432 can also support the integration of third-party modules, expanding the system's capabilities and adaptability. The system manager board 432 can include power management, which dynamically regulates energy distribution across components, such as the modules 460, while its fault detection and health diagnostics allow proactive maintenance by identifying and mitigating issues early.

As shown in FIGS. 12-14, the module enclosure 410 can further house a backplane 434. The backplane 434 can be positioned along an interior surface of the first side 411. The backplane 434 can extend from a top of the module enclosure 410 to a bottom. The backplane 434 can advantageously serve as a central hub, providing both physical support and connectivity for the modules 460. The backplane 434 can include a plurality of interconnects 436 for facilitating communication and/or power distribution between the modules 460. The interconnects 436 can enable modular flexibility, allowing for module integration, replacement, and/or expansion without extensive reconfiguration. The organization of the backplane 434 and/or the plurality of interconnects 436 can optimize space within the module enclosure 410 and support modular scalability. The interconnects 436 of the backplane 434 can include coaxial 438 and ethernet connectors 439. These connectors can enable high-speed data transmission and support signal integrity between modules 460. The coaxial connectors 438 can support RF and high-frequency signal routing by isolating signal paths to prevent interference. The ethernet connectors 439 can provide high-bandwidth data transfer, facilitating communication across internal components or with external systems. By centralizing power and communication through the backplane 434, the enclosure 410 can improve system reliability, reduces wiring complexity, and/or improves ease of maintenance. The backplane 434 and the system manager board 432 can be interconnected, allowing them to work in unison to streamline power distribution, data management, and/or communication across modules 460. This integration can enable the system manager board 432 to monitor and/or control power flow, data exchange, and/or fault management through the plurality of interconnects 436 of the backplane 434. Together, the system manager board 432 and the backplane 434 can create a coordinated network within the module enclosure 410.

The fans 450 can be in fluid communication with the interior space 414 of the module enclosure 410 via a plurality of fan interfaces 456. The fan interfaces 456 can extend through the first side 411 of the module enclosure 410. The fans 450 can cause air flow through the fan interfaces 456, which are openings and/or channels through the first side 411. Advantageously, the fan interfaces 456 can be aligned to correspond with the placement of individual modules 460, allowing the airflow to be directed toward the modules 460. For example, of the fans 450 can align with one or with multiple modules 460 such that the fans 450 can provide cooling to more than one module 460. This alignment can enable the fans 450 to generate a positive and/or negative air pressure within the module enclosure 410, providing cool air that is channeled to modules 460 for thermal regulation. The cooling of the modules 460 provided via the fans 450 and fan interfaces 456 can also advantageously minimizes temperature fluctuations, which can improve the stability and reliability of the modules 460, for example, as the modules 460 experience continuous and/or heavy workloads. In addition, the fan interfaces 456 and air pressure from fans 450 collectively create a streamlined airflow pathway, effectively expelling warm air while drawing in relatively cooler air from the external environment, which can improve the thermal performance of the module enclosure 410. In addition to their positioning and alignment, the fan interfaces 456 can include a recessed surface 458 to receive and secure a portion of the modules 460. This recessed surface 458 can allow the portion of each module 460 to sit within the fan interface 456, improving airflow. In some implementations, to further improve the seal and reduce potential air leakage, each fan interface 456 can include a gasket 459 that lines the recessed surface 458. This gasket 459 provides an airtight connection between the fan interface 456 and the module 460, ensuring that the positive air pressure generated by the fans 450 is effectively directed into the modules 460 without loss. The gasketed 459 and recessed surface 458 can improve cooling efficiency by ensuring that airflow is tightly channeled but also provides vibration damping, helping to secure the modules 460 and reduce mechanical wear over time.

As previously mentioned, the modules 460 and other components housed within the module enclosure 410 can be disposed at least partly or completely within the outer shell 412 of the RF system 402. Because each of the modules 460 can produce heat that may need to be released to the atmosphere, the modules 460 can be arranged to allow air to flow through lateral portions 462 of the modules 460 and into one or more channels 464 extending through the length of the lateral portions 462. Inside the lateral portion 462, the channel 464 can include a heatsink 465 thermally coupled to (e.g., adjacent to) components of the modules 460, such that the heatsink 465 advantageously draws heat away from said components for dissipating said generated heat. The heatsink 465 can be made of a thermally conductive material, such as metal (e.g., silver, copper, gold, aluminum, brass, and/or any other suitable metal). Further advantageously, each of the heatsinks 465 can be shaped to increase the radiation of heat therefrom and/or to allow increased air flow therethrough to promote the transfer of heat away from any corresponding elements via convection, conduction, and/or radiation. For example, one or more of the heatsinks 465 can include a zipper fin shape (also known as a “folded fin shape” as disclosed herein). A zipper fin shape can include a plurality of peaks and valleys, which can provide high heat transfer while providing high structural integrity. The zipper fin shape can be formed of a plurality of thin fins in a compact arrangement to create a high-density fin structure. The heatsinks 465 can also include, for example, a plurality of metal (e.g., copper, aluminum, iron, and/or the like) fins. In some implementations, each of the fins is plated in a corrosive-resistant layer, such as a metal (e.g., nickel plating). The fan 450 can help promote the movement of air through the modules 460 to improve heat transfer away from the modules 460. The lateral portions 462 of the modules 460 can align with a corresponding fan interfaces 456, such that the one or more channels 464 are coupled to the recessed surface 458, and, in some implementations, the gasket 459. Air can thus flow from the fans 450, through the fan interfaces 456, and into the one or more channels 464 to transfer air from the heatsink 465 and out into the external operating environment (e.g., operating environment 100). The one or more air vents 419 disposed on the cover plate 416 can also align with the one or more channels 464 for exhausting the air from the one or more channels 464.

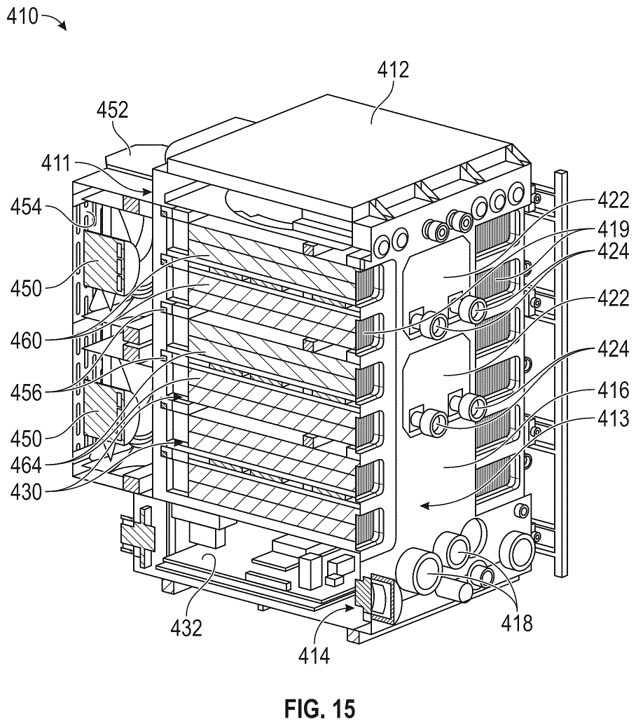

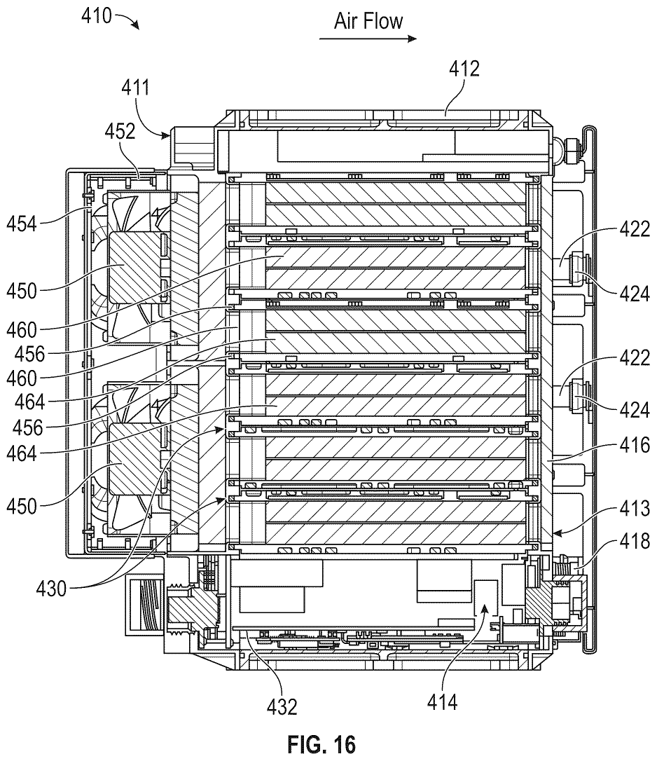

FIGS. 15 and 16 illustrate vertical cross-sections of the example implementation of the RF system 402. As described above, the fans 450 on the first side 411 of the module enclosure 410 can draw air from the environment into the module enclosure 410 and direct it to the modules 460. In some implementations, each fan 450 provides cooling for three modules 460, as shown in FIGS. 15 and 16, advantageously distributing airflow across multiple modules 460 for cooling. The airflow begins as the fans 450 intake external air, pushing it through the fan interfaces 456 and into the modules 460. The modules 460 can be arranged to allow air to flow through their lateral portions 462, which include channels 464 extending through the length of each lateral portion 462. As the air moves through the channels 464, the air flow passes over heatsinks 465, which collects and dissipates heat from components of the modules 460. The heatsinks 465 transfer heat from components to the passing air. Once the air has absorbed the heat, it continues through the module enclosure 410 and exits through air vents 419 aligned with the modules 460 on the second side 413.

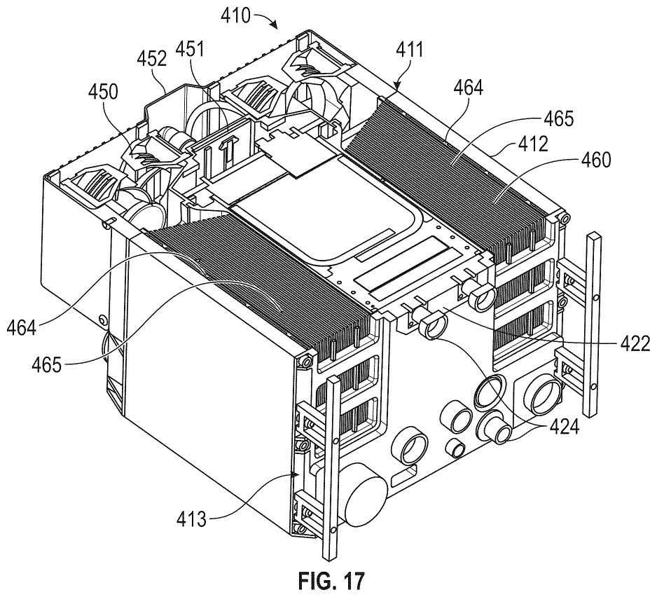

FIG. 17 illustrates a horizontal cross-section of the of the example implementation of the RF system 402. As shown in FIG. 17, the channels 464 can extend along the length (e.g., the entire length) of both the modules 460 and the module enclosure 410. The channels 464 can provide provides a direct path for airflow from the fans 450 at the entrance of the one or more channels 464 to the vents 419 on the opposite side, promoting cooling by directing air through the full length of each modules 460. At the entrance, the channels 464 can have a narrower width that then gradually widens. By having a narrower entrance, this can create an expansion effect that helps distribute air more evenly as it flows into the modules 460. The heatsink 465 located at the entrance can include fins that are angled to assist with the thermal transfer. In this angled configuration, the fins closest to the module enclosure 410 are longer than the interior fins positioned closer to the modules 460. This difference in fin length can help channel incoming air toward the module components, improving contact with the heatsink surfaces and enhancing heat dissipation as the air passes through the channels 464. The angled fins can also promote a more consistent airflow through the heatsink 465, reducing potential airflow resistance and turbulence that may impede cooling. In some implementations, the heatsink 465 can have fins of uniform length across the entire width of the entrance, with no angle to the fin layout.

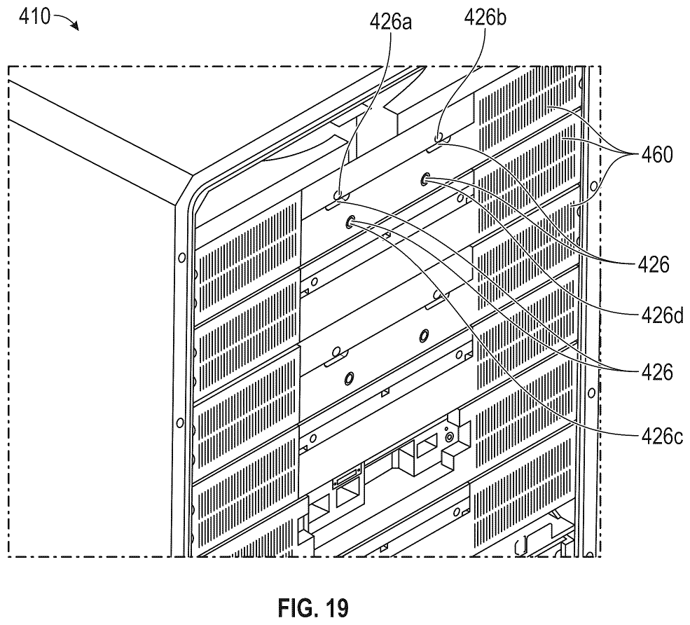

FIG. 18 illustrates a schematic cross section of a top view of the module enclosure 410 and the MUX 422, according to various implementations of the present disclosure. FIG. 19 illustrates a front perspective view of the module enclosure 410 and the MUX 422. The MUX 422 can include connectors 426 (e.g., four connectors) for coupling and/or connecting the modules 460 (e.g., RF modules 460a (power amplifier (PA) modules)) and the MUX 422, enabling signal exchange and data transfer. The connectors 426 can provide physical attachment points through which signals from the modules 460 (e.g., power amplifier (PA) modules) are routed into the MUX 422, allowing the MUX 422 to control and distribute signals as needed. In some implementations, the module 460 (e.g., power amplifier (PA) modules) can have four channels identified as Channel 1 426a, Channel 2 426b, Channel 3426c, and Channel 4 426d. Two of the channels (e.g., Channel 1 426a and Channel 2 426b) can be positioned on top and the other two channels (e.g., Channels 3 and 4) can be positioned on the bottom. Since Channel 3 426c and Channel 4 424d are less efficient and generate more heat than Channel 1 426a and Channel 2 426b, Channel 3 426c and Channel 4 426d can be positioned below Channel 1 426a and Channel 2 426b. This arrangement allows the additional generated heat by channel 3 426c and Channel 4 426d to be dissipated by the more efficient heat spreading path at the bottom of the module 460. In contrast, the top board contains channels 1 and 2, which spread heat through the top. The MUX 422 can manage signal routing by combining Channel 2 426b, Channel 3 426c, and Channel 4 426d into a single output path while allowing a direct pass-through for Channel 1 426a. Externally, this results in two output ports (e.g., MUX interface 424)—a low-band port and a mid-band port. The low-band port can comprise the signals from Channel 1 426a, and the mid-band port comprises the combined signals from Channel 2 426b, Channel 3 426c, and Channel 4 426d.

The connectors 426 can be configured as pin connectors, ribbon connectors, etc. to ensure alignment and electrical contacts, supporting both high-frequency and low-frequency signal transmission depending on the application. The connectors 426 can be located to streamline signal pathways, minimizing signal loss and/or delay as data flows from the modules 460 into the MUX 422. This configuration allows the MUX 422 to manage multiple incoming signals, enhancing the speed and responsiveness of the overall system. Additionally, the connectors 426 can include features such as locking mechanisms, like latches or clips, to secure connections and prevent accidental disconnections/decouplings, particularly in environments subject to vibrations or movement.

In some implementations, the MUX interface 424 of the MUX 422 can also include both high-frequency and low-frequency interfaces, each dedicated to specific types of signal paths, to support versatile connections to antennas (e.g., antennas 404) of the RF system 402. The high-frequency interface can be for signals in the RF, used in communication and radar applications. This enables the MUX 422 to handle high-bandwidth, fast-changing signals for accurate data transmission, high-resolution imaging, and real-time tracking. The high-frequency interface can include impedance-matching circuitry to minimize reflection losses, ensuring optimal signal clarity and reducing energy dissipation across high-frequency transmission lines. In addition to the high-frequency interface, the MUX interface 424 of the MUX 422 can include a low-frequency interface for signals in lower frequency ranges, such as control signals, power modulation signals, and/or data lines that do not require high bandwidth. This low-frequency interface allows the MUX 422 to coupled to antennas that may function as part of broader communication or control networks, managing slower, stable data transmission that supports background system operations or peripheral controls.

### System Modules

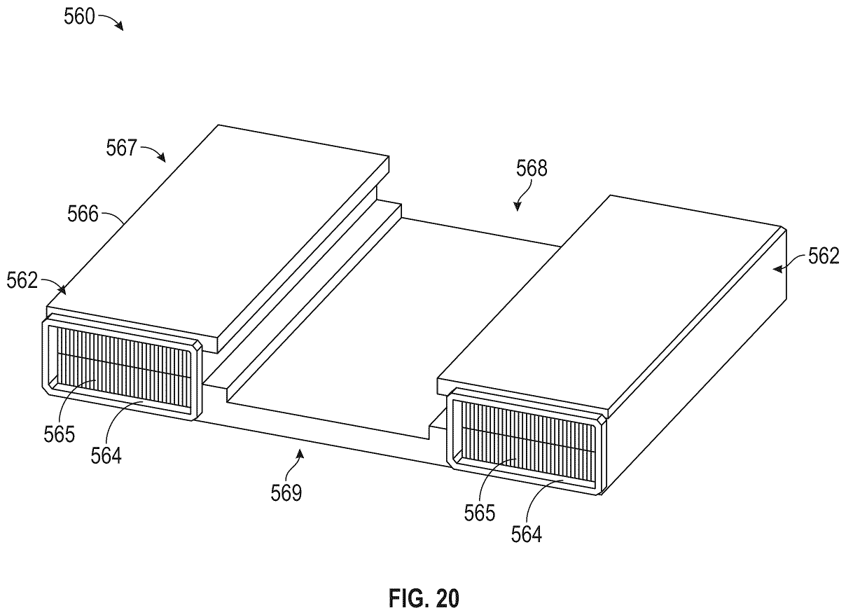

FIG. 20 illustrates a perspective front view of an example implementation of a module 560, according to various implementations of the present disclosure. In various implementations, the module 560 of FIG. 20 can correspond to the modules 460 of FIGS. 11, 12, and 14-19. Advantageously, the module 560 can be configured to be customizable to suit any type of module, such as any of the modules 460a-460c described above. Each module 560 can comprise a module package 566, which can be customized to include any and/or some of the features discussed below. The module package 566 can have a general structure which can be altered (e.g., machined) to suit the role of the module 560. For example, the module 560 can be taken “off the shelf” and adapted to a desired configuration. The module package 566 can be generally similar for each modules 560 with various variations corresponding to the type of module role.

As shown in FIG. 20, the module package 566 can include a central portion 568 configured to house an electronic component, such as sensors, processors, or any other electronic circuitry. The central portion 568 can be adapted (e.g., formed, machined, etc.) to support different types and variations of the electronic component. For example, the central portion 568 can include a cavity (e.g., an enclosure surrounding the electronic component) in which circuitry and related components are disposed within. In some implementations, the central portion 568 can receive and couple to a standardized modular package (e.g., a Sensor Open Systems Architecture (SOSA) module) having a processing unit as well as interfaces for coupling the electronic component to the central portion 568. The central portion 568 can include adjustable mounting brackets, modular connectors, and/or reconfigurable interface slots that can fit a range of component types and sizes. This structural flexibility can advantageously allow for integration of various technology or alternate components as needed, accommodating various configurations without requiring redesign of the module 560.

The module 560 can also include one or more channels 564 extending through the lateral portions 562 of the module package 566. The one or more channels 564 can extend along the channel length CL of the lateral portions 562. The channels 564 can be located in proximity to the central portion 568 and include heatsinks 565 (e.g., folded fin heatsink) contained along a channel length CL of the one or more channels 564. Inside the lateral portions 562 and the one or more channels 564, the heatsink 565 can be thermally coupled to (e.g., thermally adjacent to) whichever electronic component is disposed in the central portion 568. The heatsink 565 can be made of a thermally conductive material, such as metal (e.g., silver, copper, gold, aluminum, brass, and/or any other suitable metal). Each of the heatsinks 565 can be shaped to increase the radiation of heat therefrom and/or to allow increased air flow therethrough to promote the transfer of heat away via convection, conduction, and/or radiation. For example, one or more of the heatsinks 565 can include a zipper fin shape (also known as a “folded fin shape” as disclosed herein). A zipper fin shape can include a plurality of peaks and valleys, which can provide high heat transfer while providing high structural integrity. The zipper fin shape can be formed of a plurality of thin fins in a compact arrangement to make a high-density fin structure. The heatsinks 565 can also include, for example, a plurality of metal (e.g., copper, aluminum, iron, and/or the like) fins. In some implementations, each of the fins is plated in a corrosive-resistant layer, such as a metal (e.g., nickel plating).

The module 560 can also include one or more surfaces (e.g., top surface 567 and/or bottom surface 569) on which heat pipes (not shown) can be embedded within. Since the module 560 is pre-machined before use, a heat pipe layout can be customized for each of the modules 560. For example, the properties of an electronic component can influence the heat pipe layout, allowing the heat pipe layout to be optimized for transferring heat away from the electronic component. The heat pipe layout can be on the top surface 567 and/or bottom surface 569 can extend over one or both of the central portion 568 and the lateral portions 562 of the modules 560. The heat pipe layout can be configured to maximize the transfer of heat from the central portion 568. Thus, advantageously, the heat pipe layout can be customized based at least on the location of the heat generating components of the electronic component. Additionally, the heat pipe layout on the top surface 567 and bottom surface 569 can be different from one another to maximize the transfer of heat on either surface.

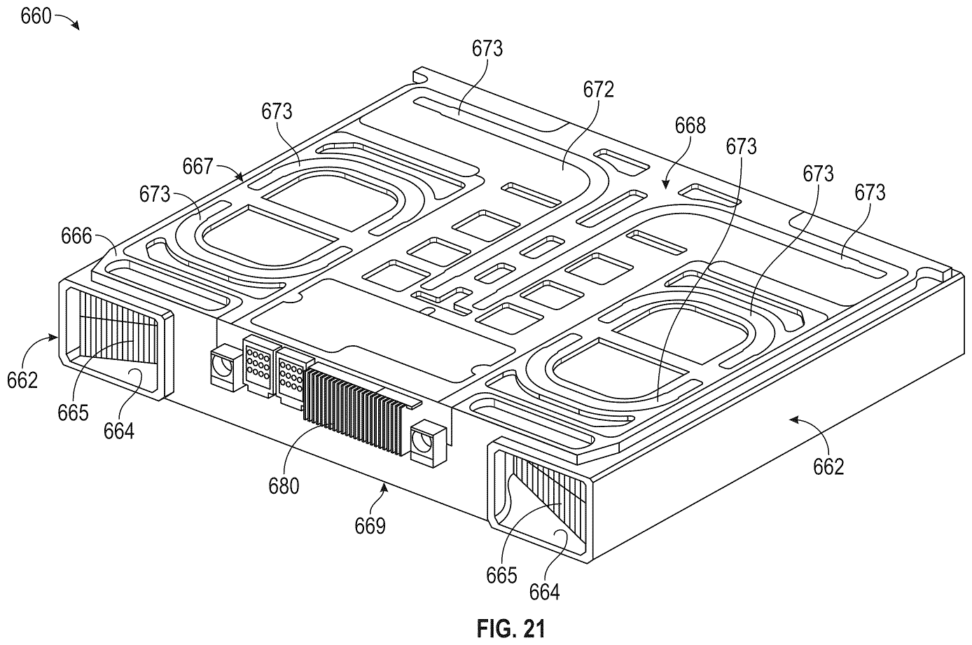

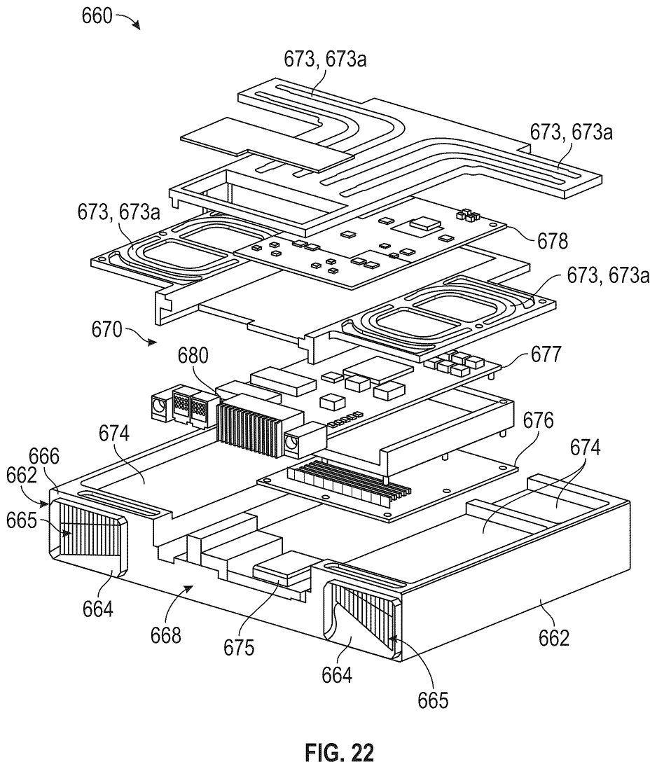

FIG. 21 illustrates a front perspective view of an example module 660 (e.g., SOM module 460b) of the RF system 402 having an integrated thermal system, according to various implementations of the present disclosure. FIG. 22 illustrates a partially exploded view of the example module 660 (e.g., SOM module 460b) of the RF system 402 having an integrated thermal system, according to various implementations of the present disclosure. In various implementations, the module 560 can correspond to the module 460 of FIGS. 11, 12, and 14-19 and the module 560 of FIG. 20. The modules 660 can include a module package 666 (e.g., chassis). The module package 666 can provide additional environmental protection, shock protection, and thermal conductivity for the internal components (e.g., to provide thermal conductivity and heat dissipation to the outside of the individual components). As mentioned above, the module package 666 can include a central portion 668 configured to house an electronic component 670. In some implementations, the central portion 668 can be adaptable to support different variations of the electronic component 670. For example, the electronic component 670 can include adjustable brackets, flexible mounting points, and/or modular slots within the central portion 668, enabling the module package 666 to support multiple variations of the electronic component 670 without the need for redesign.

As shown in FIG. 22, the electronic component 670 (e.g., the modular sensor package) can further include a compute board 676 configured to provide central processing functions and data computation. The compute board 676 can have at least one processor and memory unit for executing instructions. The electronic component 670 can also include a carrier board 677 that is electrically coupled to the compute board 676. The carrier board 677 can be configured to provide input/output interfaces and power management for the compute board 676. Additionally, a personality board 678 can be removably coupled to the carrier board 677. The personality board 678 can be configured to modify or extend the functionality of the electronic component 670 by interfacing with the carrier board 677. The personality board 678 can include circuitry to customize operations of the electronic component 670 for a desired application. In some implementations, the module package 666 can include a slot configured to receive the electronic component 670. The slot of the module package 666 can have alignment guides or rails for positioning and insertion or removal of the electronic component 670. The module package 666 can also have electrical and data connectors integrated into the slot to provide power and communication to the electronic component 670.

A removable cover 672 can be disposed over and/or in proximity to the electronic component 670. The removable cover 672 can protect the electronic component 670 from external elements such as dust, moisture, an/or physical impact. The cover 672 can be made from durable materials (e.g., polycarbonate, metal, and/or specialized polymers) to provide a balance of strength, weight, and/or environmental resistance. In some implementations, the removable cover 672 can include openings, vents, or transparent sections, depending on the needs of the electronic component 670. For example, if the electronic component 670 generates heat, the cover 672 can include ventilation or heat-dissipating features (e.g., heat pipes 673 described below). In some implementations, the cover 672 can also include quick-release fasteners, such as snap-fit fasteners, screws, and/or to allow access to the electronic component 670.

As mentioned above, the modules 660 can include channels 664 extending through the lateral portions 662 of the module package 666. The one or more channels 664 can be located in proximity to the central portion 668 and include heatsink 665 (e.g., folded fin heatsink) contained along a channel length CL of the one or more channels 664. Inside the lateral portion 662, advantageously, the heatsink 665 can be thermally coupled to (e.g., thermally adjacent to) the electronic component 670 of the modules 660, such that the heatsink 665 draws heat away from electronic component 670. The heatsink 665 can be made of a thermally conductive material, such as metal. Each of the heatsinks 665 can be shaped to increase the radiation of heat therefrom and/or to allow increased air flow therethrough to promote the transfer of heat away via convection, conduction, and/or radiation. For example, one or more of the heatsinks 665 can include a zipper fin shape (also known as a “folded fin shape” as described herein). A zipper fin shape can include a plurality of peaks and valleys, which can provide high heat transfer while providing high structural integrity. The zipper fin shape can be formed of a plurality of thin fins in a compact arrangement to make a high-density fin structure. The heatsinks 665 can also include, for example, a plurality of metal (e.g., copper, aluminum, iron, and/or the like) fins. In some implementations, each of the fins is plated in a corrosive-resistant layer, such as a metal (e.g., nickel plating).

The modules 660 can also include one or more heat pipes 673 for thermal management of the modules 660. The heat pipes 673 can comprise a sealed tube made of copper and/or aluminum, filled with a liquid coolant, such as water or alcohol. The heat pipes 673 can transfer heat away and facilitate the dissipation of excess heat generated by the electronic component 670. The heat pipe 673 can be thermally coupled to electronic component 670. As the electronic component 670 heats up, the liquid inside the heat pipes 673 can absorb said heat and vaporizes, turning into gas. The vaporized coolant travels to the cooler end of the heat pipes 673, where it releases the heat and condenses back into liquid. This liquid then returns to the hot end via capillary action or gravity, and the cycle repeats. The heat pipes 673 can be at least partially embedded in and/or on one or more exterior surfaces of, as well as within, the module package 666 to create thermal pathways. For example, the heat pipes 673 can be embedded on a top surface 667 (e.g., upper heat pipes 673a) and/or bottom surface 669 (e.g., lower heat pipes 673b) of the module package 666. The heat pipes 673 can be embedded in a recess 674 in either surface of the module package 666. Additionally, by partially embedding the heat pipes 673 on the exterior surfaces of the module package 666, the heat pipes 673 can also provide some external cooling through convection or contact with surrounding air. Advantageously, the heat pipes 673 can be configured to direct heat to various regions of the modules 660 where the heatsinks 665 are located. For example, the one or more heat pipes 673 can be configured to transfer heat from the electronic component 670 to the one or more channels 664 extending through the lateral portions 662, such that the electronic component 670 is in thermal communication with the one or more channels 664. Further advantageously, by channeling heat through multiple paths, the heat pipes 673 and channels 664 can enable the module 660 to maintain stable internal temperatures under a variety of operating conditions.

The module package 666 can also include a connector 680 to electrically coupled the module 660 and the backplane 434 of the modular housing 410. The plurality of interconnects 436 of the backplane 434 can enable integration of multiple modules 660 within the single modular housing 410, allowing power, data, and/or control signals to be routed between the modules 660 and the RF system 402. The module connector 680 can be positioned on the module package 666 to align with corresponding interconnects 436 (e.g., coaxial connectors 438 and/or ethernet connectors 439) of the backplane 434. In some implementations, for durability and connection stability, the connector 680 can include locking mechanisms and/or reinforced contact points to prevent disconnections/decouplings. The connector 680 can support various pin configurations, power requirements, and/or communication protocols, enabling compatibility across different module types within the same module enclosure 410.

The modules 660 can further include a module heatsink 675 (e.g., a copper slug), which can be a thermally conductive material. The module heatsink 675 can be thermally coupled to and configured to absorb and conduct heat away from the electronic component 670, thus advantageously regulating the temperature of the electronic component 670 and preventing overheating. The module heatsink 675 can be positioned in proximity to the electronic component 670 in the central portion 668 to draw heat away from the electronic component 670. The module heatsink 675 and the lower heat pipes 673b disposed on the bottom surface 669 of the module package 666 can be thermally coupled to the compute board 676 of the electronic component 670. In some implementations, the module heatsink 675 can be positioned in the module package 666 such that the module heatsink 675 is located at an opposite side of module package 666 from the removable cover 672 and the electronic component 670 is positioned between the removable cover 672 and the module heatsink 675. To further improve the heat transfer, the module heatsink 675 can be bonded to the heat pipes 673 of the bottom surface 669 by a thermal paste rather than a metal-to-metal coupling. The result is a continuous thermal pathway from the electronic component 670, through the heatsink 675, and into the heat pipes 673, which then transfer the heat to other areas of the module package 666, such as the channels 664.

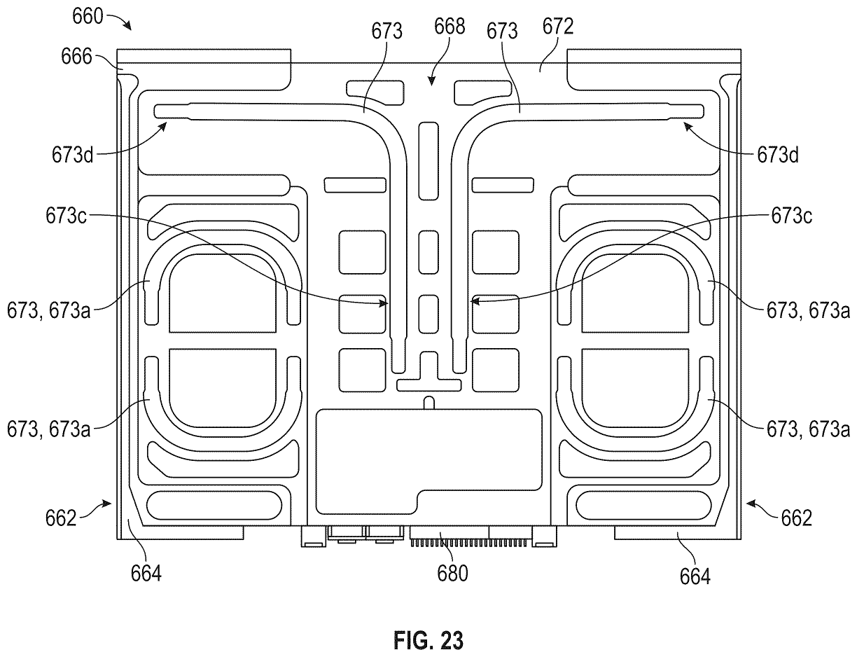

FIG. 23 illustrates a top view of the example module 660 having an integrated thermal system, according to various implementations of the present disclosure. As shown in FIG. 23, a first portion 673c of the heat pipes 673 can extend along the center of the central portion 668 such that the first portion 673c is parallel to the channels 664. This can allow the first portion 673c of the heat pipes 673 to maintain close thermal contact with the electronic component 670. A second portion 673d of the heat pipes 673 can transition to be approximately and/or substantially perpendicular to and extend towards the one or more channels 664. This perpendicular alignment of the second portion 673d directs the heat away from the electronic component 670, guiding it toward the one or more channels 664 of the modules 660. This arrangement can advantageously make a thermal pathway, facilitating the movement of heat from the electronic component 670 to the channels 664 by the directional alignment of the heat pipes 673. The two-part configuration of the heat pipes 673 thus enables a sequential transfer of heat: first, capturing and moving it along the length of the central portion 668 via the parallel alignment (e.g., first portion 673c), and second, offloading said heat to the perpendicular portion (e.g., second portion 673d) that is thermally coupled with the channels 664. This can provide thermal management and can also ensure an even distribution of heat throughout the module package 666, which can reduce thermal stress. Additionally, the heat pipes 673 (e.g., upper heat pipes 673a at the recess 674) can include circular heat pipes, which can be arranged in a circular layout to facilitate the transfer of heat from the electronic component 670 in the central portion 668 to the one or more channels 664. The circular heat pipes can comprise a continuous rounded shape and/or contain breaks such that the circular heat pipes comprises 2, 3, 4, 5, 6, or more separate pieces.

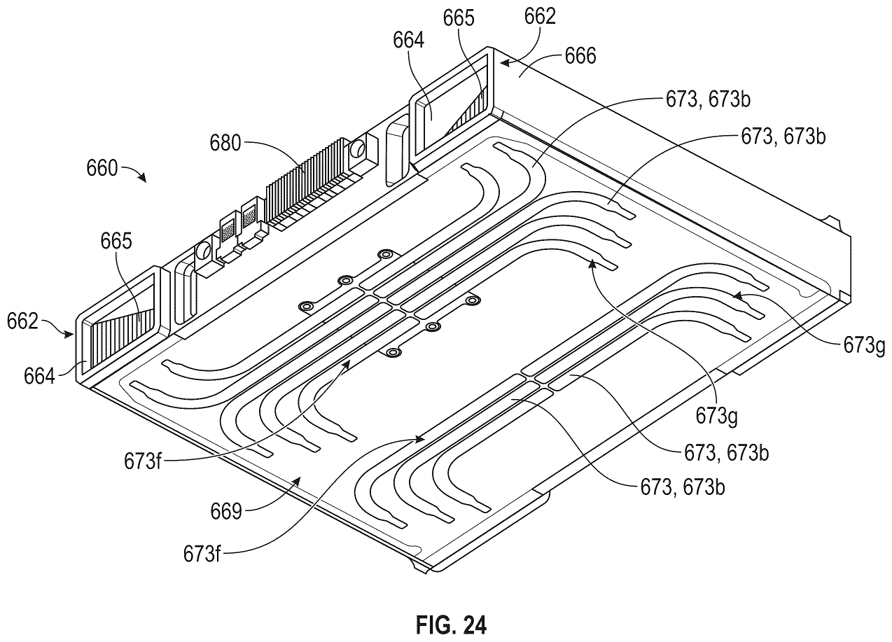

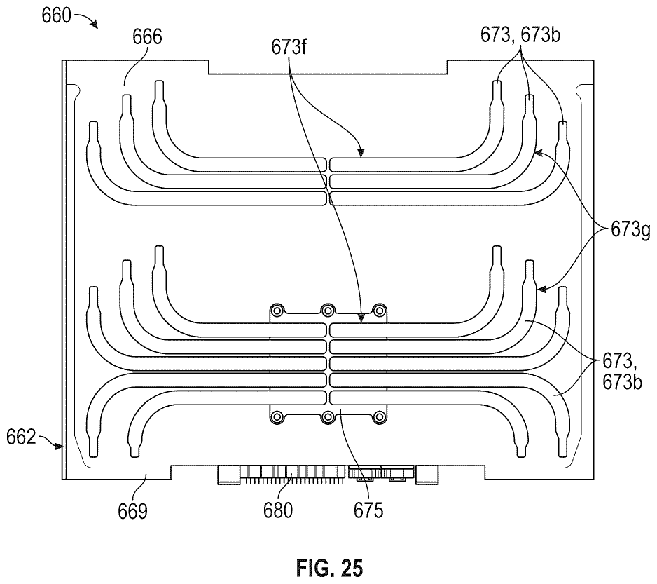

FIG. 24 illustrates a bottom perspective view of the example module 660 having an integrated thermal system, according to various implementations of the present disclosure. FIG. 25 illustrates a bottom view of the example module 660. As shown in FIGS. 24 and 25, a first portion 673f of the heat pipes 673 (e.g., lower heat pipes 673b) can extend away from the center of the central portion 668 such that the first portion 673c is perpendicular to the one or more channels 664. This can allow the first portion 673c of the lower heat pipes 673b to transfer heat away from the electronic component 670. A second portion 673g of the lower heat pipes 673b can transition to be approximately and/or substantially parallel to the one or more channels 664. This parallel alignment of the second portion 673g directs the heat along the one or more channels 664, guiding it toward the one or more channels 664 of the modules 660. Similar to the upper heat pipes 673a on the top surface 667, the arrangement of lower heat pipes 673b can also advantageously create a thermal pathway, facilitating the movement of heat from the electronic component 670 to the channels 664 by the directional alignment of the heat pipes 673 (e.g., lower heat pipes 673b). The two-part configuration of the heat pipes 673 thus enables a sequential transfer of heat: first, capturing and moving it away from the central portion 668 via the perpendicular alignment (e.g., first portion 673f), and second, offloading said heat to the parallel portion (e.g., second portion 673g) that is thermally coupled with the channels 664. This can provide thermal management and can also ensure an even distribution of heat throughout the module package 666, which can reduce thermal stress. As mentioned above, the heat pipes 673 (e.g., lower heat pipes 673b) can be in thermal communication with the module heatsink 675. The module heatsink 675 can at least partially extend through the module package 666 such that the module heatsink 675 and the lower heat pipes 673b are in direct contact with one another.

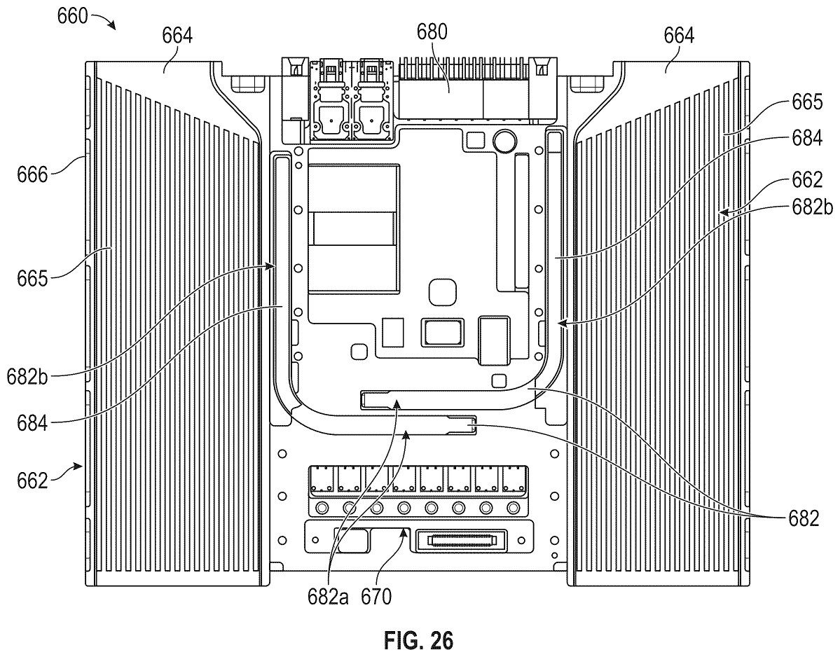

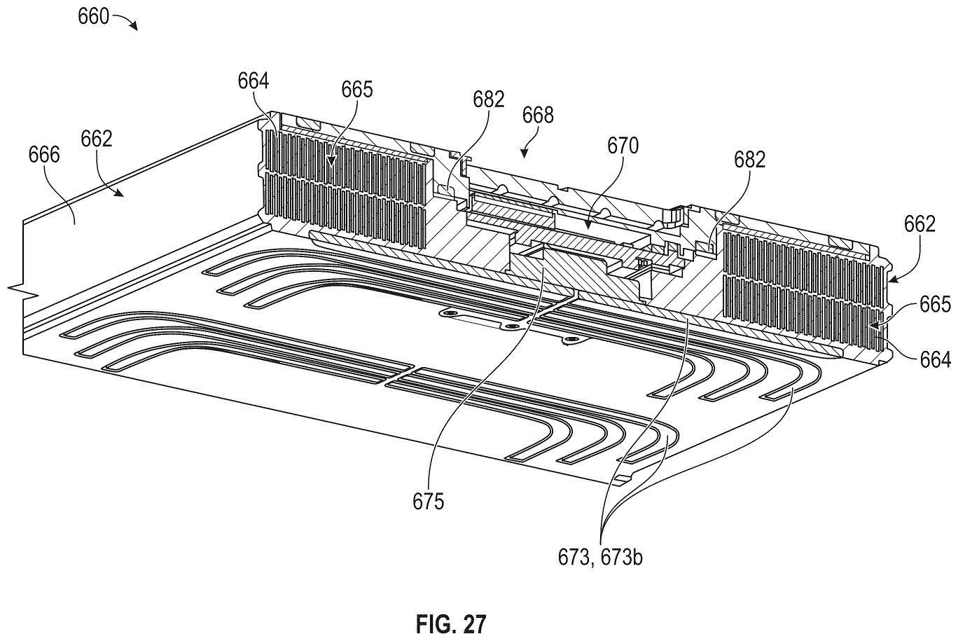

FIG. 26 illustrates a vertical cross section through the example modules 660 showing the interior heat pipes 682 within the module package 666, according to various implementations of the present disclosure. FIG. 27 illustrates a horizontal cross section through the example modules 660 showing another view of the interior heat pipes 682. The modules 660 can further include interior heat pipes 682 disposed in the interior of the module package 666. The interior heat pipes 682 can at least partially surround the electronic component 670 disposed in the central portion 668. The heat collected by the interior heat pipes 682 can be transferred heat through the module package 666 upwards towards the upper heat pipes 673a and/or downwards to the lower heat pipes 673b. Thus, advantageously, there can be a balance heat load depending on which surface (e.g., top surface 667 or bottom surface 669) of the module package 666 is hotter. A first portion 682a of the interior heat pipes 682 can overlap with and extend away from the center of the central portion 668 such that the first portion 682a is perpendicular to the one or more channels 664. This can allow the first portion 682a of the interior heat pipes 682 to transfer heat away from the electronic component 670. A second portion 682b of the interior heat pipes 682 can transition to be approximately and/or substantially parallel to the one or more channels 664. This parallel alignment of the second portion 682b directs the heat along the one or more channels 664, guiding it toward the one or more channels 664 of the modules 660. This arrangement can create a thermal pathway, facilitating the movement of heat from the electronic component 670 to the channels 664 by the directional alignment of the interior heat pipes 682.

The modules 660 can also include a thermal pad 684 thermally coupled to the interior heat pipes 682 to facilitate heat transfer. The thermal pad 684 can be compressible, allowing the thermal pad 684 to conform to the surfaces of the interior heat pipes 682 and the interior surface of the module package 666. The thermal pad 684 can direct heat downward from the interior heat pipes 682 to the lower heat pipes 673b, establishing a path for heat dissipation from the interior section of the module 660 to the bottom surface 669.

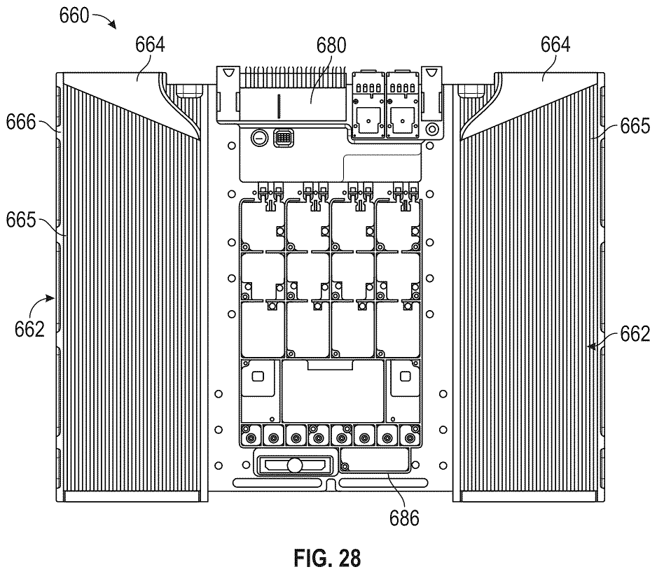

FIG. 28 illustrates another horizontal cross section through the example modules 660 showing the EMI shielding 686 in the module package 666, according to various implementations of the present disclosure. The modules 660 can include EMI (Electromagnetic Interference) shielding 686 to protect the electronic component 670 from external electromagnetic interference and to prevent the electronic signals of the electronic component 670 from emitting interference that may affect nearby devices and/or systems. The EMI shielding 686 can comprise electrically conductive materials, such as copper, silver, aluminum, or alloys, which can be deposited and/or embedded within the module package 666 to block or attenuate electromagnetic fields. The conductive material can also be combined with a curable adhesive, which can be dispensed to different regions of the module package 666 to from the EMI shielding 686. The use of a curable adhesive also advantageously allows the EMI shielding 686 to conform to various shapes and/or surface contours within the modules 660, ensuring comprehensive coverage around various areas, including around the electronic component 670 and any related connectors or interfaces. The EMI shielding 686 can also be structured to create full and/or partial enclosures within the modules 660. For example, full enclosures can be used around the entire electronic component 670 to ensure a high level of protection, while partial shields may be applied to areas most susceptible to interference or emission. The use of conductive materials combined with adhesives also enables the EMI shielding 686 to bond effectively with other parts of the module, reducing gaps that may allow electromagnetic leakage.

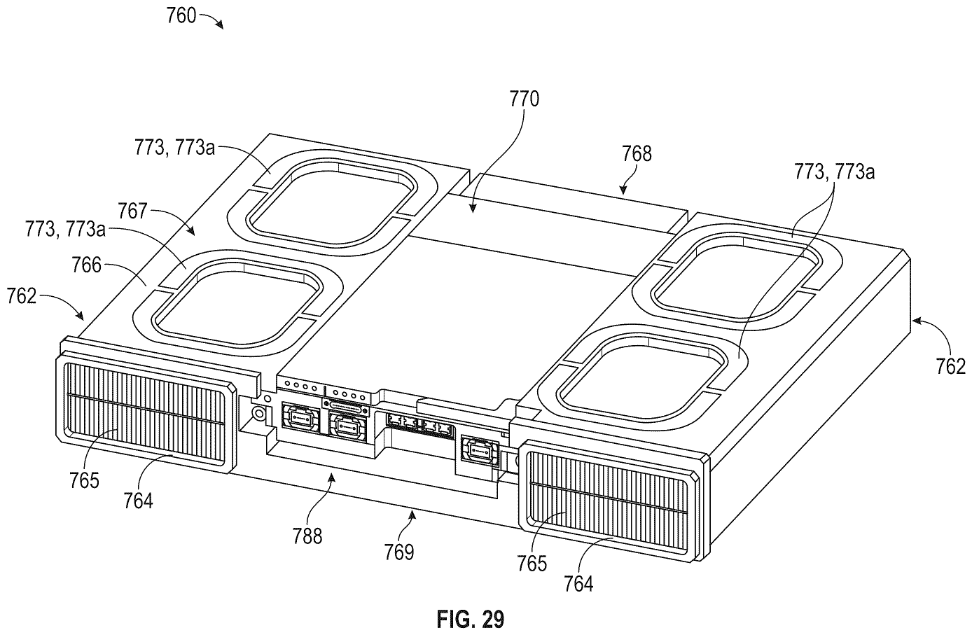

FIG. 29 illustrates a perspective front view of another example module 760 (e.g., SOM module 460b) of the RF system 402 having an integrated thermal system, according to various implementations of the present disclosure. In various implementations, the module 560 can correspond to the module 460 of FIGS. 11, 12, and 14-19, the module 560 of FIG. 20, and the modules 660 of FIGS. 21-28. Unless otherwise noted, the components of FIG. 29 can be the same as or generally similar to like-numbered components of FIGS. 21-28. However, the module 760 of FIG. 29 can comprise an adapter module package 766. The module package 766 can be configured to receive a SOSA (Sensor Open Systems Architecture) module (and/or any other suitable module and/or standard module) and thus advantageously adapt the SOSA module for use with the module enclosure 410 disclosed above and herein. A SOSA module is a standardized, interoperable component built to the SOSA Technical Standard. SOSA modules can support functions like data processing, RF and sensor interfacing, secure networking, and storage within an OpenVPX standard for physical and electrical interfaces, using VPX connectors, backplanes, and chassis. As shown in FIG. 29, the electronic component 770 can comprise a SOSA module, which can be received by a slot 788 in the central portion 768 of the module package 766. The slot 788 can include alignment guides (e.g., rails) for positioning and insertion and/or removal of the electronic component 770.

The module 760 can further include heat pipes 773, which can be positioned (e.g., at least partially embedded) in and/or on the top surface 767 and/or bottom surface 769 of the module package 766. The heat pipes 773 can be in proximity to the electronic component 770 (e.g., the SOSA module) to disperse and dissipate heat via the heatsink 765 in the one or more channels 764. The heat pipes 773 can be disposed over and/or under the one or more channels 764 extending through the lateral portions 762 of the module package 766. The heat pipes 773 can passively transfer heat and facilitate the dissipation of excess heat generated by the electronic component 770. The heat pipes 773 can be positioned to transfer heat away from the electronic component 770. For example, the heat pipes 773 can be at least partially embedded on one or more exterior surfaces, as well as within, of the module package 766 to create thermal pathways. For example, the heat pipes 773 can be embedded on a top surface 767 (e.g., upper heat pipes 773a) and/or bottom surface 769 (e.g., lower heat pipes 773b) of the module package 766. Partially embedding the heat pipes 773 on the exterior surfaces of the module package 766 can also provide some external cooling through convection or contact with surrounding air. In addition, the heat pipes 773 can be configured to direct heat to various regions of the modules 760 where the heatsinks 765 are located. For example, the one or more heat pipes 773 can be configured to transfer heat from the electronic component 770 to the one or more channels 764 extending through the lateral portions 762, such that the electronic component 770 is in thermal communication with the one or more channels 764. By channeling heat through multiple paths, the heat pipes 773 and channels 764 can enable electronic component 770 (e.g., SOSA module) of the module 760 to maintain stable internal temperatures under a variety of operating conditions.

Advantageously, according to various implementations, the transfer of heat via heat pipes 773 can increase operational capacity of the electronic component 770 (e.g., the SOSA module). This cooling allows the electronic component 770 to maintain performance levels without overheating, reducing the risk of thermal throttling or damage. By keeping temperatures stable, the heat pipes 773 enable the electronic component 770 to handle higher power inputs and more demanding processing loads, improving reliability and longevity. For example, electronic components 770 (e.g., SOSA modules) coupled to the module package 766 can increase operational ratings from 55° C. to 65° C.

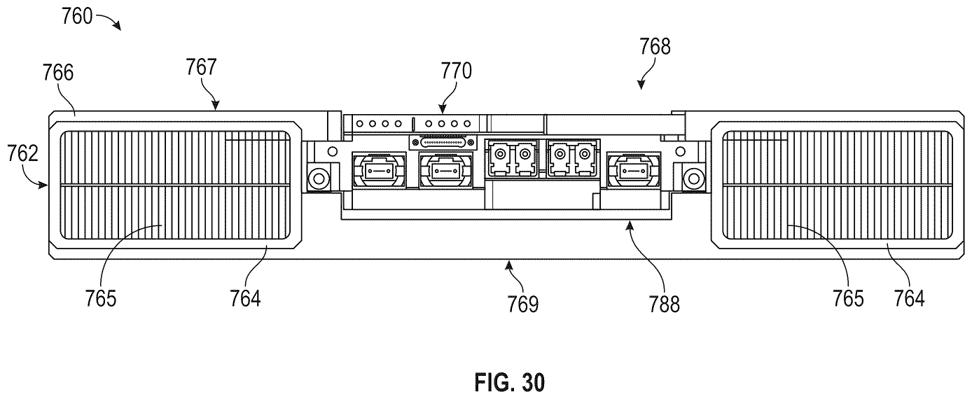

FIG. 30 illustrates a front view of the another example module 760 (e.g., SOM module 460b) having an integrated thermal system, according to various implementations of the present disclosure. As shown in FIG. 30, the electronic component 770 can be positioned within the slot 788 by sliding the electronic component 770 into place and securing it in a fixed position. The positioning of the electronic component 770 can include aligning the electronic component 770 with the slot 788 and inserting the electronic component 770 until it reaches a desired depth and/or position within the slot 788. The slot 788 can be configured to fit SOSA modules, ensuring a fit that allows the electronic component 770 to function within the module package 766. Once in place, the electronic component 770 can be secured by using mechanical fasteners, locking mechanisms, and/or other retention systems to hold it firmly in the slot 788, preventing any movement during operation.

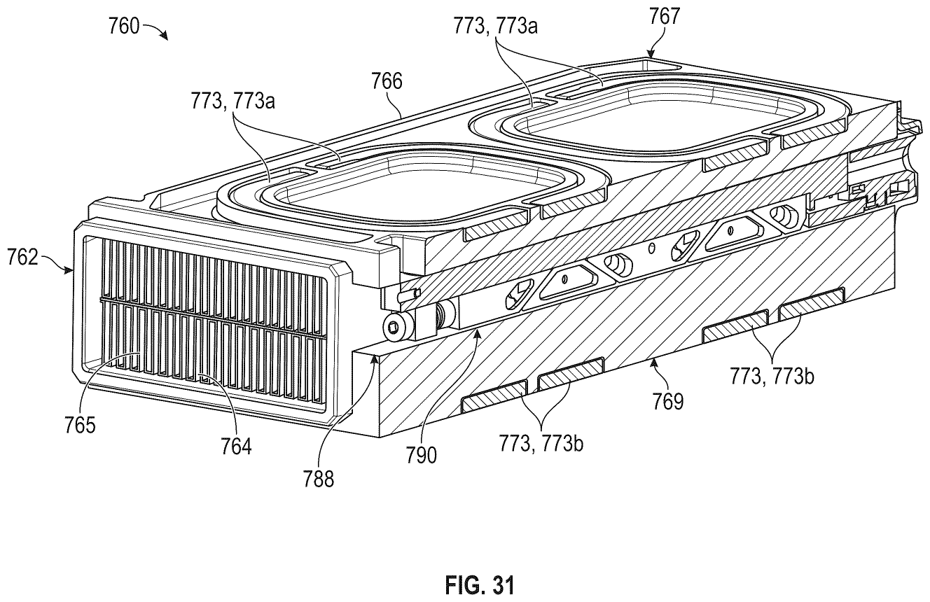

FIG. 31 illustrates a vertical cross section of the another example module 760 (e.g., SOM module 460b) having an integrated thermal system, according to various implementations of the present disclosure. The electronic component 770 can include a lock 790 (e.g., a wedge lock) that, when tightened, presses against the slot 788 to couple the electronic component 770 to the module package 766. The lock 790 can comprise a tapered wedge-shaped element that is inserted into a corresponding recess or groove within the slot 788. As the wedge is tightened, it gradually moves into place, applying pressure against the walls of the slot 788 and the electronic component.

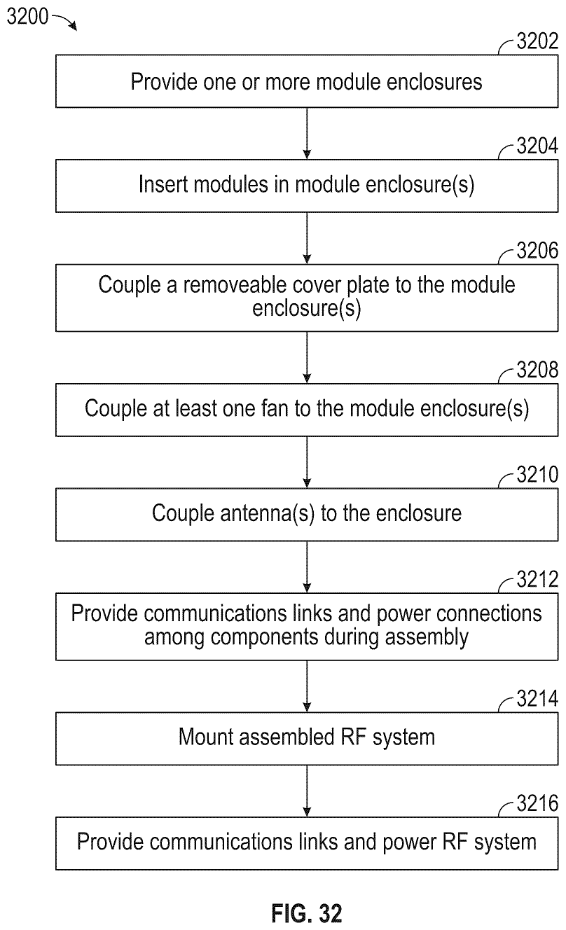

FIG. 32 illustrates an example flow or method 3200 of assembling an RF system, according to various implementations of the present disclosure. Although FIG. 32 discloses one example, other methods of assembling an RF system are possible and described elsewhere herein. Further, in various implementations various blocks of the flow or method may be rearranged, optional, and/or omitted, and/or additional blocks may be added. The blocks illustrated schematically in FIG. 32 are described with reference to certain hardware components of the present disclosure. However, it will be understood that the hardware components of FIG. 32 and/or individual components or subsets thereof may equally be implemented in conjunction with other hardware components, software components, and/or systems without departing from the scope of the present disclosure.

At block 3202, the method can include providing one or more module enclosures (e.g., the module enclosure 410). At block 3204 the method includes inserting one or more system modules (e.g., modules 460a-460c) into the one or more enclosures. The method can include assembly of the one or more elements without the need for tools. The system modules can be coupled to one or more slots (e.g., slot 430 of the module enclosure 410) of the module enclosures. The module enclosures can include a locking mechanism that presses the system modules against a thermal interface side of the module enclosure so as to maximize thermal transfer.

At block 3206, the method can include coupling a removeable cover plate to the module enclosure. The removeable cover plate can seal the modules within the module enclosure from an external environment.

At block 3208, the method includes coupling at least one fan to a side of the module enclosure. The fan can cause air to flow through the module enclosure and the modules within the module enclosure.

At block 3210, the method includes coupling (e.g., attaching, connecting, and/or the like) one or more antennas, such as the antennas 404 and/or the direction finder (DF) antennas 404e described above. For example, an antenna bracket may be rotationally coupled to one or more coupling features. Additionally or alternatively, the antenna bracket and/or one or more of the coupling features may be fixedly coupled to a side of the RF system. In some embodiments, all of the antennas may be coupled to the same portion of the modular assembly (e.g., to an upper module enclosure).

At block 3212, the method includes providing communications links and power connections among various components, including the system modules, of the RF system, and including during the assembly steps described above. The communications links can include various wires and/or optical connections (e.g., cables, such as ethernet) which may be provided via the various cavities of the enclosures of the RF system, as described above. The block 3212 may include coupling one or more connectors that may be configured to protect certain components, including the communication links and/or power connections, from adverse weather or other environmental conditions described herein. The communications links may be wired links and/or wireless data interfaces. In some embodiments, the method includes coupling one or more antennas to exterior portions or exterior surfaces of the module enclosure and providing communications links between the one or more antennas and one or more of the one or more modules. Such external to internal communications links may be provided via one or more plugs or ports positioned on outside surfaces of the RF system, which may be configured to seal the inside of the enclosure from the outside environment, and which may be configured to provide secure connections with corresponding connectors of, for example, wires coming from the antennas, external power source, and/or the like.

At block 3214 the method may include mounting the RF system. This may include mounting a portion of a modular assembly (e.g., a bottom, a side, a top) to a mounting surface, such as another RF system and/or to a mounting system (e.g., a tripod, a building, the ground, and/or the like). The mounting may include a coupling that can be coupled (e.g., assembled) without a need for power and/or other tools. At block 3216 the method may include providing power, activating, and/or operating the RF system. Operating the RF system may include receiving RF signals via the one or more antennas, processing the received RF signals, and/or transmitting RF signals at one or more frequencies.

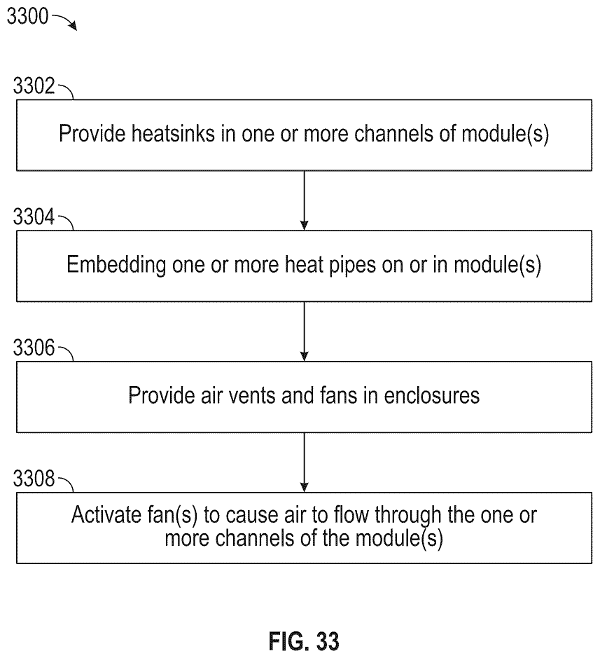

FIG. 33 illustrates an example flow or method 3300 of managing thermal transfer in a module of an RF system, according to various implementations of the present disclosure. Although FIG. 33 discloses one example, other methods of managing thermal transfer in an RF system are possible and described elsewhere herein. Further, in various implementations various blocks of the flow or method may be rearranged, optional, and/or omitted, and/or additional blocks may be added. The blocks illustrated schematically in FIG. 33 are described with reference to certain hardware components of the present disclosure. However, it will be understood that the hardware components of FIG. 33 and/or individual components or subsets thereof may equally be implemented in conjunction with other hardware components, software components, and/or systems without departing from the scope of the present disclosure

At block 3302, the method includes providing one or more heatsinks (e.g., heatsinks 465, heatsinks 565, heatsink 665) in a lateral portion of a module (e.g., modules 460, module 560, modules 660). The one or more heatsinks can be disposed in one or more channels of the modules, which can be in proximity to heat generating electronic components. The heatsinks can extend along a channel length of the one or more channels of the module. The heatsinks can include a zipper fin or other structure configured to draw heat away from the heatsinks and/or other components of the RF system.

At block 3304, the method includes embedding one or more heat pipes (e.g., heat pipes 673, heat pipes 773) on or in the modules. The heat pipes can passively transfer thermal energy from the central portion of the modules to the one or more channels. Each heat pipe layout can be customized for the modules based at least on the role of the module and its components.

Air movement can be promoted via air vents and/or cooling fans disposed in or on an enclosure of the RF system, at block 3306. The cooling fans may be coordinated to push air in the same direction as one another. For example, at block 3308 the method can include activating the cooling fans to cause air to flow through the one or more channels of the modules (e.g., into the modules from one of the enclosure, through heatsinks, and out of an opposite side of the enclosure). This may provide improved cooling of the one or more heatsinks and/or system modules described herein. A fan disposed on the side of the enclosure can provide cool air to more than one module such that multiple modules receive cooler air simultaneously. Additionally, a pair of fans can ensure that the one or more channels of the module both receive cool air in order to prevent uneven cooling of said module.

### HBFE Antenna Housing

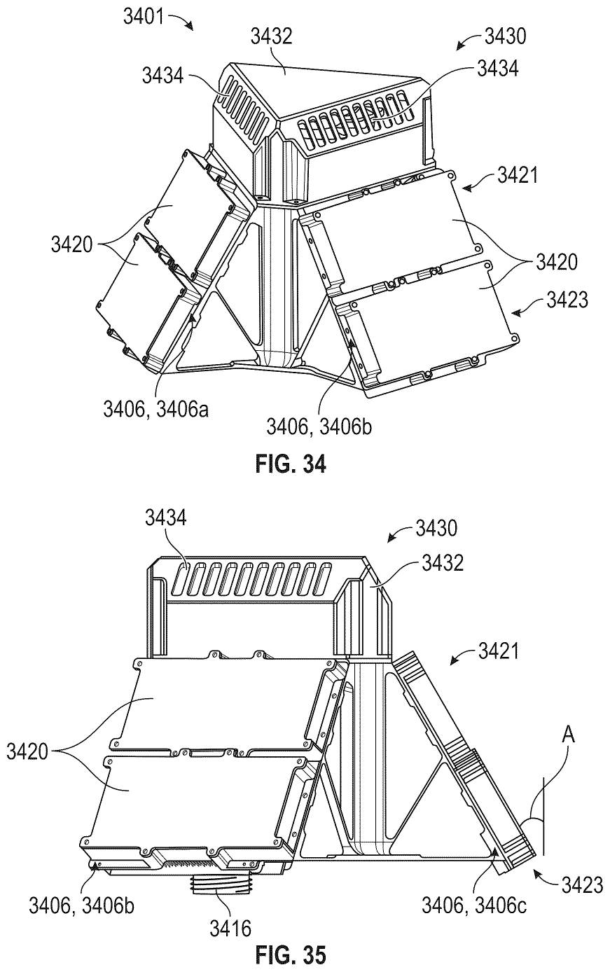

FIGS. 34 and 35 illustrate various views of an example HBFE antenna (e.g., similar to, or the same as, the HBFE antenna 404d of FIG. 7), including an example antenna housing 3401 of the HBFE antenna 404d of the RF system 402, according to various implementations of the present disclosure. FIG. 34 illustrates a front perspective view of an example antenna housing 3401, and FIG. 35 illustrates a profile view of the example antenna housing 3401. The antenna housing 3401 making up the main housing of the HBFE antenna 404d can generally be comprised of a rigid and/or strong material, such as metal, plastics, composites, etc. The antenna housing 3401 can include a material, or include coatings, to protect internal components from EMI, weather, and/or other adverse conditions. The antenna housing 3401 can also comprise a plurality of exterior surfaces 3406. In some implementations, the exterior surfaces 3406 of the antenna housing 3401 comprises three exterior surfaces 3406a-3406c arranged in a radial configuration around a center axis of the antenna housing 3401. In said radial arrangement, the exterior surfaces 3406a-3406c can be positioned at equal angular intervals around a center axis of the antenna housing 3401. For example, the exterior surfaces 3406a-3406c can be positioned at 120-degree angles relative to each other around the center axis. Additionally or alternatively, the exterior surfaces 3406 can be positioned at varying angular intervals around the center axis of the antenna housing 3401.

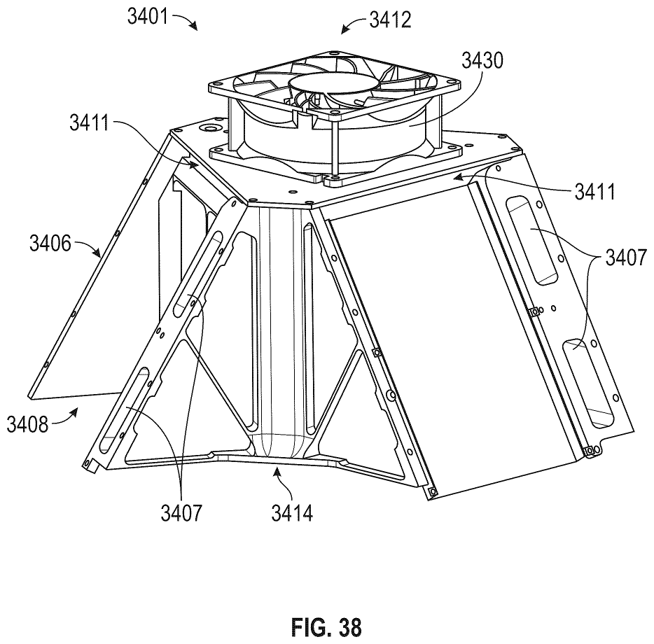

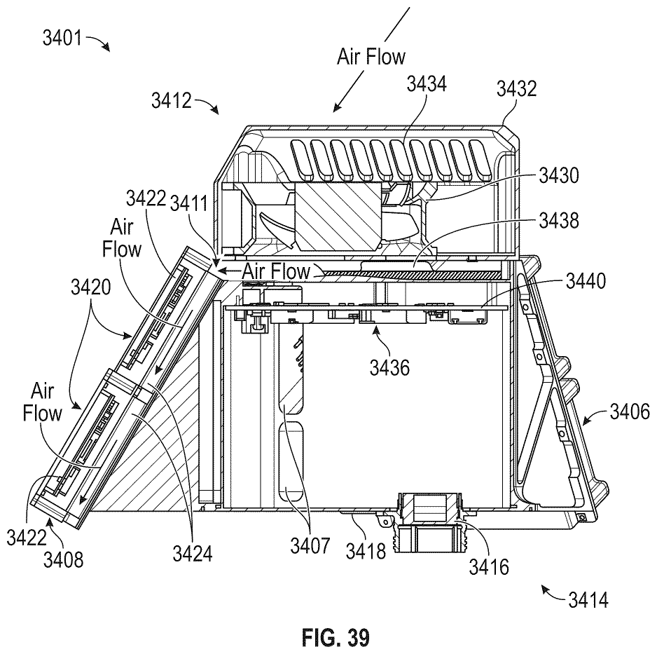

Each of the exterior surfaces 3406 can include at least one slot 3408 configured to receive and secure one or more antenna packages 3420. For example, the slot 3408 can receive and couple to at least one antenna package 3420 (e.g., one, two, three, four, five, six, etc.). As mentioned above, the antenna packages 3420 of the HBFE 404d can monitor a 360° area (or approximately a 360° area), allowing for effective and continuous surveillance of the surrounding area in the horizontal and vertical plane, thus providing hemispherical coverage. Each antenna packages 3420 can be placed at an equal angular distance from the others around the center, ensuring minimal overlap and interference while maximizing coverage. This radial positioning allows each antenna packages 3420 to monitor a specific segment of the environment, collectively covering the entire circumference. The RF system 402 can thus receive and transmit signals across all directions in the plane, ensuring that no single point within the hemispherical field is left unmonitored. For example, the RF system 102 can dynamically track a moving target within its coverage area by seamlessly switching between the antenna packages 3420 as needed. As the target (e.g., an object) moves from the coverage zone of one antenna packages 3420 to another, the RF system 402 can automatically reassign the tracking function to the next antenna packages 3420, allowing for continuous monitoring without any interruptions. This adaptive switching between antennas of the HBFE 404d also optimizes signal quality and accuracy, as the system can prioritize the antenna that provides the strongest, most reliable signal for a given target's location. This functionality can enable the system to maintain continuous contact with a target and to adjust its response in real-time, enhancing the reliability and robustness of tracking. This setup can be advantageous for applications where constant coverage in all directions is desired, such as in radar, surveillance, and communication systems. Additionally, the hemispherical coverage provided by the antenna packages 3420 allows for enhanced reliability, as signals received from multiple directions can be analyzed together to improve accuracy and mitigate signal loss. By coupling each of the antenna packages 3420 of the HBFE 404d to the RF system 402, signal processing algorithms can combine input from each antenna to provide a seamless, comprehensive picture of the monitored area, further supporting robust and high-resolution hemispherical coverage. In some implementations, the antenna packages 3420 coupled to a same exterior surface 3406 can include multiple frequency bands such that no two antenna packages 3420 operate in the same or a similar frequency band. The antenna packages 3420 can include heatsinks 3424 (see FIG. 39) which can also be received into the slot 3408. The slots 3408 can comprise alignment guides or rails within each slot 3408 for positioning and insertion or removal of the antenna packages 3420. The antenna packages 3420 can removably couple to the slot 3408 disposed on each of the exterior surfaces 3406. In some implementations, fasteners (e.g., screws, pins, etc.) couple the antenna packages 3420 to the slot 3408. Each of the antenna packages 3420 in the slots 3408 can be configured to lie flat against the exterior surfaces 3406 of the antenna housing 3401. In some implementations, the exterior surfaces 3406 and the antenna packages 3420 comprise a bottom portion 3423 and a top portion 3421. The bottom portion 3423 can extend outward from the antenna housing 3401 relative to the top portion 3421 such that the top portion 3421 is angled rearward with respect to the bottom portion 3423. For example, the top portion 3412 can be angled rearward with respect to the bottom portion 3423 such that the angle A in FIG. 35 is between approximately 0 degrees to 89 degrees, between approximately 5 degrees to 85 degrees, between approximately 10 degrees to 80 degrees, between approximately 15 degrees to 75 degrees, between approximately 20 degrees to 70 degrees, between approximately 25 degrees to 65 degrees, between approximately 30 degrees to 60 degrees, between approximately 35 degrees to 55 degrees, and between approximately 40 degrees to 50 degrees.

The arrangement of the antenna packages 3420 can advantageously allow the signals received and/or transmitted by the antenna packages 3420 to provide 360-degree coverage around the antenna housing 3401, enabling omnidirectional communication. Said arrangement can further allow the antenna packages 3420 to transmit and/or receive signals from any direction, ensuring consistent connectivity and minimizing blind spots in signal coverage. By arranging multiple antenna packages 3420 around the perimeter of the antenna housing 3401 on the exterior surfaces 3406, the RF system 402 can achieve full spatial coverage. This 360-degree capability can also provide continuous tracking or communication with moving targets or multiple signal sources in different directions. For example, this configuration enables the detection of objects across the entire surrounding area without needing to rotate the antenna physically. Similarly, the 360-degree coverage allows uninterrupted communication with multiple devices or stations located around the module.

The antenna housing 3401 can also include at least one fan 3430 (e.g., cooling fans). The fan 3430 can be coupled to a top portion 3412 of the antenna housing 3401. The fan 3430 can enable or promote air flow within the antenna housing 3401. For example, the fan 3430 can draw air from the environment into an interior space of the antenna housing 3401 to be dispersed for cooling. Antenna packages 3420 disposed on the exterior surfaces 3406 can include one or more heatsinks in which the drawn air can be forced through, advantageously cooling the antenna packages 3420. Additionally, the fan 3430 can provide a variable airflow rate, allowing the antenna housing 3401 to adapt dynamically to the thermal demands of the hardware housed within the antenna packages 3420. To protect the fan 3430 from external debris and accidental contact, a fan cover 3432 can be mounted over the fan 3430. The fan cover 3432 can be constructed from a durable, heat-resistant material with vents 3434 to allow unrestricted airflow while also shielding the fan 3430 from dust and foreign particles. Additionally, the fan cover 3432 can include fasteners (e.g., screws, pins, etc.) for accessing the fans 3430. In some implementations, the fan cover 3432 can also include an integrated, removable fan filter, which can trap debris (e.g., fine particles) before they reach the fans 3430, thereby reducing dust accumulation on the blades of the fan 3430 and within the fan cover 3432.

The antenna housing 3401 can further include a port 3416 extending through a base plate 3418 of the antenna housing 3401. The port 3416 can provide a secure access point for accessing the interior of the antenna housing 3401. Additionally, the port 3416 can include exterior and/or interior threads for mounting the antenna housing 3401 to another device (e.g., module enclosure 410 of the RF system 402) and/or a stationary object. The port 3416 can be dimensioned to accommodate wires and/or cables for operating the antenna packages 3420.

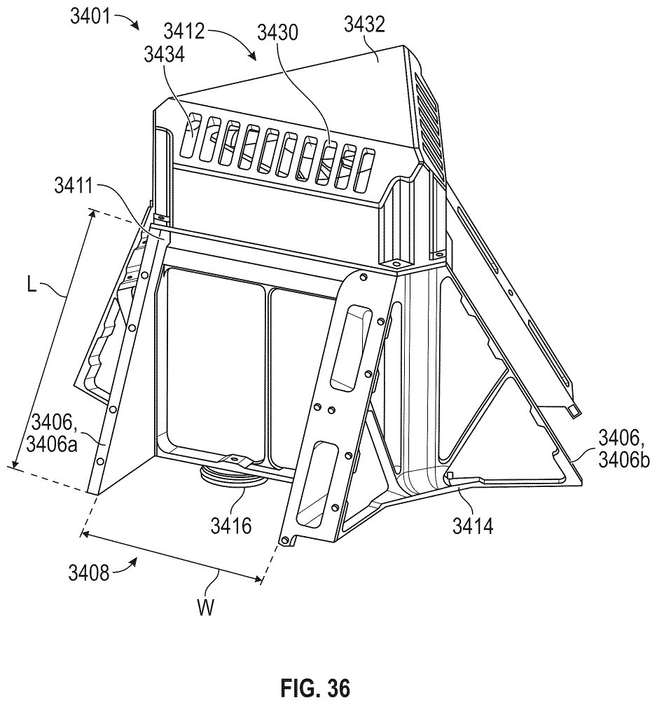

FIGS. 36-38 illustrate various perspective views of the example antenna housing 3401 without the antenna packages 3420 coupled to slots 3408, according to various implementations of the present disclosure. Additionally, FIG. 38 illustrates a perspective view of the example antenna housing 3401 without the antenna packages 3420 coupled to slots 3408 or the fan cover 3432. The antenna housing 3401 can include internal channels 3411 extending through the antenna housing 3401. The internal channels 3411 can advantageously be in fluid communication with the slot 3408 and the fan 3430, and, thus, fluidly coupling the slots 3408 to the fan 3430. Further advantageously, the internal channels 3411 can be configured to allow air to flow from the fan 3430 to the heatsink 3424 of the antenna packages 3420 positioned in the slots 3408. The internal channels 3411 can extend along a width W of the slot 3408. By extending along the width of the slot 3408, the internal channels 3411 can provide consistent airflow and even distribution across the width of the heatsink 3424. Additionally, in some implementations, the internal channels 3411 can extend along a length L of each slot 3408 from a top portion 3412 of the antenna housing 3401 to a bottom portion 3414. The slots 3408 can include a slot surface 3409 on which the heatsink 3424 can abut, extending the length of the internal channels 3411. The slot surface 3409 can extend from the top portion 3412 of the antenna housing 3401 to the bottom portion 3414 to form a continuous alignment guide along the slot 3408. By positioning the slot surface 3409 along the internal channels 3411, the slot surface 3409 can assist with aligning the heatsink 3424 of the antenna packages 3420 with the internal channels 3411 to ensure the heatsink 3424 receives the airflow from the fan 3430.

The exterior surfaces 3406 of the antenna housing 3401 can also include one or more apertures 3407. The apertures 3407 can extend through the exterior surfaces 3406 to an interior space of the antenna housing 3401. The apertures 3407 can align with one or more connectors of the antenna packages 3420 and facilitate the coupling of the antenna packages 3420 to the components and/or connectors housed within the antenna housing 3401. For example, the apertures 3407 can align with internal connectors housed within the antenna housing 3401. The apertures 3407 can be similar or vary in shape, size, and/or orientation. For example, some apertures 3407 can be larger to accommodate connectors requiring broader access, while others can be smaller for finer couplings and/or to support structural integrity. Additionally, the apertures 3407 can be arranged in patterns or arrays, optimizing spatial layout and accessibility within the antenna housing 3401.

As mentioned above, the heatsink 3424 of the antenna packages 3420 can be positioned into the slot 3408. The heatsink 3424 can align with one of the internal channels 3411 such that the heatsink 3424 is advantageously in fluid communication with the internal channel 3411 in order to receive the airflow promoted by the fan 3430. In some implementations, the heatsink 3424 comprises a folded fin heatsink (e.g., zipper fin shape) having a plurality of thin fins. Each of the thin fins can be formed from a thermally conductive material, such as aluminum, copper, and/or a thermally conductive alloy. The thermally conductive material can have high thermal conductivity to facilitate heat dissipation from heat-generating components of the antenna packages 3420. The fins can be configured to maximize surface area exposed to the ambient environment, thereby enhancing convective heat transfer. Additionally, the thermally conductive material can be treated or coated with a thermally emissive finish to further improve heat dissipation efficiency. The thickness, spacing, and orientation of the fins can be optimized to maintain a balance between structural integrity and thermal performance, thereby ensuring heat management while minimizing material use and weight. For example, the fins can be formed in a compact arrangement to create a high-density fin structure. This configuration can allow the fins to draw heat away from heat-generating components within the antenna packages 3420 and dissipate it effectively into the surrounding environment.

In some implementations, the antenna housing 3401 can further temperature sensors to monitor the temperature of each of the antenna packages 3420. The antenna housing 3401 can also include a control unit 3436 disposed on the control board 3440 that is configured to adjust the speed of the motor 3438 of the fan 3430 based at least on the temperature detected by the temperature sensors. The temperature sensors can be positioned adjacent to and/or within each of the antenna packages 3420. For example, the temperature sensors can be embedded and/or adjacent to the antenna 3422 and/or the heatsink 3424 of the antenna packages 3420 (see FIG. 39) to provide real-time temperature measurements to the control unit 3436.

FIG. 39 illustrates a cross-section along a vertical plane of the antenna housing 3401 of FIG. 34, further illustrating the flow path of the air flow through the antenna housing 3401. As shown in FIG. 39, the fan 3430 (e.g., cooling fans) coupled to the top portion 3412 of the antenna housing 3401 can direct airflow through the internal channels 3411 of the antenna housing 3401 and the heatsink 3424 of each of the antenna packages 3420. The fan 3430 can include a motor 3438 with adjustable speed control to vary the airflow based at least on thermal requirements of the antenna packages 3420. The fans 3430 can be configured to draw air into the antenna housing 3401 via the vents 3434 at the top portion 3412 of the antenna housing 3401 and exit out the bottom portion 3414 of the antenna housing 3401. For example, the fan 3430 can draw air through the vents 3434, cause the air to flow through the internal channels 3411 to the heatsink 3424 of the antenna packages 3420 to regulate the temperatures of the antenna packages 3420, and exit the heatsinks 3424 at the bottom portion 3414. The fan 3430 can create a positive pressure system (e.g., fans blow air into the internal channels 3411 of the antenna housing 3401). Alternatively, the fan 3430 can create a negative pressure system (e.g., fans draws air into the heatsinks 3424 and internal channels 3411 of the antenna housing 3401).

As also shown in FIG. 39, the antenna housing 3401 can further include a control board 3440. The control board 3440 can be multifunctional substrate (e.g., a printed circuit board (PCB)) configured to manage fan operation and direct power to various antenna packages 3420 of the antenna housing 3401. The control board 3440 can include circuitry for fan speed control (e.g., control unit 3436), allowing for variable speed adjustments based on temperature or operational requirements. This control ensures cooling while conserving energy by adjusting performance of the fan 3430 in real-time. In addition to fan management, the control board can include a power distribution system that channels and regulates power to antenna packages 3420 of the antenna housing 3401. The control board 3440 can include integrated power management components, such as voltage regulators and current sensors, which ensures that each antenna package 3420 receives the appropriate power level to maintain stable and efficient operation. Additionally, the control board 3440 can also include input/output (I/O) interfaces that enable communication between components of the antenna housing 3401 as well as any external devices (e.g., module enclosure 410).

### HBFE Antenna Packages

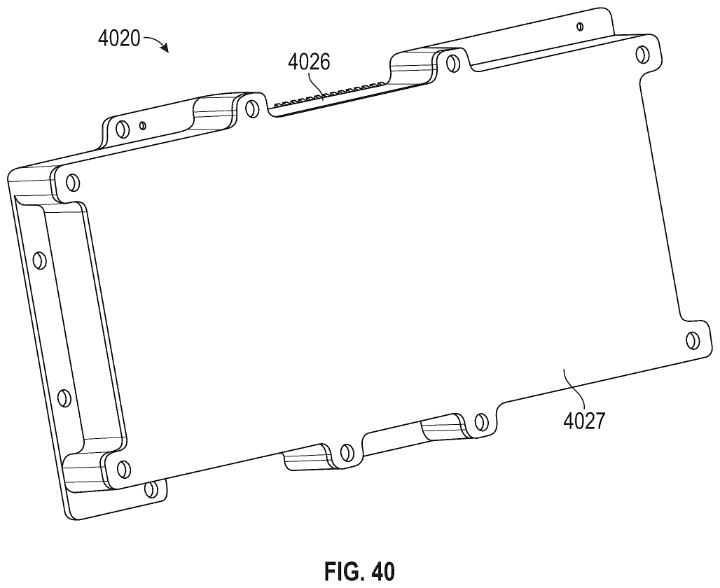

FIG. 40 illustrates a top perspective view of an example implementation of an antenna package 4020, according to various implementations of the present disclosure. In various implementations, the antenna package 4020 can correspond to the antenna package 3420 of FIGS. 34, 35, and 39. The antenna package 4020 can include an antenna package housing 4026 to protect and support the internal components of each antenna package 4020. The antenna package housing 4026 can comprise a rigid and/or strong material, such as metal, plastics (e.g., high-strength plastics), composites, etc. The antenna package 4020 can include a material, or include coatings, to protect internal components from EMI, weather, and/or other adverse conditions. The antenna package housing 4026 can further include connection apertures for coupling the antenna packages 4020 to the slot 3408 along the exterior surfaces 3406 of the antenna housing 3401.

The antenna package housing 4026 also includes a removable antenna package cover 4027 configured to facilitate access to internal components of the antenna package 4020 while maintaining structural integrity and environmental protection. The removeable antenna package cover 4027 which can be secured with fasteners (e.g., quick release fasteners), screws, latches, etc., provides a seal when in place, protecting the internal components from dust, moisture, and/or other external elements. The removable antenna package cover 4027 can comprise the same durable materials as the antenna package housing 4026 itself, the removable antenna package cover 4027 configured to withstand repeated removal and reattachment without compromising its fit and/or protective qualities. Additionally, the removable antenna package cover 4027 can have alignment guides to ensure that the removable antenna package cover 4027 is aligned with the antenna package housing 4026 each time it is reinstalled.

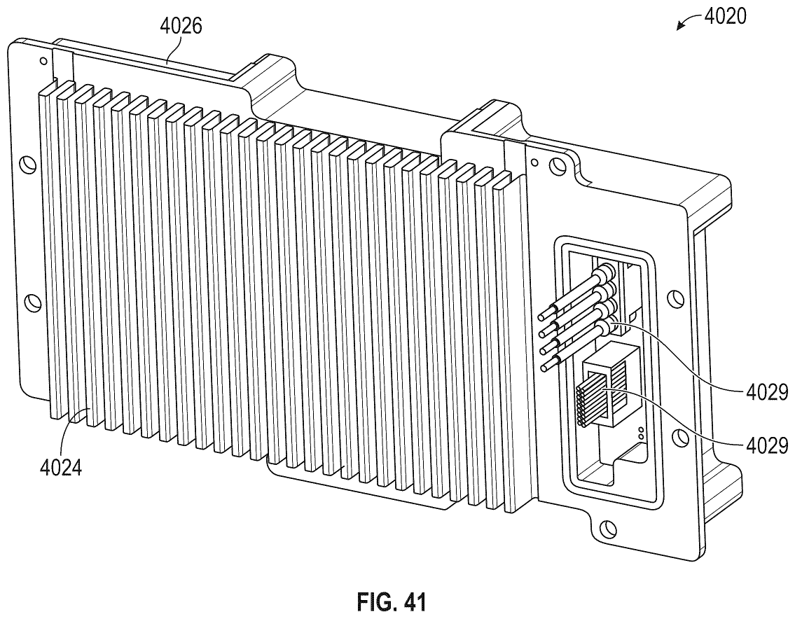

FIG. 41 illustrates a bottom perspective view of the antenna package 4020, according to various implementations of the present disclosure. The antenna package 4020 can include a heatsink 4024 on an opposite surface from the removable antenna package cover 4027. The heatsink 4024 can extend along all or a portion of the width or length of the antenna package 4020. Additionally, the heatsink 4024 can be positioned under the heat-generating components of the antenna packages 4020. The heatsinks 4024 can be advantageously shaped to increase the radiation of heat therefrom and/or to allow increased air flow therethrough to promote the transfer of heat away from any corresponding elements via convection, conduction, and/or radiation. As mentioned above, the heatsink 4024 can include a folded fin configuration, also known as a zipper fin shape. A zipper fin shape can include a plurality of peaks and valleys, which can provide high heat transfer while providing high structural integrity. The heatsink 4024 can include, for example, a plurality of metal (e.g., copper, aluminum, iron, and/or the like) fins. In some implementations, each of the fins is plated in a corrosive-resistant layer, such as a metal (e.g., nickel plating). In some implementations, some of the heatsinks 4024 of the antenna packages 4020 can have longer (or otherwise higher-surface-area) heating elements (e.g., fins) than others of the heatsink 4024. Heating elements with larger surface area may promote improved heat transfer and/or dissipation. Accordingly, some of the antenna packages 4020 can produce higher amounts of heat and therefore be coupled to the heatsink 4024 with larger surface areas than the other heatsinks.

The antenna packages 4020 can also include connectors 4029 for electrically coupling the antenna packages 4020 and the antenna housing 3401, which can further interface with the control board 3440 or other internal circuitry, for example, as shown in FIG. 39. The connectors 4029 can support data and power transmission, allowing the antenna packages 3420 to communicate with and be controlled by components within the antenna housing 3401. The connectors 4029 can fit through apertures 3407 in the antenna housing 3401, ensuring physical and electrical coupling. In some implementations, the connectors 4029 are pin-type connectors, where each pin aligns with a corresponding socket or contact point in the antenna housing 3401. The connectors 4029 can also include other configurations, such as blade connectors, edge connectors, and/or coaxial connectors, depending on signal and power needs. For high-frequency signal transmission, coaxial connectors may be used to preserve signal integrity and limit electromagnetic interference (EMI). In other cases, edge or ribbon connectors may be used for high-density or space-limited applications, allowing multiple data channels in a compact setup. To secure the coupling, some implementations of the connectors 4029 include locking mechanisms, such as latches, clips, and/or screws, which engage with the antenna housing 3401. This mechanical stability prevents accidental decoupling caused by vibrations and/or movement, maintaining uninterrupted operation.

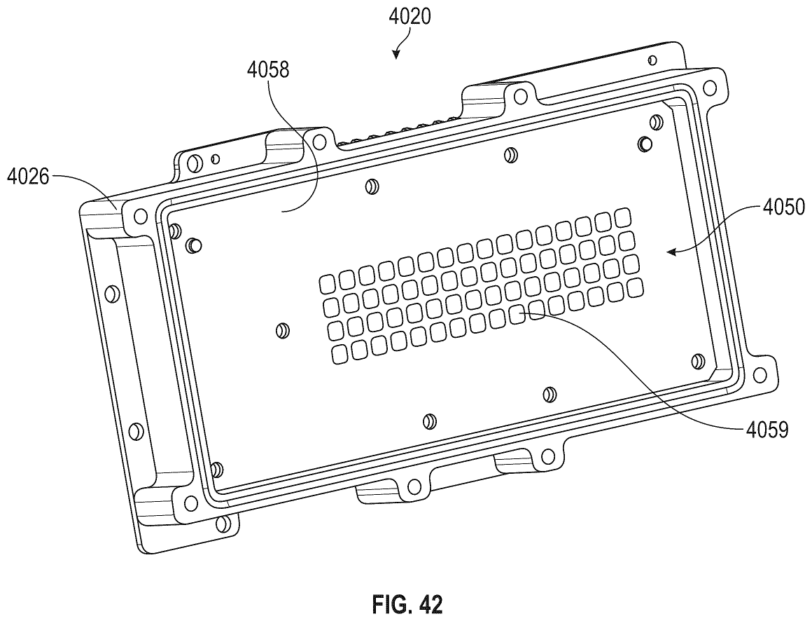

FIG. 42 illustrates a top perspective view of the antenna packages 4020 without the removable antenna package cover 4027, according to various implementations of the present disclosure. As shown in FIG. 42, the antenna packages 4020 can include an antenna 4050 with radiator elements 4059 (further described below), arranged in a phased array configuration, for directionally transmitting and/or receiving signals. In a phased array antenna system, the antenna 4050 can comprise multiple individual elements and/or modules that work together to form a beam of electromagnetic energy. These antenna elements can be arranged in a pattern one or more substrates within the antenna package housing 4026, allowing the system to control the direction of the signal without physically moving the antenna 4050. To do so, the antenna 4050 uses constructive and destructive interference. By controlling the phase of the signal emitted or received by each individual antenna element 4050, the system can manipulate the wavefronts of the signals to either enhance (constructive interference) or cancel out (destructive interference) certain directions of signal propagation. In constructive interference, the signals from multiple antenna elements are aligned in phase, leading to a stronger signal in the desired direction. In contrast, destructive interference occurs when the signals from different elements are out of phase, effectively canceling out signals in other directions, thus minimizing interference and focusing the energy in a specific direction.

Each antenna package 4020 that houses an antenna 4050 can include phase shifters and/or beamforming circuitry to control the phase of each antenna element. By adjusting the phase of each signal in real-time, the phased array antenna can electronically steer its beam, directing the transmission or reception toward a specific target without mechanical movement. This allows for highly dynamic and flexible signal steering, which can be ideal for applications such as radar systems, satellite communications, and wireless networks where fast, precise control of the antenna's direction is required. Furthermore, the antenna package housing 4026 can be designed to support the electrical and thermal requirements of the antenna elements. This may include provisions for power distribution, heat dissipation, and shielding to prevent electromagnetic interference (EMI) from affecting the antenna's performance. The integration of the antenna 4050 with other system components within the antenna package housing 4026 allows for a compact, modular design that is scalable to meet the needs of the specific application.

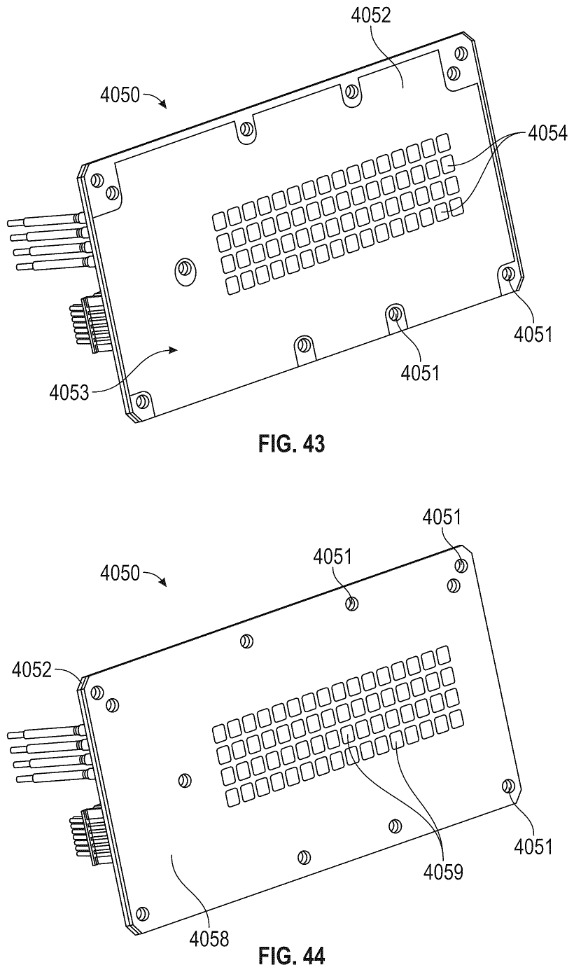

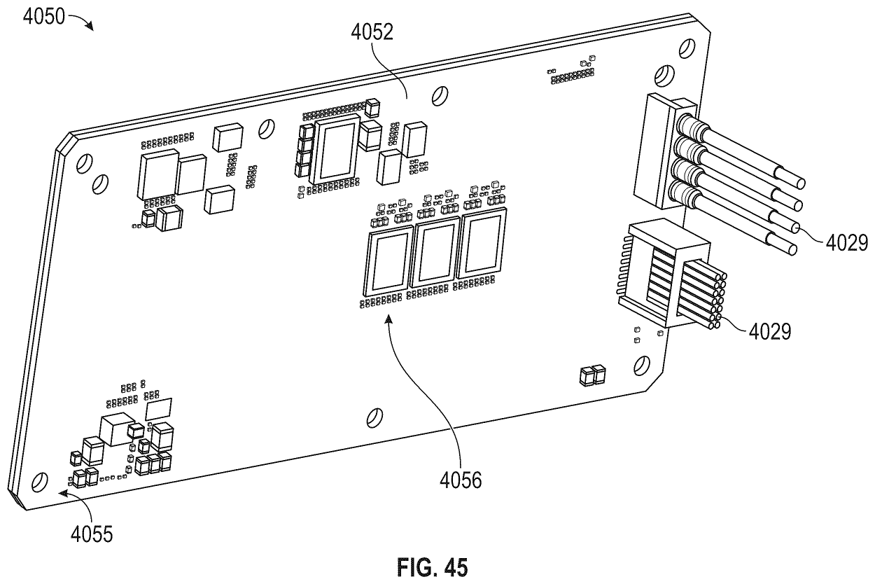

FIG. 43 illustrates a perspective view of the first substrate 4052 of the antenna 4050, according to various implementations of the present disclosure. The first substrate 4052 can include an array of antenna elements 4054 (e.g., beam receivers and/or transmitters) arranged on a first surface 4053 of the first substrate 4052. These antenna elements 4054 can enable both the transmission and reception of electromagnetic signals. Each antenna element 4054 can comprise a conductive material, such as copper, having high conductivity, low resistance, and durability, ensuring efficient signal transmission with minimal power loss. The arrangement of antenna elements 4054 on the first substrate 4052 can be configured to optimize the ability of the antenna 4050 to generate and control beam direction. The antenna elements 4054 can be laid out in linear, circular, or grid configurations, depending on the beamforming requirements and/or operating frequencies of the system. By positioning the antenna elements 4054 at specific distances—typically fractions of the signal wavelength—the antenna 4050 can achieve constructive and destructive interference patterns that enable control over signal direction. The antenna elements 4054 can be in communication with integrated components 4056, such as phase shifters or variable capacitors, on a second surface 4055 (see FIG. 45) of the first substrate 4052 to adjust the phase and amplitude of the signals independently. The integrated components 4056 can allow each antenna elements 4054 to contribute to the collective beam steering capability of the array. The first substrate 4052 can comprise a dielectric, such as FR4, PTFE, or ceramic, which support stable signal performance over a wide range of frequencies. Additionally, grounding layers or additional shielding elements can be embedded within or beneath the first substrate 4052 to minimize electromagnetic interference (EMI) from other components in the system, preserving the integrity of the transmitted or received signals.

FIG. 44 illustrates a perspective view of the second substrate 4058 of the antenna 4050, according to various implementations of the present disclosure. The second substrate 4058 can be stacked (e.g., directly stacked) on top of the first substrate 4052 to create a multi-layer structure. The second substrate 4058 can include array of radiator elements 4059, each of which is aligned with a corresponding antenna element 4054 on the first substrate 4052. This alignment can allow the radiator elements 4059 to interact directly with the signals generated or received by the antenna elements 4054, functioning to radiate or capture electromagnetic waves efficiently. Each radiator element 4059 can comprise a conductive material, such as copper, chosen for its signal propagation characteristics and/or low signal loss. The radiator elements 4059 can be positioned in a pattern that optimizes signal gain and directivity, effectively amplifying the signal strength and improving the overall efficiency of the antenna 4050. The alignment of radiator elements 4059 with antenna elements 4054 can also enable impedance matching between the first substrate 4052 and second substrate 4058, minimizing signal reflection and maximizing the amount of energy that is radiated or captured by the antenna 4050. The second substrate 4058 can comprise a dielectric, such as ceramic, PTFE, or low-loss composite materials, to minimize energy dissipation and support high-frequency performance. Additionally, the dielectric properties of the second substrate 4058 can support a controlled propagation of electromagnetic waves, allowing for improved radiation patterns and greater control over beam directionality. Furthermore, the physical stacking of the second substrate 4058 on top of the first substrate 4052 can allow the overall structure of the antenna 4050 to remain compact. This compact, multi-layer design can improve the electrical performance of the phased array, and can also improve its mechanical stability, enabling it to withstand environmental stressors and maintain alignment between the substrates.

To ensure alignment and attachment between the first substrate 4052 and the second substrate 4058, an adhesive layer can be applied between the first substrate 4052 and the second substrate 4058. This adhesive can comprise a dielectric material to maintain insulation between the first substrate 4052 and the second substrate 4058 while providing strong bonding that withstands environmental stressors, such as vibration or thermal expansion. To further facilitate alignment, both the first substrate 4052 and the second substrate 4058 can include alignment holes 4051 positioned along the surfaces of the first substrate 4052 and the second substrate 4058. These alignment holes 4051 can allow for mechanical guides and/or pins during the assembly process, ensuring that the antenna elements 4054 on the first substrate 4052 are aligned with the radiator elements 4059 on the second substrate 4058. This alignment can improve signal propagation and impedance matching, contributing to the overall performance and reliability of the antenna 4050.

FIG. 45 illustrates a perspective view of the second surface 4055 of the first substrate 4052, according to various implementations of the present disclosure. As mentioned above, the integrated components 4056 can be disposed on the second surface 4055 of the first substrate 4052, opposite to the array of antenna elements 4054 on the first surface 4053. These integrated components 4056 can include various types of electronic circuitry and components for the functionality and control of the antenna 4050. Examples of such components include phase shifters, amplifiers, signal processors, and/or impedance-matching circuits, which work together to manage the phase and amplitude of the signals transmitted and received by each antenna element 4054. By placing these components on the second surface 4055, the arrangement maintains a separation between the antenna elements 4054 and the signal-processing electronics, reducing potential interference and minimizing signal loss. The placement of the integrated components 4056 on the second surface 4055 also advantageously allow for heat dissipation, as thermal management solutions, such as heatsinks (e.g., heatsink 4024) or thermal pads, can be applied directly to the exposed surface of these components without obstructing the antenna array on the opposite side. Moreover, the layout of the integrated components 4056 on the second surface 4055 can be arranged to align with the electrical pathways and vias that couple them to the antenna elements 4054. This ensures that signals can travel with minimal resistance and delay between the control electronics and the antenna 4050, supporting rapid, real-time adjustments for precise beam steering and phased array operation.

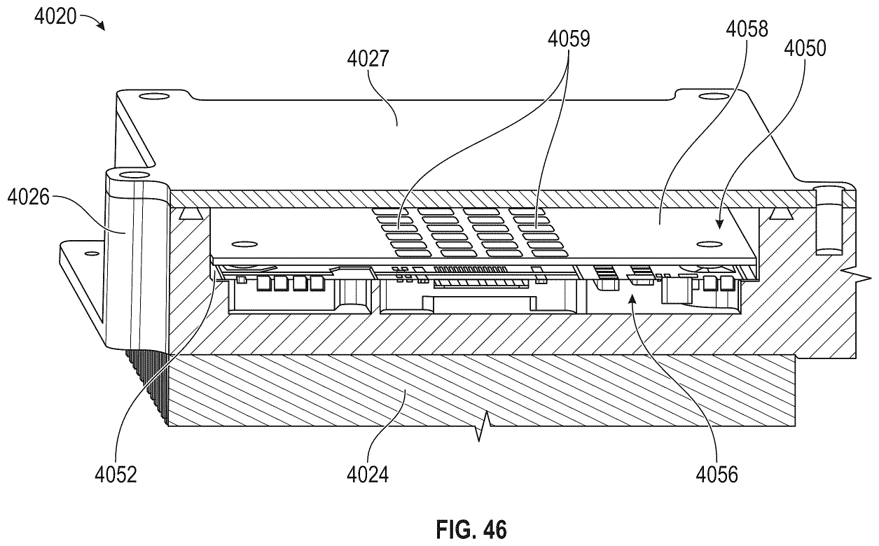

FIG. 46 illustrates a schematic cross section of a side view of the antenna packages 4020, according to various implementations of the present disclosure. As shown in FIG. 46, the integrated components 4056 on the second substrate 4058 can be positioned on the side closest to the heatsink 4024, which manages thermal distribution within the antenna packages 4020. This arrangement advantageously places the heat-generating components of the integrated components 4056 in proximity to the heatsink 4024, allowing for heat transfer away from the integrated components 4056. The heatsink 4024 can absorb and dissipate the thermal energy produced by the integrated components 4056, preventing overheating and ensuring stable performance. Further advantageously, in some implementations, by positioning the integrated components 4056 near the heatsink 4024, thermal interface materials (TIMs), such as thermal pads or conductive adhesives, can be positioned between the integrated components 4056 and the heatsink 4024. These TIMs fill air gaps between surfaces, improving contact and heat transfer. This setup is useful in high-power or high-frequency applications, where heat buildup may otherwise impair the performance or lifespan of the integrated components 4056. As mentioned above, in some implementations, the heatsink 4024 can include fins, grooves, etc. to increase its surface area, further enhancing heat dissipation. Cooling efficiency can be supported by forced airflow (e.g., airflow from fan 3430) or additional cooling mechanisms integrated into the antenna housing 3401 and/or antenna packages 4020. By ensuring that the integrated components 4056 are positioned closest to the heatsink 4024, the arrangement keeps operating temperatures low, allowing the antenna 4050 to perform under various conditions.

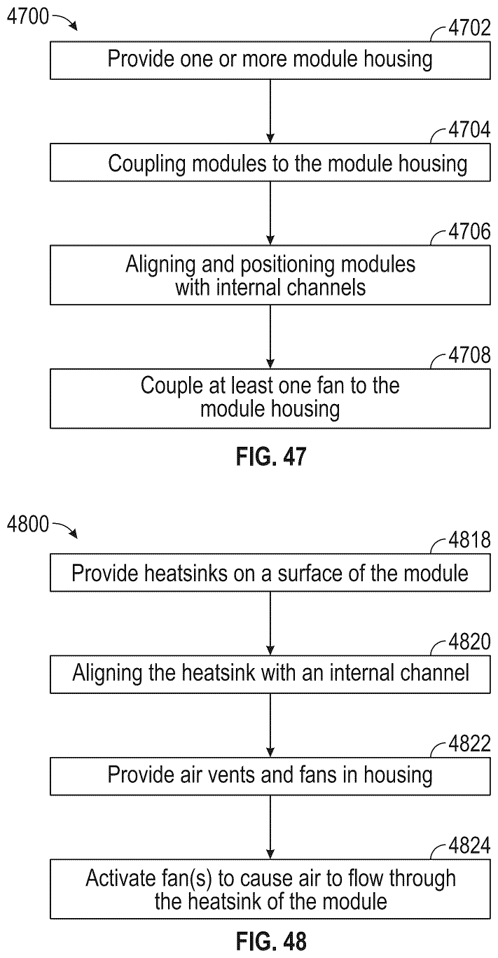

FIG. 47 illustrates an example process 4700 of assembling an antenna housing 3401 for an RF system, according to various implementations of the present disclosure. Although FIG. 47 discloses one example, other methods of assembling the antenna housing are possible and described elsewhere herein. Further, in various implementations various blocks of the flow or method may be rearranged, optional, and/or omitted, and/or additional blocks may be added. The blocks illustrated schematically in FIG. 47 are described with reference to certain hardware components of the present disclosure. However, it will be understood that the hardware components of FIG. 47 and/or individual components or subsets thereof may equally be implemented in conjunction with other hardware components, software components, and/or systems without departing from the scope of the present disclosure.

At block 4702, the method can include providing one or more antenna housings (e.g., the antenna housing 3401). At block 4704 the method includes couplings one or more antenna packages (e.g., antenna packages 3420) into one or more slots (e.g., slots 3408) on the exterior surfaces of the antenna housing. The method can include assembly of the one or more elements without the need for tools. The antenna housing can include a locking mechanism that couples the antenna packages to the slots of the antenna housing.

At block 4706, the method can include aligning and positioning the antenna packages with a corresponding internal channel (e.g., internal channels 3411). A heatsink (e.g., heatsink 3424) of the antenna packages can be in fluid communication with the internal channel.

At block 4708, the method includes coupling at least one fan (e.g., fan 3430) to a top of the antenna housing. The fan can cause air to flow through the antenna housing, out of the antenna housing via the internal channels, and through the heatsinks of the antenna packages coupled to the slots.

FIG. 48 illustrates an example process 4800 of managing thermal transfer in a module of an antenna housing for an RF system, according to various implementations of the present disclosure. Although FIG. 48 discloses one example, other methods of managing thermal transfer in an RF system are possible and described elsewhere herein. Further, in various implementations various blocks of the flow or method may be rearranged, optional, and/or omitted, and/or additional blocks may be added. The blocks illustrated schematically in FIG. 48 are described with reference to certain hardware components of the present disclosure. However, it will be understood that the hardware components of FIG. 48 and/or individual components or subsets thereof may equally be implemented in conjunction with other hardware components, software components, and/or systems without departing from the scope of the present disclosure

At block 4818, the method includes providing a heatsink (e.g., heatsink 3424) on a side of a module (e.g., antenna packages 3420) to be coupled to an antenna housing. The heatsinks can be coupled to a bottom surface of the antenna packages, which can be in proximity to heat generating electronic components. The heatsinks can include a zipper fin or other structure configured to draw heat away from the heatsinks and/or other components of the module.

At block 4820 the method includes aligning the heatsinks with a slot and corresponding internal channel (e.g., internal channels 3411) configured to provide cool air of the antenna housing. The internal channels can extend along a width of the slot (e.g., slot 3408) to provide consistent airflow to the heatsinks. In some implementations, the internal channel can extend along the length of the slot such that the heatsink is disposed in and surrounded by the internal channel. The heatsink can be disposed against a slot surface which can assist with aligning the heatsink with the internal channel.

Air movement can be promoted via air vents and/or cooling fans disposed in or on the antenna housing, at block 4822. The cooling fan can push air through the antenna housing and internal channels. For example, at block 4824 the method can include activating the cooling fans to cause air to flow through the one or more internals channels of the antenna housing (e.g., into the internal channels from the antenna housing, through heatsinks, and out of an opposite side of the heatsink). This may provide improved cooling of the one or more heatsinks and/or antenna packages described herein.

### Additional Implementation Details and Embodiments

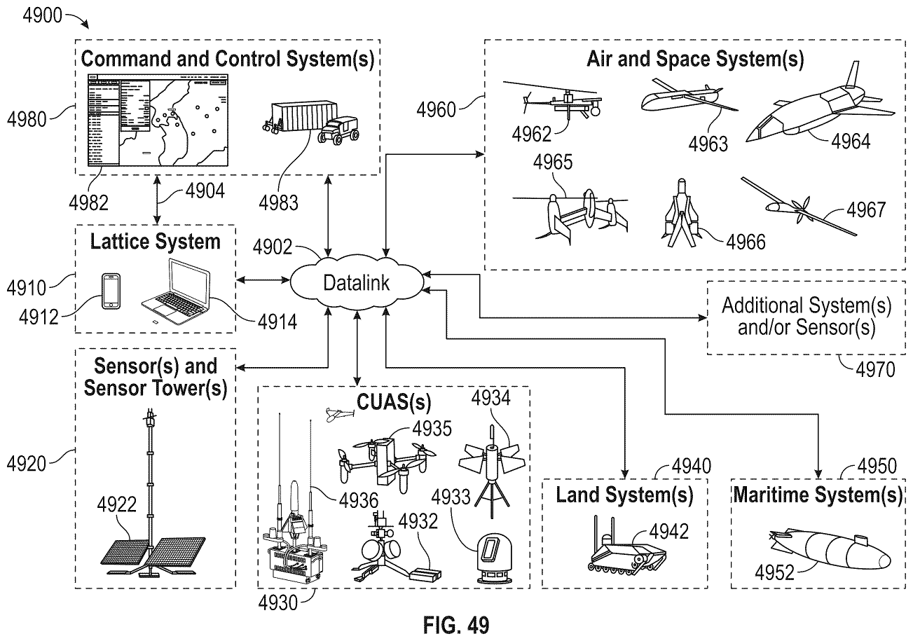

FIG. 49 illustrates a block diagram of an example operational environment 4900 of the system, according to various implementations. The example operational environment 4900 can be similar to, or the same as, or include components similar to the operating environment 100 described in reference to FIG. 1. For example, the operational environment 4900 can include one or more RF systems 102 and/or RF systems 106 (e.g., various sensors and/or systems described herein), one or more central processing servers 107 (e.g., Lattice system 4910, control and communications system(s) 4980, and/or other components described below in reference to FIG. 49), one or more additional systems and sensors 104 (e.g., various sensors and systems described below in reference to FIG. 49), one or more networks 112 (e.g., various networks and/or datalinks described below in reference to FIG. 49), and/or additional components as described herein.

For example, and as illustrated in the example of FIG. 49, the example operational environment 4900 optionally includes, for example, vehicles such as land system(s) 4940, maritime system(s) 4950, air and/or space system(s) 4960, and/or counter unmanned arial system(s) 4930 (referred to herein as “CUAS(s)” 4930). As also illustrated, the operational environment 4900 optionally includes, for example, one or more external computing devices such as a Lattice system 4910, control and communication system(s) 4980 (such as, e.g., Menace), and/or the like. As further illustrated, the operational environment 4900 optionally includes, for example, data sources and/or sensors such as one or more sensor(s) and/or sensor tower(s) 4920, and/or CUAS(s) 4930. As also illustrated, the operational environment 4900 optionally includes, for example, networks and/or datalinks such as network and/or datalink 4902 (which can be similar to network 112) which can provide communications among the various components of the operational environment 4900. In some cases, the operational environment 4900 also includes various direct and/or alternative communications links among various components, such as communications link 4904 between the Lattice system 4910 and the control and communications system 4980.

The groupings of components in the example operational environment 4900 illustrated in FIG. 49 and described above is illustrative and not limiting. For example, various components are organizable into groups different from those described above, and/or into multiple groups. For example, in various implementations any of the various vehicles (e.g., land system 4940, maritime systems 4950, and/or air and space systems 4960) also include sensor and/or data source functionality by way of various sensors (e.g., cameras, radar devices, and/or any other sensors 104) included in or on those vehicles. Similarly, any of the various sensors (e.g., sensors and sensor towers 4920, CUASs 4930, and/or the like) optionally also comprise and/or are associated with vehicles. Further, in some cases, the operational environment 4900 includes components different from those described in reference to FIG. 49, and/or additional system(s) (e.g., vehicles, computing systems, and/or the like) and/or sensor(s) 4970.

Sensors and sensor towers 4920 include, for example, a sentry tower 4922. Examples of such sensor towers and associated functionality are described in U.S. Patent Publication No. 2022/0377232, published Nov. 24, 2022, and titled “Auto-Focus Acquisition For Remote Flying Targets” (the '232 Publication), the entire disclosure of which is hereby made part of this specification as if set forth fully herein and incorporated by reference for all purposes, for all that it contains.

CUASs 4930 include, for example, a long-range sentry tower 4932, a wide-area infrared system for persistent surveillance (“WISP”) 4933, a software-defined electromagnetic warfare (“EW”) device/system (e.g., “Pulsar system”) 4934, an autonomous counter unmanned arial system drone device (e.g., an “Anvil device”) 4935, and/or multi-mission electromagnetic warfare system (e.g., a “Polaris system”) 4936 (e.g., an RF system as described herein). CUASs 4930, in some cases, include various autonomous functionalities, such as movement, goal seeking, ISR (“intelligence, surveillance, and reconnaissance”), and/or the like. Examples of such Pulsar and Polaris systems and associated functionality are described herein and also in PCT International Publication No. 2023/225417, published Nov. 23, 2023, and titled “Modular System For Detecting, Tracking, And Transmitting To Identified Objects” (the '417 Publication), the entire disclosure of which is hereby made part of this specification as if set forth fully herein and incorporated by reference for all purposes, for all that it contains. Examples of such Anvil devices and associated functionality are described in U.S. Patent Publication No. 2020/0363824, published Nov. 19, 2020, and titled “Counter Drone System” (the '824 Publication), the entire disclosure of which is hereby made part of this specification as if set forth fully herein and incorporated by reference for all purposes, for all that it contains.

Land systems 4940 include, for example, various land-based vehicles 4942, such as automobiles, tanks or other armored vehicles, all-terrain vehicles, and/or the like. Land systems 4940, in some cases, include various autonomous functionalities, such as movement, goal seeking, ISR, and/or the like.

Maritime systems 4950 include, for example, a boat, a ship, and/or a submarine 4952. Maritime systems 4950, in some cases, include various autonomous functionalities, such as movement, goal seeking, ISR, and/or the like.

Air and/or space systems 4960 include, for example, an extended-range unmanned aircraft system (“UAS”) 4962, an air-breathing autonomous air vehicle (“AAV”) 4963, a group 5 AAV 4964, a tandem rotor AAV 4965, a vertical take-off and landing (“VTOL”) AAV 4966, an autonomous launch effect 4967, an airplane, a balloon, a missile, a rocket, a satellite, and/or the like. Examples of such UASs and associated functionality are described in U.S. Patent Publication No. 2020/0126431, published Apr. 23, 2020, and titled “Ruggedized Autonomous Helicopter Platform” (the '431 Publication), the entire disclosure of which is hereby made part of this specification as if set forth fully herein and incorporated by reference for all purposes, for all that it contains. Examples of such tandem rotor AAVs and associated functionality are described in U.S. Patent Publication No. 2024/0262489, published Aug. 8, 2024, and titled “Dual Engine Vertical Take Off And Landing Collapsible Fixed Wing Aircraft” (the '489 Publication), the entire disclosure of which is hereby made part of this specification as if set forth fully herein and incorporated by reference for all purposes, for all that it contains. Examples of such autonomous launch effect and associated functionality are described in U.S. Pat. No. 9,545,991, issued Jan. 17, 2017, and titled “Aerial Vehicle With Deployable Components” (the '991 Patent), the entire disclosure of which is hereby made part of this specification as if set forth fully herein and incorporated by reference for all purposes, for all that it contains.

In various implementations, and as described above, various components of the operational environment 4900 advantageously include autonomous functionality. This means, for example, that submarine 4952 and/or VTOL AAV 4966 is able to operate and pursue mission objectives and/or tasks autonomously. Such components, in some cases, also are able to autonomously coordinate with each other in pursuit of mission objectives and/or tasks.

In various implementations, various components of the operational environment 4900 include munitions capabilities. Such capabilities, in some cases, are used by these components in pursuit of mission objectives and/or tasks.

In various implementations, and as described above, various vehicles and systems of the operational environment 4900 include sensor, munitions, and/or other functionality specific to the types of vehicles or systems. For example, in some cases a submarine includes SONAR functionality, a UAS or AAV includes camera functionality, and a sensor tower includes radar functionality.

In some examples, the Lattice system 4910 comprised a software platform advantageously capable of being used for a variety of missions and industries. The Lattice system 4910 communicates with any type of sensor, network, and/or system, and receives, integrates, and/or sends data and/or communications. The Lattice system 4910 moves data received from the various systems with which it communicates into a single integration layer that uses AI, machine learning, and/or sensor and data processing techniques to, e.g., filter high-value information to users. The filtering and the functionality of the Lattice system 4910 advantageously enables quick reactions to the data by tasking other systems such as sensors, vehicles, or other assets within and via the platform itself. Communications among the Lattice system 4910 and various components of the operational environment 4900 (e.g., vehicles, sensors, system, networks, and/or the like) are provided via various networks and/or datalinks, and in some cases includes “mesh” type communications. Examples of such mesh and/or secure communications, and/or other functionality and/or operations of the Lattice system 4910, are described in U.S. Patent Publication No. 2019/0380032, published Dec. 12, 2019, and titled “Lattice Mesh” (the '032 Publication), the entire disclosure of which is hereby made part of this specification as if set forth fully herein and incorporated by reference for all purposes, for all that it contains.

The Lattice system 4910 provides various ways of presenting data and/or enabling user interactions. This includes, for example, various interactive graphical user interfaces provided via user devices such as smartphones 4912 and/or other computing devices 4914. Further examples of sensors, vehicles, and/or systems in the operational environment 4900, and/or operation of the Lattice system 4910, are described in U.S. Patent Publication No. 2020/0167059, published May 28, 2020, and titled “Interactive Virtual Interface” (the '059 Publication), and the '824 Publication, the entire disclosures of each of which are hereby made part of this specification as if set forth fully herein and incorporated by reference for all purposes, for all that they contain.

The control and communications system 4980 includes any existing and/or legacy systems for providing control and communications over, for example, various sensors, systems, and/or vehicles. These control and communications systems 4980 includes various computer systems, user interfaces 4982, hardware and/or devices 4983, and/or the like. The Lattice system 4910 advantageously communicates with the control and communications system 4980 and integrates with the control and communications system 4980 to provide various of the functionality described herein. This includes, for example, communications and coordination with various sensors, systems, and/or vehicles, including to execute missions and achieve operational objectives. These functionalities include providing instructions to various autonomous systems, and enabling various systems to communicate and coordinate with each other.

Various components of the operational environment 4900, according to various implementations, include configurable computers (e.g., computer system 300) and/or other components and/or functionality of the present disclosure. For example, various of the CUASs 4930, land systems 4940, maritime systems 4950, air and space systems 4960, and control and communications systems 4980 each optionally include configurable computers. By way of the combination of the configurable computers, each vehicle and/or system advantageously has functionality specific to that vehicle or system, or type of vehicle or system. Such functionality optionally includes, as described herein, receiving sensor and/or operational data, and executing controls to perform tasks and/or seek mission objectives, within the operational environment 4900.

Various components of the operational environment 4900, according to various implementations, include signal transmission and reception systems, object detection systems, and other related components and functionalities. For example, various of the CUASs 4930, land systems 4940, maritime systems 4950, and air and space systems 4960 each optionally include signal and detection management systems. In each case, these systems optionally include respective common and/or similar signal processing boards and application-specific boards. By combining the signal processing board with the application-specific board, each system advantageously performs functions tailored to its specific requirements or type. Such functionality optionally includes, as described herein, detecting objects, receiving sensor or communication data, processing these signals, and transmitting responses or commands to perform tasks and achieve operational objectives within the operational environment 4900.

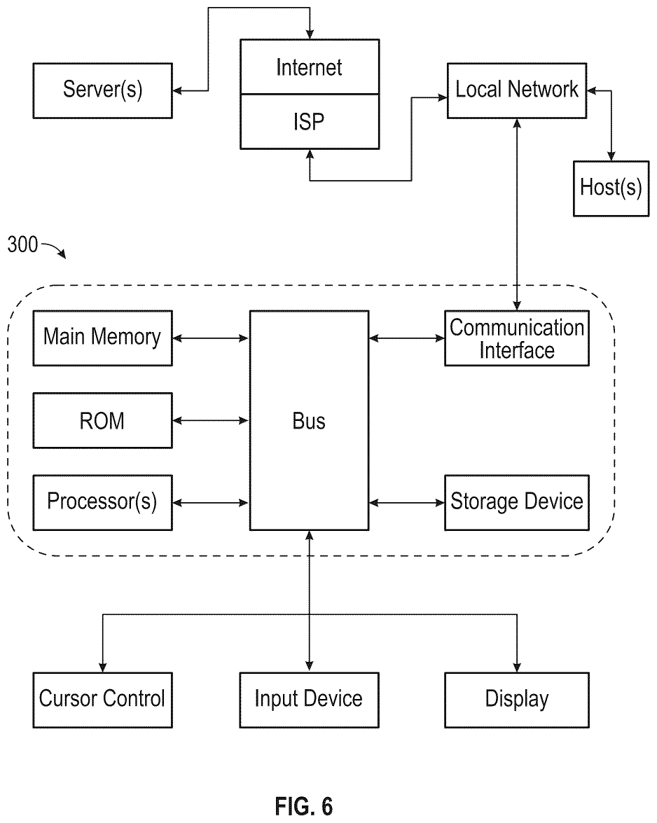

In various implementations, the system (e.g., one or more aspects of the RF system 102, RF systems 106, the central processing server 107, user devices 110, other aspects of the operational environment 100, and/or the like) comprise, or are implemented in, a “virtual computing environment”. As used herein, the term “virtual computing environment” should be construed broadly to include, for example, computer-readable program instructions executed by one or more processors (e.g., as described in the example of FIG. 6) to implement one or more aspects of the modules and/or functionality described herein. Further, in this implementation, one or more services/modules/engines and/or the like, of the system are to be understood as comprising one or more rules engines of the virtual computing environment that, in response to inputs received by the virtual computing environment, execute rules and/or other program instructions to modify operation of the virtual computing environment. For example, a request received from the user computing device is to be understood as modifying operation of the virtual computing environment to cause the request access to a resource from the system. Such functionality optionally comprises a modification of the operation of the virtual computing environment in response to inputs and according to various rules. Other functionality implemented by the virtual computing environment (as described throughout this disclosure) optionally further comprises modifications of the operation of the virtual computing environment, for example, the operation of the virtual computing environment optionally changes depending on the information gathered by the system. Initial operation of the virtual computing environment is to be understood as an establishment of the virtual computing environment. In some implementations the virtual computing environment comprises one or more virtual machines, containers, and/or other types of emulations of computing systems or environments. In some implementations the virtual computing environment comprises a hosted computing environment that includes a collection of physical computing resources that are remotely accessible and are rapidly provisionable as needed (commonly referred to as “cloud” computing environment).

Implementing one or more aspects of the system as a virtual computing environment optionally advantageously enables executing different aspects or modules of the system on different computing devices or processors, which increases the scalability of the system. Implementing one or more aspects of the system as a virtual computing environment optionally further advantageously enables sandboxing various aspects, data, or services/modules of the system from one another, which increases security of the system by preventing, e.g., malicious intrusion into the system from spreading. Implementing one or more aspects of the system as a virtual computing environment optionally further advantageously enables parallel execution of various aspects or modules of the system, which increases the scalability of the system. Implementing one or more aspects of the system as a virtual computing environment optionally further advantageously enables rapid provisioning (or de-provisioning) of computing resources to the system, which increases scalability of the system by, e.g., expanding computing resources available to the system or duplicating operation of the system on multiple computing resources. For example, in some cases the system is usable by thousands, hundreds of thousands, or even millions of users simultaneously, and many megabytes, gigabytes, or terabytes (or more) of data are transferred or processed by the system, and scalability of the system enables such operation in an efficient and/or uninterrupted manner.

Various implementations of the present disclosure comprise one or more systems, methods, computer-readable storage mediums, and/or computer program products at any possible technical detail level of integration. In various implementations, a computer program product (or products) includes one or more computer-readable storage mediums. The computer-readable storage medium(s), according to various implementations, comprise, are configured to store, and/or store computer-readable program instructions that are executable to cause a processor to carry out aspects of the present disclosure.

For example, various of the functionality described herein, in some implementations, is performed as software instructions that are executed by, and/or in response to software instructions being executed by, one or more hardware processors and/or any other suitable computing devices. The software instructions and/or other executable code may be read from one or more computer-readable storage mediums.

The computer-readable storage medium(s) is a tangible device that retains and stores data and/or instructions for use by an instruction execution device, e.g., a processor. The computer-readable storage medium may be, for example, but is not limited to, an electronic storage device (including any volatile and/or non-volatile electronic storage devices), a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a solid state drive, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer-readable program instructions described herein, according to some implementations, are downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers, and/or edge servers. In some implementations, a network adapter card or network interface in each computing/processing device receives computer-readable program instructions from the network and forwards the computer-readable program instructions for storage in a computer-readable storage medium within the respective computing/processing device.

Computer-readable program instructions (as also referred to herein as, for example, “code,” “instructions,” “module,” “application,” “software application,” and/or the like) for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Java, C++, or the like, and procedural programming languages, such as the “C” programming language or similar programming languages. Computer-readable program instructions may be callable from other instructions or from itself, and/or may be invoked in response to detected events or interrupts. Computer-readable program instructions configured for execution on computing devices may be provided on a computer-readable storage medium, and/or as a digital download (and may be originally stored in a compressed or installable format that requires installation, decompression or decryption prior to execution) that may then be stored on a computer-readable storage medium. Such computer-readable program instructions may be stored, partially or fully, on a memory device (e.g., a computer-readable storage medium) of the executing computing device, for execution by the computing device. According to various implementations, computer-readable program instructions execute entirely on a user's computer (e.g., the executing computing device), partly on the user's computer as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) executes the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, are implementable by computer-readable program instructions.

These computer-readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the function/act specified in the flowchart(s) and/or block diagram(s) block or blocks.

The computer-readable program instructions may also be loaded onto a computer, other programmable data processing apparatus, or other device to cause a series of operational steps to be performed on the computer, other programmable apparatus or other device to produce a computer-implemented process, such that the instructions which execute on the computer, other programmable apparatus, or other device implement the functions/acts specified in the flowchart and/or block diagram block or blocks. For example, the instructions may initially be carried on a magnetic disk or solid-state drive of a remote computer. The remote computer may load the instructions and/or modules into its dynamic memory and send the instructions over a telephone, cable, or optical line using a modem. A modem local to a server computing system may receive the data on the telephone/cable/optical line and use a converter device including the appropriate circuitry to place the data on a bus. The bus may carry the data to a memory, from which a processor may retrieve and execute the instructions. The instructions received by the memory may optionally be stored on a storage device (e.g., a solid-state drive) either before or after execution by the computer processor.

The flowchart and block diagrams in the Figures illustrate the architecture, functionality, and operation of possible implementations of systems, methods, and computer-program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks occur out of the order noted in the Figures. For example, two blocks shown in succession may be executed substantially concurrently, or the blocks may sometimes be executed in the reverse order, depending upon the functionality involved. In addition, certain blocks may be omitted in some implementations. The methods and processes described herein are also not limited to any particular sequence, and the blocks or states relating thereto can be performed in other sequences that are appropriate.

It will also be noted that each block of the block diagrams and/or flowchart illustration, and combinations of blocks in the block diagrams and/or flowchart illustration, are implementable by special purpose hardware-based systems that perform the specified functions or acts or carry out combinations of special purpose hardware and computer instructions. For example, any of the processes, methods, algorithms, elements, blocks, applications, or other functionality (or portions of functionality) described herein may be embodied in, and/or fully or partially automated via, electronic hardware such application-specific processors (e.g., application-specific integrated circuits (ASICs)), programmable processors (e.g., field programmable gate arrays (FPGAs)), application-specific circuitry, and/or the like (any of which may also combine custom hard-wired logic, logic circuits, ASICs, FPGAs, etc. with custom programming/execution of software instructions to accomplish the techniques).

Any of the above-mentioned processors, and/or devices incorporating any of the above-mentioned processors, may be referred to herein as, for example, “computers,” “computer devices,” “computing devices,” “hardware computing devices,” “hardware processors,” “processing units,” and/or the like. Computing devices of the implementations of the present disclosure may generally (but not necessarily) be controlled and/or coordinated by operating system software, such as Mac OS, iOS, Android, Chrome OS, Windows OS (e.g., Windows XP, Windows Vista, Windows 7, Windows 8, Windows 10, Windows 11, Windows Server, etc.), Windows CE, Unix, Linux, SunOS, Solaris, Blackberry OS, VxWorks, or other suitable operating systems. In other embodiments, the computing devices are controlled by a proprietary operating system, or a combination of proprietary and/or other operation systems. Conventional operating systems control and schedule computer processes for execution, perform memory management, provide file system, networking, I/O services, and provide a user interface functionality, such as a graphical user interface (“GUI”), among other things.

For example, FIG. 6 shows a block diagram that illustrates an example computer system 300 upon which various implementations and/or aspects (e.g., one or more aspects of the RF system 102, RF systems 106, the central processing server 107, user devices 110, other aspects of the operating environment 100, and/or the like) are implementable. Computer system 300 includes a bus or other communication mechanism for communicating information, and a hardware processor, or multiple processors, coupled with bus for processing information. Hardware processor(s) is optionally, for example, one or more general purpose microprocessors.

Computer system 300 also includes a main memory, such as a random-access memory (RAM), cache and/or other dynamic storage devices, coupled to bus for storing information and instructions to be executed by processor. Main memory also is usable for storing temporary variables or other intermediate information during execution of instructions to be executed by processor. Such instructions, when stored in storage media accessible to processor, render computer system 300 into a special-purpose machine that is customized to perform the operations specified in the instructions. The main memory, for example, optionally includes instructions to implement the cooling features of any of the implementations above, such as the variable fan speed, and/or other aspects of functionality of the present disclosure, according to various implementations.

Computer system 300 further includes a read only memory (ROM) or other static storage device coupled to bus for storing static information and instructions for processor. A storage device, such as a magnetic disk, optical disk, or USB thumb drive (Flash drive), and/or the like, is provided and coupled to bus for storing information and instructions.

Computer system 300 is optionally coupled via bus to a display, such as a cathode ray tube (CRT) or LCD display (or touch screen), for displaying information to a computer user. An input device, including alphanumeric and other keys, is coupled to bus for communicating information and command selections to processor. Another type of user input device is cursor control, such as a mouse, a trackball, or cursor direction keys for communicating direction information and command selections to processor and for controlling cursor movement on display. This input device typically has two degrees of freedom in two axes, a first axis (e.g., x) and a second axis (e.g., y), that allows the device to specify positions in a plane. In some embodiments, the same direction information and command selections as cursor control is implemented via receiving touches on a touch screen without a cursor.

Computing system 300 optionally includes a user interface module to implement a GUI that may be stored in a mass storage device as computer executable program instructions that are executed by the computing device(s). Computer system 300 further, as described below, optionally implements the techniques described herein using customized hard-wired logic, one or more ASICs or FPGAs, firmware and/or program logic which in combination with the computer system causes or programs computer system 300 to be a special-purpose machine. According to various embodiments, the techniques herein are performed by computer system 300 in response to processor(s) executing one or more sequences of one or more computer-readable program instructions contained in main memory. Such instructions are optionally read into main memory from another storage medium, such as storage device. Execution of the sequences of instructions contained in main memory causes processor(s) to perform the process steps described herein. In alternative embodiments, hard-wired circuitry is used in place of, or in combination with, software instructions.

Various forms of computer-readable storage media are optionally involved in carrying one or more sequences of one or more computer-readable program instructions to processor for execution. For example, the instructions are optionally initially carried on a magnetic disk or solid-state drive of a remote computer. In some cases, the remote computer loads the instructions into its dynamic memory and sends the instructions over a telephone or other signal transmission line, e.g., using a modem. A modem and/or transmitter device local to computer system 300 receives the data, and causes the data to be transmitted on the telephone or other signal transmission line. A receiver receives the data and appropriate circuitry places the data on bus. The bus carries the data to main memory, from which processor retrieves and executes the instructions. The instructions received by main memory are optionally stored on storage device either before or after execution by processor.

Computer system 300 also includes a communication interface coupled to bus. Communication interface provides a two-way data communication coupling to a network link that is connected to a local network. For example, communication interface is optionally an integrated services digital network (ISDN) card, cable modem, satellite modem, or other interface device to provide a data communication connection to a corresponding type of signal transmission line. As another example, communication interface is optionally a local area network (LAN) card to provide a data communication connection to a compatible LAN (or WAN component to communicated with a WAN). In some cases, wireless links are implemented. In any such implementation, communication interface sends and receives electrical, electromagnetic, or optical signals that carry digital data streams representing various types of information.

Network link typically provides data communication through one or more networks to other data devices. For example, network link optionally provides a connection through local network to a host computer or to data equipment operated by an Internet Service Provider (ISP). ISP in turn provides data communication services through the worldwide packet data communication network commonly referred to as the “Internet”. Local network and Internet both use electrical, electromagnetic, or optical signals that carry digital data streams. The signals through the various networks and the signals on network link and through communication interface, which carry the digital data to and from computer system 300, are example forms of transmission media.

Computer system 300 is configurable to send messages and receive data, including program code, through the network(s), network link and communication interface. In the Internet example, a server optionally transmits a requested code for an application program through Internet, ISP, local network and communication interface. The received code is executable by processor as it is received, and/or stored in storage device, or other non-volatile storage for later execution.

In various implementations certain functionality is accessible by a user through a web-based viewer (such as a web browser), or other suitable software program. In some implementations, the user interface (and/or user interface data usable for rending a user interface) is generated by a server computing system and transmitted to a web browser of the user (e.g., running on the user's computing system). Alternatively, data (e.g., user interface data) necessary for generating the user interface is provided by the server computing system to the browser, where the user interface is generated (e.g., the user interface data may be executed by a browser accessing a web service and may be configured to render the user interfaces based on the user interface data). The user may then interact with the user interface through the web-browser. User interfaces of certain implementations may be accessible through one or more dedicated software applications. In certain embodiments, one or more of the computing devices and/or systems of the disclosure include mobile computing devices, and user interfaces may be accessible through such mobile computing devices (for example, smartphones, tablets, virtual and/or augmented reality glasses, and/or the like).

While certain implementations of the inventions have been described, these implementations have been presented by way of example only, and are not intended to limit the scope of the disclosure. Indeed, the novel methods and systems described herein are implementable in a variety of other forms. Furthermore, various omissions, substitutions and changes in the systems and methods described herein are implementable without departing from the spirit of the disclosure. The accompanying claims and their equivalents are intended to cover such forms or modifications as would fall within the scope and spirit of the disclosure. Accordingly, the scope of the present inventions is defined only by reference to the appended claims.

Features, materials, characteristics, or groups described in conjunction with a particular aspect, implementation, or example are to be understood to be applicable to any other aspect, implementation or example described in this section or elsewhere in this specification unless incompatible therewith. All of the features disclosed in this specification (including any accompanying claims, abstract and drawings), and/or all of the steps or blocks of any method or process so disclosed, are combined in any combination, except combinations where at least some of such features and/or steps are mutually exclusive. The protection is not restricted to the details of any foregoing implementations. The protection extends to any novel one, or any novel combination, of the features disclosed in this specification (including any accompanying claims, abstract and drawings), or to any novel one, or any novel combination, of the steps or blocks of any method or process so disclosed.

Furthermore, certain features that are described in this disclosure in the context of separate implementations are also implementable in combination in a single implementation. Conversely, various features that are described in the context of a single implementation are also implementable in multiple implementations separately or in any suitable subcombination. Moreover, although features are described above as acting in certain combinations, one or more features from a claimed combination are, in some cases, excised from the combination, and the combination is claimable as a subcombination or variation of a subcombination.

Moreover, while operations are depicted in the drawings or described in the specification in a particular order, such operations need not be performed in the particular order shown or in sequential order, or that all operations be performed, to achieve desirable results. Other operations that are not depicted or described are incorporated in the example methods and processes. For example, one or more additional operations are performable before, after, simultaneously, or between any of the described operations. Further, in various implementations, the operations are rearranged or reordered in other implementations. Those skilled in the art will appreciate that in some implementations, the actual steps taken in the processes illustrated and/or disclosed differ from those shown in the figures. Depending on the implementation, certain of the steps described above are removed, and/or others are added. Furthermore, the features and attributes of the specific implementations disclosed above are, in various implementations, combined in different ways to form additional implementations, all of which fall within the scope of the present disclosure. Also, the separation of various system components in the implementations described above should not be understood as requiring such separation in all implementations, and it should be understood that the described components and systems are, in some implementations, integrated together in a single product or packaged into multiple products.

For purposes of this disclosure, certain aspects, advantages, and novel features are described herein. Not necessarily all such advantages are achieved in accordance with any particular implementation. Thus, for example, those skilled in the art will recognize that the disclosure, in various implementations, is embodied or carried out in a manner that achieves one advantage or a group of advantages as taught herein without necessarily achieving other advantages as are taught or suggested herein.

Conditional language, such as “can,” “could,” “might,” or “may,” unless specifically stated otherwise, or otherwise understood within the context as used, is intended to convey that certain implementations include, while other implementations do not include, certain features, elements, and/or steps. Thus, such conditional language is not intended to imply that features, elements, and/or steps are in any way required for one or more implementations or that one or more implementations necessarily include logic for deciding, with or without user input or prompting, whether these features, elements, and/or steps are included or are to be performed in any particular implementation.

Conjunctive language such as the phrase “at least one of X, Y, and Z,” or “at least one of X, Y, or Z,” unless specifically stated otherwise, is to be understood with the context as used in general to convey that an item, term, and/or the like is either X, Y, or Z, or a combination thereof. For example, the term “or” is used in its inclusive sense (and not in its exclusive sense) so that when used, for example, to provide a list of elements, the term “or” means one, some, or all of the elements in the list. Thus, such conjunctive language is not generally intended to imply that certain implementations require at least one of X, at least one of Y, and at least one of Z to each be present.

The term “a” as used herein should be given an inclusive rather than exclusive interpretation. For example, unless specifically noted, the term “a” should not be understood to mean “exactly one” or “one and only one”; instead, the term “a” means “one or more” or “at least one,” whether used in the claims or elsewhere in the specification and regardless of uses of quantifiers such as “at least one,” “one or more,” or “a plurality” elsewhere in the claims or specification.

The term “comprising” as used herein should be given an inclusive rather than exclusive interpretation. For example, a general-purpose computer comprising one or more processors should not be interpreted as excluding other computer components, and possibly includes such components as memory, input/output devices, and/or network interfaces, among others.

Language of degree used herein, such as the terms “approximately,” “about,” “generally,” and “substantially,” represent a value, amount, or characteristic close to the stated value, amount, or characteristic that still performs a desired function or achieves a desired result. For example, the terms “approximately”, “about”, “generally,” and “substantially,” according to various implementations, refer to an amount that is within less than 10% of, within less than 5% of, within less than 1% of, within less than 0.1% of, and within less than 0.01% of the stated amount. As another example, in certain implementations, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred implementations in this section or elsewhere in this specification, and are defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

Of course, the foregoing description is that of certain features, aspects and advantages of the present invention, to which various changes and modifications can be made without departing from the spirit and scope of the present invention. Moreover, the devices described herein need not feature all of the objects, advantages, features and aspects discussed above. Thus, for example, those of skill in the art will recognize that the invention can be embodied or carried out in a manner that achieves or optimizes one advantage or a group of advantages as taught herein without necessarily achieving other objects or advantages as may be taught or suggested herein. In addition, while a number of variations of the invention have been shown and described in detail, other modifications and methods of use, which are within the scope of this invention, will be readily apparent to those of skill in the art based upon this disclosure. It is contemplated that various combinations or subcombinations of these specific features and aspects of implementations are made and still fall within the scope of the invention. Accordingly, it should be understood that various features and aspects of the disclosed implementations are combinable with or substitutable for one another in order to form varying modes of the discussed devices.

### Example Clauses and Aspects

Examples of the implementations of the present disclosure are described in view of the following example clauses. The features recited in the below example implementations are combinable with additional features disclosed herein. Furthermore, additional inventive combinations of features are disclosed herein, which are not specifically recited in the below example implementations, and which do not include the same features as the specific implementations below. For sake of brevity, the below example implementations do not identify every inventive aspect of this disclosure. The below example implementations are not intended to identify key features or essential features of any subject matter described herein. Any of the example clauses below, or any features of the example clauses, are combinable with any one or more other example clauses, or features of the example clauses or other features of the present disclosure.

Clause 1: A radio frequency (RF) system, the system comprising: a module enclosure having an outer shell defining an interior space; a plurality of modules disposed within the interior space, each of the plurality of modules comprising at least one channel extending through an interior portion of each module, the at least one channel configured to allow airflow through the interior portion of each of the plurality of modules; a cover plate that removable couples to the module enclosure, wherein the cover seals the module enclosure from an external environment; and at least one fan coupled to a first side of the module enclosure to cause air to flow through the at least one channel of each of the plurality of modules and exit through a second side of the module enclosure.

Clause 2: The system of clause 1, wherein the cover plate includes at least one external interface for attaching external devices or accessing the interior space of the module enclosure, the external interface located on an outer surface of the cover plate, the at least external interface including at least one of: a plurality of attachment points for securely coupling external devices comprising at least one of antennas, sensors, and communication modules, to the cover plate; and a closeable closure integrated into the cover plate, the closeable closure being movable between an open and closed position to provide access to the interior space of the module enclosure without removing the cover plate.

Clause 3: The system of clause 2, wherein the plurality of attachment points includes a multiplexer (MUX) configured to combine signals from multiple power amplifiers for selective transmission of the signals to the antennas.

Clause 4: The system of any one of clauses 1 to 3, wherein the at least one fan provides a variable airflow rate through the at least one channel, the at least one fan comprising a motor with adjustable speed control to vary the airflow based at least on thermal requirements of the plurality of modules disposed within the interior space.

Clause 5: The system of any one of clauses 1 to 4, further comprising temperature sensors to monitor the temperature of each module and a control unit configured to adjust a speed of the at least one fan based at least on the temperature detected by the temperature sensors.

Clause 6: The system of clause 5, wherein the temperature sensors are positioned within each of the plurality of modules, the temperature sensors embedded in the at least one channel and a center of each of the plurality of modules to provide real-time temperature measurements.

Clause 7: The system of any one of clauses 1 to 6, further comprising openings in the second side of the module enclosure, the openings corresponding with and in fluid communication with the at least one channel for exhausting the air from the at least one channel.

Clause 8: The system of any one of clauses 1 to 7, wherein the module enclosure further comprises a plurality of slots, each of the plurality of slots is configured to receive a corresponding module of the plurality of modules, the plurality of slots comprising alignment guides or rails within each of the plurality of slots to for positioning and insertion or removal of the corresponding module of the plurality of modules, and electrical and data connectors integrated within the plurality of slots to provide power and communication to the corresponding module of the plurality of modules.

Clause 9: The system of any one of clauses 1 to 8, further comprising one or more antennas coupled to the module enclosure on one or more exterior surfaces of the module enclosure and configured to receive RF signals and transmit RF signals.

Clause 10: The system of any one of clauses 1 to 9, further comprising a direction finder coupled to an exterior surface of the module enclosure, and configured to receive RF signals and provide direction finding information to the at least one of the module enclosure.

Clause 11: The system of any one of clauses 1 to 10, further comprising a system manager for monitoring and managing the RF system, the system manage providing real-time data of the RF system.

Clause 12: The system of any one of clauses 1 to 11, further comprising a backplane board comprising a plurality of interconnects configured for facilitating communication and power distribution between the plurality of modules.

Clause 13: The system of any one of clauses 1 to 12, further comprising one or more handles coupled to the module enclosure, the handles configured for manual transportation or positioning of the module enclosure.

Clause 14: A thermal management system for a radio frequency (RF) system, the system comprising: a module enclosure having an outer shell defining an interior space and configured to house a plurality of modules; at least one channel extending through an interior portion of each of the plurality of modules, the at least one channel having a channel heatsink disposed within the at least one channel to dissipate thermal energy generated within each of the plurality of modules; and at least one fan coupled to a first side of the module enclosure to cause air to flow through the at least one channel of each of the plurality of modules and exit through a second side of the module enclosure.

Clause 15: The system of clause 14, wherein the channel heatsink comprises a folded fin heatsink, the folded fin heatsink comprising a plurality of thin fins, each of the thin fins formed from a thermally conductive material, the fins formed in a compact arrangement to create a high-density fin structure.

Clause 16: The system of any one of clauses 14 to 15, wherein the at least one fan provides a variable airflow rate through the at least one channel, the at least one fan comprising a motor with adjustable speed control to vary the airflow based at least on thermal requirements of the plurality of modules disposed within the interior space.

Clause 17: The system of any one of clauses 14 to 16, further comprising temperature sensors to monitor the temperature of each module and a control unit configured to adjust a speed of the at least one fan based at least on the temperature detected by the temperature sensors.

Clause 18: The system of clause 17, wherein the temperature sensors are positioned within each of the plurality of modules, the temperature sensors embedded in the at least one channel and a center of each of the plurality of modules to provide real-time temperature measurements.

Clause 19: The system of any one of clauses 14 to 18, further comprising openings in the second side of the module enclosure, the openings corresponding with and in fluid communication with the at least one channel for exhausting the air from the at least one channel.

Clause 20: The system of any one of clauses 14 to 19, wherein the at least one fan is positioned to create a positive pressure within the module to push air through the at least one channel from the first side to the second side or create a negative pressure within the module enclosure to draw air through the at least one channel from the second side to the first side.

Clause 21: A thermal management method of a radio frequency (RF) system, the method comprising: providing a module enclosure having an outer shell defining an interior space; disposing a plurality of modules within the interior space, each of the plurality of modules comprising at least one channel extending through an interior portion of each module, the at least one channel configured to allow airflow through the interior portion of each of the plurality of modules; coupling a removable cover plate to the module enclosure, wherein the cover seals the module enclosure from an external environment; and coupling at least one fan a first side of the module enclosure to cause air to flow through the at least one channel of each of the plurality of modules and exit through a second side of the module enclosure.

Clause 22: The method of clause 21, wherein the cover plate includes at least one external interface for attaching external devices or accessing the interior space of the module enclosure, the external interface located on an outer surface of the cover plate, the at least external interface including at least one of: a plurality of attachment points for securely coupling external devices comprising at least one of antennas, sensors, and communication modules, to the cover plate; and a closure integrated into the cover plate, the closure being movable between an open and closed position to provide access to the interior space of the module enclosure without removing the cover plate.

Clause 23: The method of clause 22, wherein the plurality of attachment points includes a multiplexer (MUX) configured to combine signals from multiple power amplifiers for selective transmission of the signals to the antennas.

Clause 24: The method of any one of clauses 21 to 23, further comprising providing via the at least one fan a variable airflow rate through the at least one channel, the at least one fan comprising a motor with adjustable speed control to vary the airflow based at least on thermal requirements of the plurality of modules disposed within the interior space.

Clause 25: The method of any one of clauses 21 to 24, further comprising monitoring via temperature sensors the temperature of each module and a control unit configured to adjust a speed of the at least one fan based at least on the temperature detected by the temperature sensors.

Clause 26: The method of clause 25, wherein the temperature sensors are positioned within each of the plurality of modules, the temperature sensors embedded in the at least one channel and a center of each of the plurality of modules to provide real-time temperature measurements.

Clause 27: The method of any one of clauses 21 to 26, wherein the module enclosure further comprising openings in the second side of the module enclosure, the openings corresponding with and in fluid communication with the at least one channel for exhausting the air from the at least one channel.

Clause 28: The method of any one of clauses 21 to 27, wherein the module enclosure further comprises a plurality of slots, each of the plurality of slots is configured to receive a corresponding module of the plurality of modules, the plurality of slots comprising alignment guides or rails within each of the plurality of slots to for positioning and insertion or removal of the corresponding module of the plurality of modules, and electrical and data connectors integrated within the plurality of slots to provide power and communication to the corresponding module of the plurality of modules.

Clause 29: The method of any one of clauses 21 to 28, further comprising coupling one or more antennas to the module enclosure on one or more exterior surfaces of the module enclosure, the one or more antennas configured to receive RF signals and transmit RF signals.

Clause 30: The method of any one of clauses 21 to 29, further comprising coupling a direction finder to an exterior surface of the module enclosure, and configured to receive RF signals and provide direction finding information to the at least one of the module enclosure.

Clause 31: The method of any one of clauses 21 to 30, further comprising disposing a system manager for monitoring and managing the RF system within the interior space, the system manage providing real-time data of the RF system.

Clause 32: The method of any one of clauses 21 to 31, further comprising disposing a backplane board comprising a plurality of interconnects configured for facilitating communication and power distribution between the plurality of modules within the interior space.

Clause 33: The method of any one of clauses 21 to 32, further comprising coupling one or more handles to the module enclosure, the handles configured for manual transportation or positioning of the module enclosure.

Clause 34.A module having an integrated thermal system, the module comprising: a module package comprising a central portion configured to house an electronic component, wherein the central portion is adaptable to support different variations of the electronic component; at least two channels extending through lateral portions of the module package in proximity to the central portion, wherein the at least two channels further comprises a folded fin heatsink disposed within a length of the at least two channels; and one or more heat pipes at least partially embedded in the module package and configured to transfer heat from the electronic component in the central portion of the module package to the at least two channels extending through the lateral portions, wherein the electronic component is in thermal communication with the at least two channels.

Clause 35: The module of clause 34, wherein the folded fin heatsink comprises a plurality of thin fins, each of the thin fins comprising a thermally conductive material and in a compact arrangement.

Clause 36: The module of any one of clauses 34 to 35, further comprising a module heatsink positioned in proximity to the electronic component in the central portion and in thermal communication with the one or more heat pipes, the module heatsink configured to transfer heat from the electronic component to the one or more heat pipes.

Clause 37: The module of any one of clauses 34 to 36, wherein the electronic component comprises a modular sensor package having a processing unit for data processing and analysis and interfaces for coupling the electronic component for data transmission and power, wherein the one or more heat pipes extend over a top surface of the electronic component and a bottom surface of the electronic component.

Clause 38: The module of clause 37, wherein the modular sensor package further comprises: a compute board configured to provide central processing functions and data computation, the compute board comprising at least one processor and memory unit for executing instructions; a carrier board electrically coupled to the compute board, the carrier board configured to provide input/output interfaces and power management for the compute board; and a personality board removably attached to the carrier board, the personality board configured to modify or extend the functionality of the electronic component by interfacing with the carrier board, wherein the personality board includes circuitry to customize operations of the electronic component for a desired application.

Clause 39: The module of clause 38, wherein the one or more heat pipes comprises interior heat pipes, the interior heat piped completely embedded within the module package, the interior pipes positioned in proximity to the electronic component in the central portion of the module package, and wherein the interior heat pipes are disposed in between at least one of the compute board, carrier board, and personality board.

Clause 40: The module of any one of clauses 37 to 39, wherein the one or more heat pipes comprises exterior heat pipe and are at least partially embedded in one or more exterior surfaces of the module package, the exterior heat pipes disposed on the top surface and the bottom surface, the bottom surface opposite the top surface.

Clause 41: The module of any one of clauses 34 to 40, wherein the module package further comprises a slot configured to receive the electronic component, the slot comprising alignment guides or rails for positioning and insertion or removal of the electronic component, and electrical and data connectors integrated the slot to provide power and communication to the electronic component.

Clause 42: The module of clause 41, wherein the one or more heat pipes comprises exterior heat pipe and are at least partially embedded in one or more exterior surfaces of the module package, the exterior heat pipes disposed on a first surface and a second surface, the second surface opposite the first surface, and wherein the exterior heat pipes are disposed above or below the at least two channels extending through the lateral portions.

Clause 43: The module of any one of clauses 34 to 42, wherein the electronic component comprises a power amplifier configured to provides radio frequency (RF) power amplification, converting low-power RF into a higher-power signal, the power amplifier being further configured to couple via a multiplexer (mux) to a plurality of antennas for transmission of the amplified signal.

Clause 44: A thermal management method of a module, the thermal management method comprising: providing a module package comprising a central portion configured to house an electronic component, wherein the central portion is adaptable to support variations of the electronic component; forming at least two channels extending through lateral portions of the module package in proximity to the central portion, wherein the at least two channels further comprises a folded fin heatsink disposed within a length of the at least two channels; and at least partially embedding one or more heat pipes in the module package, the one or more heat pipes to transfer heat from the electronic component in the central portion of the module package to the at least two channels extending through the lateral portions, wherein the electronic component is in thermal communication with the at least two channels via the one or more heat pipes.

Clause 45: The method of clause 44, wherein the folded fin heatsink comprises a plurality of thin fins, each of the thin fins formed from a thermally conductive material and in a compact arrangement to create a high-density fin structure.

Clause 46: The method of any one of clauses 44 to 45, further comprising positioning a module heatsink below the electronic component in the central portion and in thermal communication with the one or more heat pipes, the module heatsink configured to transfer heat from the electronic component to the one or more heat pipes.

Clause 47: The method of any one of clauses 44 to 46, wherein the electronic component comprises a modular sensor package having a processing unit for data processing and analysis and interfaces for coupling the electronic component for data transmission and power, wherein the one or more heat pipes extend over a top surface of the electronic component and a bottom surface of the electronic component.

Clause 48: The method of clause 47, wherein the modular sensor package further comprises: a compute board configured to provide central processing functions and data computation, the compute board comprising at least one processor and memory unit for executing instructions; a carrier board electrically coupled to the compute board, the carrier board configured to provide input/output interfaces and power management for the compute board; and a personality board removably attached to the carrier board, the personality board configured to modify or extend the functionality of the electronic component by interfacing with the carrier board, wherein the personality board includes circuitry to customize operations of the electronic component for a desired application.

Clause 49: The method of clause 48, wherein the one or more heat pipes comprises interior heat pipes and are completely embedded within the module package, the interior pipes positioned in proximity to the electronic component in the central portion of the module package, and wherein the interior heat pipes are disposed in between at least one of the compute board, carrier board, and personality board.

Clause 50: The method of any one of clauses 47 to 49, wherein the one or more heat pipes comprises exterior heat pipe and are at least partially embedded in one or more exterior surfaces of the module package, the exterior heat pipes disposed on a first surface and a second surface, the second surface opposite the first surface.

Clause 51: The method of any one of clauses 44 to 50, wherein the module package further comprises a slot configured to receive the electronic component, the slot comprising alignment guides or rails for positioning and insertion or removal of the electronic component, and electrical and data connectors integrated the slot to provide power and communication to the electronic component.

Clause 52: The method of clause 51, wherein the one or more heat pipes comprises exterior heat pipe and are at least partially embedded in one or more exterior surfaces of the module package, the exterior heat pipes disposed on a first surface and a second surface, the second surface opposite the first surface, and wherein the exterior heat pipes are disposed above or below the at least two channels extending through the lateral portions.

Clause 53: The method of any one of clauses 44 to 52, wherein the electronic component comprises a power amplifier configured to provides radio frequency (RF) power amplification, converting low-power RF into a higher-power signal, the power amplifier being further configured to couple via a multiplexer (mux) to a plurality of antennas for transmission of the amplified signal.

Clause 54. A radio frequency (RF) system, the system comprising: an antenna housing comprising a plurality of exterior surfaces, each of the plurality of exterior surfaces having at least one slot, the antenna housing having a plurality of internal channels extending through the antenna housing and along a width of each of the at least one slot; one or more antenna packages coupling to the at least one slot, wherein the at least one slot is configured to receive and couple to the one or more antenna packages, each of the one or more antenna packages comprising at least one antenna and a heatsink, wherein the heatsink aligns with and is positioned in a corresponding internal channel of the plurality of internal channels, the heatsink in fluid communication with the corresponding internal channel; and at least one fan mounted on a top of the antenna housing to direct airflow through the plurality of internal channels and the heatsink of each of the one or more antenna packages, wherein the at least one fan, the plurality of internal channels, and the at least one slot are in fluid communication with one another.

Clause 55. The system of Claim 54, wherein the antenna housing comprises vents on the top of the antenna housing, wherein the airflow flows through the vents to the fan, through the plurality of internal channels to the heatsink positioned in the at least one slot, and exits through the heatsink and out a bottom portion of the antenna housing.

Clause 56. The system of any one of Claims 54 to 55, wherein the at least one fan provides a variable airflow rate through the antenna housing, the at least one fan comprising a motor with adjustable speed control to vary the airflow based at least on thermal requirements of the one or more antenna packages in the at least one slot of each of the plurality of exterior surfaces.

Clause 57. The system of any one of Claims 54 to 56, further comprising temperature sensors to monitor the temperature of each module of the one or more antenna packages and a control unit configured to adjust a speed of the at least one fan based at least on the temperature detected by the temperature sensors.

Clause 58. The system of Claim 57, wherein the temperature sensors are positioned within each of the one or more antenna packages, the temperature sensors embedded or adjacent to the at least one antenna or heatsink of the of the one or more antenna packages to provide real-time temperature measurements.

Clause 59. The system of any one of Claims 54 to 58, wherein the heatsink comprises a folded fin heatsink, the folded fin heatsink comprising a plurality of thin fins, each of the thin fins formed from a thermally conductive material and in a compact arrangement to create a high-density fin structure.

Clause 60. The system of any one of Claims 54 to 59, wherein the one or more exterior surfaces of the antenna housing comprise three exterior surfaces on which the one or more antenna packages are arranged in a radial configuration around the antenna housing, wherein signals received and transmitted by the one or more antenna packages provide a 360 degree coverage of the antenna housing.

Clause 61. The system of any one of Claims 54 to 60, wherein the at least slot comprises alignment guides or rails for positioning and insertion or removal of the one or more antenna packages, and electrical and data connectors integrated within the at least one slot via one or more apertures through the antenna housing to provide power and communication to the one or more antenna packages.

Clause 62. The system of any one of Claims 54 to 61, wherein each of the one or more antenna packages further comprise a housing having an electromagnetic interference (EMI) shield coupled to the heatsink, active radio frequency (RF) components and a feed located within the housing, antenna components operably coupled to the feed, and an antenna cover disposed over the antenna components.

Clause 63. The system of any one of Claims 54 to 62, wherein each of the one or more antenna packages is configured to lie flat against the one or more exterior surfaces of the antenna housing, and wherein each of the one or more exterior surfaces and the one or more antenna packages comprise a bottom portion and a top portion, wherein the bottom portion extends outward relative to the top portion, and the top portion is angled rearward with respect to the bottom portion.

Clause 64. A thermal management method of a radio frequency (RF) system, the method comprising: providing a antenna housing comprising a at least one slot positioned along each of a plurality of exterior surfaces of the antenna housing, the antenna housing having a plurality of internal channels extending through the antenna housing and along a width of each of the at least one slot; coupling one or more antenna packages to the at least one slot, wherein the at least one slot is configured to receive and couple to the one or more antenna packages, each of the one or more antenna packages comprising at least one antenna and a heatsink, the heatsink aligning with and positioned in a corresponding internal channel of the plurality of internal channels, the heatsink in fluid communication with the corresponding internal channel; and mounting at least one fan on a top of the antenna housing to direct airflow through the plurality of internal channels and the heatsink of each of the one or more antenna packages, wherein the at least one fan, the plurality of internal channels, and the at least one slot are in fluid communication with one another.

Clause 65. The method of Claim 64, further comprising providing vents on the top of the antenna housing, wherein the airflow flows through the vents to the fan, through the plurality of internal channels to the heatsink positioned in the at least one slot, and exits through the heatsink and out a bottom portion of the antenna housing.

Clause 66. The method of any one of Claims 64 to 65, further comprising providing via the at least one fan a variable airflow rate through the antenna housing, the at least one fan comprising a motor with adjustable speed control to vary the airflow based at least on thermal requirements of the one or more antenna packages disposed in the at least one slot of each of the plurality of exterior surfaces.

Clause 67. The method of any one of Claims 64 to 66, further comprising monitoring via temperature sensors the temperature of each module of the one or more antenna packages and a control unit configured to adjust a speed of the at least one fan based at least on the temperature detected by the temperature sensors.

Clause 68. The method of Claim 67, wherein the temperature sensors are positioned within each of the one or more antenna packages, the temperature sensors embedded or adjacent to the at least one antennas or heatsink of the of the one or more antenna packages to provide real-time temperature measurements.

Clause 69. The method of any one of Claims 64 to 68, wherein the heatsink comprises a folded fin heatsink, the folded fin heatsink comprising a plurality of thin fins, each of the thin fins formed from a thermally conductive material and in a compact arrangement to create a high-density fin structure.

Clause 70. The method of any one of Claims 64 to 69, wherein the one or more exterior surfaces of the antenna housing comprise three exterior surfaces on which the one or more antenna packages are arranged in a radial configuration around the antenna housing, wherein signals received and transmitted by the one or more antenna packages provide a 360 degree coverage of the antenna housing.

Clause 71. The method of any one of Claims 64 to 70, wherein the at least slot comprises alignment guides or rails for positioning and insertion or removal of the one or more antenna packages, and electrical and data connectors integrated within the at least one slot via one or more apertures through the antenna housing to provide power and communication to the one or more antenna packages.

Clause 72. The method of any one of Claims 64 to 71, wherein each of the one or more antenna packages further comprise a housing having an electromagnetic interference (EMI) shield coupled to the heatsink, active radio frequency (RF) components and a feed located within the housing, antenna components operably coupled to the feed, and an antenna cover disposed over the antenna components.

Clause 73. The method of any one of Claims 64 to 72, wherein each of the one or more antenna packages is configured to lie flat against the one or more exterior surfaces of the antenna housing, and wherein each of the one or more exterior surfaces and the one or more antenna packages comprise a bottom portion and a top portion, wherein the bottom portion extends outward relative to the top portion, and the top portion is angled rearward with respect to the bottom portion.

What is claimed is:

1. A module having an integrated thermal system, the module comprising:
a module package comprising a central portion configured to house an electronic component, wherein the central portion is adaptable to support different variations of the electronic component;
at least two channels extending through lateral portions of the module package in proximity to the central portion, wherein the at least two channels further comprises a folded fin heatsink disposed within a length of the at least two channels; and
one or more heat pipes at least partially embedded in the module package and configured to transfer heat from the electronic component in the central portion of the module package to the at least two channels extending through the lateral portions, wherein the electronic component is in thermal communication with the at least two channels.

2. The module of claim 1, wherein the folded fin heatsink comprises a plurality of thin fins, each of the thin fins comprising a thermally conductive material and in a compact arrangement.

3. The module of claim 2, further comprising a module heatsink positioned in proximity to the electronic component in the central portion and in thermal communication with the one or more heat pipes, the module heatsink configured to transfer heat from the electronic component to the one or more heat pipes.

4. The module of claim 3, wherein the electronic component comprises a modular sensor package having a processing unit for data processing and analysis and interfaces for coupling the electronic component for data transmission and power, wherein the one or more heat pipes extend over a top surface of the electronic component and a bottom surface of the electronic component.

5. The module of claim 4, wherein the modular sensor package further comprises:
a compute board configured to provide central processing functions and data computation, the compute board comprising at least one processor and memory unit for executing instructions;
a carrier board electrically coupled to the compute board, the carrier board configured to provide input/output interfaces and power management for the compute board; and
a personality board removably attached to the carrier board, the personality board configured to modify or extend the functionality of the electronic component by interfacing with the carrier board, wherein the personality board includes circuitry to customize operations of the electronic component for a desired application.

6. The module of claim 5, wherein the one or more heat pipes comprises interior heat pipes, the interior heat piped completely embedded within the module package, the interior pipes positioned in proximity to the electronic component in the central portion of the module package, and wherein the interior heat pipes are disposed in between at least one of the compute board, carrier board, and personality board.

7. The module of claim 6, wherein the one or more heat pipes comprises exterior heat pipe and are at least partially embedded in one or more exterior surfaces of the module package, the exterior heat pipes disposed on the top surface and the bottom surface, the bottom surface opposite the top surface.

8. The module of claim 7, wherein the module package further comprises a slot configured to receive the electronic component, the slot comprising alignment guides or rails for positioning and insertion or removal of the electronic component, and electrical and data connectors integrated the slot to provide power and communication to the electronic component.

9. The module of claim 8, wherein the one or more heat pipes comprises exterior heat pipe and are at least partially embedded in one or more exterior surfaces of the module package, the exterior heat pipes disposed on a first surface and a second surface, the second surface opposite the first surface, and wherein the exterior heat pipes are disposed above or below the at least two channels extending through the lateral portions.

10. The module of claim 9, wherein the electronic component comprises a power amplifier configured to provides radio frequency (RF) power amplification, converting low-power RF into a higher-power signal, the power amplifier being further configured to couple via a multiplexer (mux) to a plurality of antennas for transmission of the amplified signal.

11. A thermal management method of a module, the method comprising:
providing a module package comprising a central portion configured to house an electronic component, wherein the central portion is adaptable to support variations of the electronic component;
forming at least two channels extending through lateral portions of the module package in proximity to the central portion, wherein the at least two channels further comprises a folded fin heatsink disposed within a length of the at least two channels; and
at least partially embedding one or more heat pipes in the module package, the one or more heat pipes to transfer heat from the electronic component in the central portion of the module package to the at least two channels extending through the lateral portions, wherein the electronic component is in thermal communication with the at least two channels via the one or more heat pipes.

12. The method of claim 11, wherein the folded fin heatsink comprises a plurality of thin fins, each of the thin fins formed from a thermally conductive material and in a compact arrangement to create a high-density fin structure.

13. The method of claim 12, further comprising positioning a module heatsink below the electronic component in the central portion and in thermal communication with the one or more heat pipes, the module heatsink configured to transfer heat from the electronic component to the one or more heat pipes.

14. The method of claim 13, wherein the electronic component comprises a modular sensor package having a processing unit for data processing and analysis and interfaces for coupling the electronic component for data transmission and power, wherein the one or more heat pipes extend over a top surface of the electronic component and a bottom surface of the electronic component.

15. The method of claim 14, wherein the modular sensor package further comprises:
a compute board configured to provide central processing functions and data computation, the compute board comprising at least one processor and memory unit for executing instructions;
a carrier board electrically couple to the compute board, the carrier board configured to provide input/output interfaces and power management for the compute board; and
a personality board removably attached to the carrier board, the personality board configured to modify or extend the functionality of the electronic component by interfacing with the carrier board, wherein the personality board includes circuitry to customize operations of the electronic component for a desired application.

16. The method of claim 15, wherein the one or more heat pipes comprises interior heat pipes and are completely embedded within the module package, the interior pipes positioned in proximity to the electronic component in the central portion of the module package, and wherein the interior heat pipes are disposed in between at least one of the compute board, carrier board, and personality board.

17. The method of claim 16, wherein the one or more heat pipes comprises exterior heat pipe and are at least partially embedded in one or more exterior surfaces of the module package, the exterior heat pipes disposed on a first surface and a second surface, the second surface opposite the first surface.

18. The method of claim 17, wherein the module package further comprises a slot configured to receive the electronic component, the slot comprising alignment guides or rails for positioning and insertion or removal of the electronic component, and electrical and data connectors integrated the slot to provide power and communication to the electronic component.

19. The method of claim 18, wherein the one or more heat pipes comprises exterior heat pipe and are at least partially embedded in one or more exterior surfaces of the module package, the exterior heat pipes disposed on a first surface and a second surface, the second surface opposite the first surface, and wherein the exterior heat pipes are disposed above or below the at least two channels extending through the lateral portions.

20. The method of claim 19, wherein the electronic component comprises a power amplifier configured to provides radio frequency (RF) power amplification, converting low-power RF into a higher-power signal, the power amplifier being further configured to couple via a multiplexer (mux) to a plurality of antennas for transmission of the amplified signal.
